(19) United States
(12) Patent Application Publication
(10) Pub. No.: US 2022/0223754 A1
(43) Pub. Date: Jul. 14, 2022

(54) METHOD FOR MANUFACTURING MICRO LED DISPLAY, AND MICRO LED DISPLAY USING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN, Gyeonggi-do (KR)

(73) Assignee: POINT ENGINEERING CO., LTD., Chungcheongnam-do (KR)

(21) Appl. No.: 17/613,943

(22) PCT Filed: May 15, 2020
(86) PCT No.: PCT/KR2020/006391

§ 371 Date: Nov. 23, 2021

(30) Foreign Application Priority Data
May 24, 2019 (KR) 10-2019-0061482

(51) Int. Cl. H01L 33/00; H01L 27/15; G09G 3/00; H01L 33/62; H01L 33/38

(52) U.S. Cl. CPC H01L 33/005; H01L 27/156; H01L 33/38; H01L 33/62; G09G 3/006

(57) ABSTRACT

Proposed is a method for manufacturing a micro-LED display, the method including a transfer step of absorbing, by a transfer head, a micro-LED on a first substrate and transferring, by the transfer head, the absorbed micro-LED to a second substrate.

### TECHNICAL FIELD

The present invention relates to a method for manufacturing a micro-LED display including a unit module and a micro-LED display manufactured using the method for manufacturing a micro-LED display.

### BACKGROUND ART

Currently, LCDs hold a majority display market share, but the trend is for OLEDs to replace LCDs and continue an increase in display market share. Display manufacturing companies actively participate in this rapidly growing OLED market. In this situation, micro-LED displays have emerged as next-generation displays. Essential materials of LCDs and OLEDs are liquid crystal and organic material, respectively. In contrast, micro-LED displays use a 1 to 100 micrometer (μm) LED chip itself as a light emitting material.

Cree Incorporated filed a patent application titled “MICRO-LED ARRAYS WITH ENHANCED LIGHT EXTRACTION” in 1999 (Korean Patent No. 10-0731673). Since then, the term micro-LED appeared. Research and development have been conducted with relevant research papers being published. In order to find applications of micro-LEDs in displays, there is a need to develop a customized micro-chip, as a micro-LED element, that is based on a flexible material/element. Accordingly, technologies for transfer of a micrometer-sized LED chip and precise mounting on a display pixel electrode are necessary.

Particularly, regarding a transfer that transports the micro-LED element to a display substrate, because a LED is reduced in size to 1 to 100 micrometer (μm), an existing pick-and-place apparatus can be used. Technologies for a transfer head capable of performing transportation with higher precision are necessary.

Instead of using a vacuum absorption force in the related art, technologies for using various forces, such as an electrostatic force, a van der Waals force, and a magnetic force have developed. Transfer technologies that use a material of which a bonding force varies with heat, a laser beam, UV light, and an electrostatic wave, and transfer methods that use a roller, fluid, and the like have been developed.

However, as described below, several technologies proposed so far have several disadvantages.

LuxVue Technology Cooperation in the USA filed a patent application for a method of transferring a micro-LED using electrostatic head (Korean Patent Application Publication No. 10-2014-0112486, hereinafter referred to as “Patent Document 2”). The principle of transfer in Patent Document 2 is that close contact with micro-LED is possible with electrification phenomenon that occurs by applying voltage to a head portion formed of silicon. This method may cause damage to the micro-LED due to the electrification phenomenon by the voltage applied to the head when inducing static electricity.

X-Celeprint US in the USA filed a patent application for a method of transporting a micro-LED on a wafer to a desired substrate by applying an elastic polymer material to a transfer head (Korean Patent Application Publication No. 10-2017-0019415, hereinafter referred to as “Patent Document 3”). This method, unlike the electrostatic head method, does not cause damage to the micro-LED. However, the disadvantage with this method is that the elastic transfer head needs to have a greater adhesion force than a target substrate for stable transportation of the micro-LED during a transfer process and that a process for electrode formation is additionally required. In addition, continuous maintenance of an adhesion force of the elastic polymer material is a very important factor.

Korea photonics technology institute filed a patent application for a method transferring a micro-LED using head with a ciliary adhesive structure (Korean Patent No. 10-1754528, hereinafter referred to as “Patent Document 4”) Patent Document 4 has the disadvantage that the ciliary adhesive structure is difficult to manufacture.

Korea Institute of Machinery & Materials filed a patent application for a method of transferring a micro-LED with a roller being coated with an adhesive agent (Korean Patent No. 10-1757404, hereinafter referred to as “Patent Document 5”). The Patent Document has the disadvantage that continuous use of the adhesive agent is required and that the micro-LED may be caused when the roller is pressed.

SAMSUNG DISPLAY filed a patent application for a method of transferring a micro-LED to an array substrate by using an electrostatic induction phenomenon occurring when applying a minus voltage to first and second electrodes of an array substrate in a state where the array substrate is immersed in a solution (Korean Patent Application Publication No. 10-2017-0026959, hereinafter referred to as “Patent Document 6”). Patent Document 6 has the disadvantage that a separate solution is necessary to transfer the solution-immersed micro-LED to the array substrate and that a drying process is required later.

LG Electronics filed a patent application for a method of arranging a head holder between a plurality of pick-up heads and a substrate, allowing movement of the plurality of pick-up heads in a deformable manner and thus providing the freedom to a plurality of pick-up heads (Korean Patent Application Publication No. 10-2017-0024906, hereinafter referred to as “Patent Document 7”). Patent Document 7 has the disadvantage that a separate process of applying an adhesive bonding material to the pick-up head because a micro-LED is transferred with the adhesive bonding material be applied to adhesion surfaces of the plurality of pick-up heads.

Patent Documents have their respective problems as described above. In order to solve these problems, it is necessary to improve upon the disadvantages described above while employing the basic principles employed in Patent Documents. However, since the disadvantages are derived from the principles, there are limitations to improve upon the disadvantages while utilizing the basic principles. The inventor of the present invention proposes a novel method to improve upon the disadvantages in the related art. This novel method is not considered in Patent Documents.

### DOCUMENTS OF RELATED ART

### Documents of Related Art

(Patent Document 1)

(Patent Document 1) Korean Patent No. 10-0731673

(Patent Document 2) Korean Patent Application Publication No. 10-2014-0112486

(Patent Document 3) Korean Patent Application Publication No. 10-2017-0019415

(Patent Document 4) Korean Patent No. 10-1754528

(Patent Document 5) Korean Patent No. 10-1757404

(Patent Document 6) Korean Patent Application Publication No. 10-2017-0026959

(Patent Document 7) Korean Patent Application Publication No. 10-2017-0024906

### DISCLOSURE

### Technical Problem

According to an objective of the present invention, which is made in view of the above-described problems, is to provide a method for manufacturing a micro-LED display and a micro-LED display using the method for manufacturing a micro-LED display.

### Technical Solution

According to an aspect of the present invention, there is provided a method for manufacturing a micro-LED display, the method including a transfer step of absorbing, by a transfer head, a micro-LED on a first substrate and transferring, by the transfer head, the absorbed micro-LED to a second substrate.

In the method, the transfer head may include: an absorption member divided into an absorption region absorbing the micro-LED that is a transfer target on the first substrate and a non-absorption region not absorbing the micro-LED that is a non-transfer target on the first substrate; and a support member provided on top of the absorption member and formed of a porous material, wherein the transfer head selectively absorbs the micro-LED on the first substrate and transfers the absorbed micro-LED to the second substrate.

In the method, hot air may be injected toward the absorption region of the transfer head, and thus the micro-LED may be separated from the first substrate.

In the method, in a state where a vacuum absorption force is generated, the transfer head may separate the micro-LED from the first substrate using a separation-force generation apparatus.

In the method, the transfer head may absorb the micro-LED with a first absorption force and a second absorption force that are different from each other.

The method may further include a cleaning step of cleaning an absorption surface of the transfer head, wherein the cleaning step is performed by at least one apparatus of a plasma generation apparatus, a purge gas injection apparatus, an ionic-wind injection apparatus, and a static electricity removal apparatus.

In the method, the micro-LED may be transferred in such a manner that a pitch distance in an x-direction between the same types of the micro-LEDs on the second substrate is three times a pitch distance in the x-direction between the same types of the micro-LEDs on the first substrate, and a pitch distance in a y-direction between the same types of the micro-LEDs on the second substrate is as much as a pitch distance in the y-direction between the same types of the micro-LEDs on the first substrate.

In the method, the micro-LEDs may be transferred in such a manner that a pitch distance in an x-direction between the same types of the micro-LEDs on the second substrate is three times a pitch distance in the x-direction between the same types of the micro-LEDs on the first substrate, and a pitch distance in a y-direction between the same types of the micro-LEDs on the second substrate is three times a pitch distance in the y-direction between the same types of the micro-LEDs on the first substrate.

In the method, the micro-LEDs may be transferred in such a manner that a pitch distance in an x-direction between the same types of the micro-LEDs on the second substrate is two times a pitch distance in the x-direction between the same types of the micro-LEDs on the first substrate, and a pitch distance in a y-direction between the same types of the micro-LEDs on the second substrate is two times a pitch distance in the y-direction between the same types of the micro-LEDs on the first substrate.

In the method, the micro-LEDs may be transferred in such a manner that a pitch distance in a diagonal direction between the same types of the micro-LEDs on the second substrate is the same as a pitch distance in the diagonal direction between the same types of the micro-LEDs on the first substrate.

In the method, the micro-LEDs may be transferred in such a manner that a pitch distance in one direction between the same types of the micro-LEDs on the second substrate is M/3 (where M is an integer that is equal to or greater than 4) times a pitch distance in the one direction between the same types of the micro-LEDs on the first substrate.

The method may further include: a step of preparing a positional error correction carrier that includes a loading groove having a bottom surface and an oblique portion and accommodating the micro-LED, and a non-loading surface provided in the vicinity of the loading groove; a positional error correction step of transferring the micro-LED on a first substrate to the positional error correction carrier and correcting a positional error of the micro-LED; and a step of transferring the micro-LED in the positional error correction carrier to the second substrate.

The method may further include an inspection step of inspecting the micro-LD in the first substrate or the second substrate, wherein the micro-LEDs in the first to m-th rows are sequentially inspected, and the micro-LEDs in the first to m-th columns are sequentially inspected, and coordinates of a position of the defective micro-LCD may be identified through the row-based inspection and the column-based inspection.

The method may further include: an inspection step of inspecting whether or not the micro-LED on the first substrate is defective; a removal step of removing the defective micro-LED detected in the inspection step from the first substrate; a repair step of attaching the quality micro-LED in such a manner as to be positioned at a position on the first substrate from which the defective micro-LED is removed; and a micro-LED transfer step of transferring the micro-LED on the first substrate to the second substrate using the transfer head.

The method may further a step of absorbing the micro-LED on the first substrate using the transfer head; an inspection step of inspecting whether or not the micro-LED absorbed to the transfer head is defective; a removal step of removing the defective micro-LED detected in the inspection step from the transfer head; a repair step of absorbing the quality micro-LED in such a manner as to be positioned at a position on the transfer head from which the defective micro-LED is removed; and a micro-LED transfer step of transferring the micro-LED absorbed to the transfer head to the second substrate.

The method may further include: a step of absorbing the micro-LED on the first substrate using the transfer head; an inspection step of inspecting whether or not the micro-LED absorbed to the transfer head is defective; a removal step of removing the defective micro-LED detected in the inspection step from the transfer head; a micro-LED transfer step of transferring the micro-LED absorbed to the transfer head to the second substrate; and a repair step of attaching the quality micro-LED in such a manner as to be positioned at a position on the second substrate from which the defective micro-LED is removed.

The method may further include: a step of absorbing the micro-LED on the first substrate using the transfer head; an inspection step of inspecting whether or not the micro-LED absorbed to the transfer head is defective; a micro-LED transfer step of transferring the micro-LED absorbed to the transfer head to the second substrate; a removal step of removing the defective micro-LED detected in the inspection step from the second substrate; and a repair step of attaching the quality micro-LED in such a manner as to be positioned at a position on the second substrate from which the defective micro-LED is removed.

The method may further include: a step of transferring the micro-LED on the first substrate to a relay wiring substrate including a relay wiring unit; a step of cutting the relay wiring substrate to which the micro-LED is transferred into a plurality of discrete modules; and a step of transferring, by the transfer head, a quality discrete module, among the discrete modules, and transferring, by the transfer head, the absorbed quality discrete module to the second substrate.

In the method, an electrostatic chuck may be provided underneath the second substrate, and the electrostatic chuck may attach the second substrate with an electrostatic force, may apply the electrostatic force to the micro-LED absorbed to the transfer head, and thus may force in the to descend toward the second substrate.

In the method, the transfer head may include an openable valve, wherein, when the transfer head absorbs the micro-LED, a vacuum pump may be operated in a state where the openable value is closed, and thus the micro-LED may be absorbed with a vacuum absorption force, and wherein, when the transfer head desorbs the micro-LED, the openable value may be open to release the vacuum absorption force, and thus the micro-LED absorbed to the transfer head may be desorbed.

In the method, the transfer head may include a heater unit, wherein in a micro-LED bonding step of bonding the micro-LED to the second substrate, an upper surface of the micro-LED may be heated through the heater unit.

In the method, in a micro-LED bonding step of bonding the micro-LED to the second substrate, an upper surface of the micro-LED may be heated by applying hot air through an absorption region of the transfer head.

In the method, a micro-LED bonding step of bonding the micro-LED to the second substrate may include a sub-step of preparing between the micro-LED and the second substrate an anisotropically conductive anodic oxide film formed by filling with a conductive material a pore in an anodic oxide film formed by anodically oxidizing a metal or a separate through-hole; and a sub-step of mounting the micro-LED in the anisotropically conductive anodic oxide film.

In the method, a micro-LED bonding step of bonding the micro-LED to the second substrate may include: a sub-step of preparing between the micro-LED and the second substrate an anisotropic conductive film formed by filling with a conductive material a plurality of holes vertically formed in an insulating porous film which is formed of an elastic material and in which the plurality of holes is vertically formed; and a sub-step of mounting the micro-LED on the anisotropic conductive film.

According to another aspect of the present invention, there is provided a micro-LED display including a second substrate to which a circuit wiring unit is provided; and a discrete module including a micro-LED electrically connected to the circuit wiring unit at an upper surface of the second substrate and electrically connected to a relay wiring unit on top of a relay wiring substrate on which the relay wiring unit is provided, wherein the discrete modules are discontinuously arranged on the second substrate.

According to still another aspect of the present invention, there is provided a micro-LED display including: a second substrate to which a circuit wiring unit is provided; and an anisotropically conductive anodic oxide film provided between a micro-LED and the second substrate and electrically connecting the second substrate and the micro-LED, wherein the anisotropically conductive anodic oxide film electrically connects the second substrate and the micro-LED to each other by filling a pore formed by anodically oxidizing a metal or a separate through-hole with a conductive material.

According to still another aspect of the present invention, there is provided a micro-LED display including: a second substrate to which a circuit wiring unit is provided; and an anisotropically conductive anodic oxide film provided between a micro-LED and the second substrate, wherein the anisotropically conductive anodic oxide film is formed by filling with a conductive material a plurality of holes vertically formed in an insulating porous film that is formed of an elastic material and in which the plurality of holes are vertically formed, and the vertical conductive material connects to the second substrate and the micro-LED to each other.

### Advantageous Effects

As described above, with a method for manufacturing a micro-LED display including a unit module according to the present invention and a micro-LED display manufactured using the method for manufacturing a micro-LED display according to the present invention, it is possible that the efficient process is performed, and the effect of being able to improve UPH for producing the finished product can be achieved.

### DESCRIPTION OF DRAWINGS

FIG. 1 is a view a micro-LED that is to be transported by a transfer head;

FIG. 2 is a view illustrating a micro-LED structure formed as a result of being transported and mounted to a circuit substrate by the transfer head according to the preferred embodiment of the present invention;

FIGS. 3 to 7 are views each illustrating an embodiment of the transfer head according to the present invention;

FIG. 8 is a view illustrating a cleaning step;

FIGS. 9 and 10 are views each illustrating an implementation example of a step of separating a micro-LED;

FIGS. 11 to 13 are views each illustrating an implementation example of a step of adjusting a pitch distance between the micro-LEDs;

FIGS. 14 and 15 are views each illustrating an implementation example of a step of inspecting a repairing a defective micro-LED;

FIGS. 16 to 19 are views each illustrating an implementation example of a step of bonding the micro-LED; and

FIG. 20 is a view schematic illustrating a process of manufacturing a micro-LED display according to the present invention.

### MODE FOR INVENTION

The principle behind the invention will be described below for illustrative purposes. Therefore, although not definitely described or illustrated in the present specification, it would be apparent to a person of ordinary skill in the art that various apparatuses that are predicted from the principle behind the invention and fall within the concept and scope of the invention. In addition, terms and embodiments used and described, respectively, throughout the present specification are all intended primarily to help understand the concept of the present invention, and therefore it should be understood that the present invention is not limited to the terms and embodiments that are particularly given with this intention.

Features and advantages of the present invention, which are described above, will be clearly understood from the following description with reference to the accompanying drawings, and thus the technical idea of the present invention will be easily embodied by a person of ordinary skill in the art to which the invention pertains.

In the present specification, embodiments of the present invention will be described with reference to exemplary cross-sectional and/or perspective views. Thicknesses of films and regions illustrated in the drawings, diameters holes in the films and the regions, and the like are expressed in an exaggerated manner for effective description. Forms in these views may be modified according to manufacturing technologies and/or allowed tolerances, and the like. In addition, only some of actual micro-LEDS are illustrated in the drawings for illustrative purposes. Therefore, embodiments of the present invention are not limited to specific forms illustrated in the drawings, and may vary in form and shape according to a manufacturing process.

For convenient description of various embodiments, the same constituent elements performing the same function, although in different embodiments, are given the same name and the same reference numeral. In addition, a configuration and an operation that are described in an earlier embodiment will be omitted for convenience.

Before starting to describe preferred embodiments of the present invention with reference to the accompanying drawings, it is noted that micro-elements may include a micro-LED. The micro-LED is separated by dicing a wafer used for crystal growth, but is packaged by molding resin or the like. The micro-LED is academically defined as having a size of 1 to 100 μm. However, the size (a length of one side) of the micro-LED described in the present specification is not limited to 1 to 100 μM and may be equal to or greater 100 μM or less than 1 μm.

Constituent elements described below of the preferred embodiment of the present invention may also be used for transferring micro-elements in which the technical idea of each embodiment finds application without any change.

A primary process of manufacturing a display D using a micro-LED (ML) manufactured on a growth substrate 101 includes Step (1) of manufacturing a micro-LED on a growth substrate, Step (2) of separating the micro-LED from a first substrate (growth substrate), Step (3) of transferring the micro-LED to a transfer head, Step (4) of adjusting a pitch distance between the micro-LEDs in order to build a pixel array of the micro-LEDs on a display panel, Step (5) of replacing a defective micro-LED with a quality micro-LED for repairing, Step (6) of bonding the micro-LED to an electrode on a circuit substrate, Step (7) of manufacturing a large-sized display panel using a unit module, and the like.

The novel technical means contemplated by the inventor in the process of manufacturing the display D using the micro-LED (ML) will be described below in a stepwise manner.

1. Step of Manufacturing the Micro-LED on the Growth Substrate

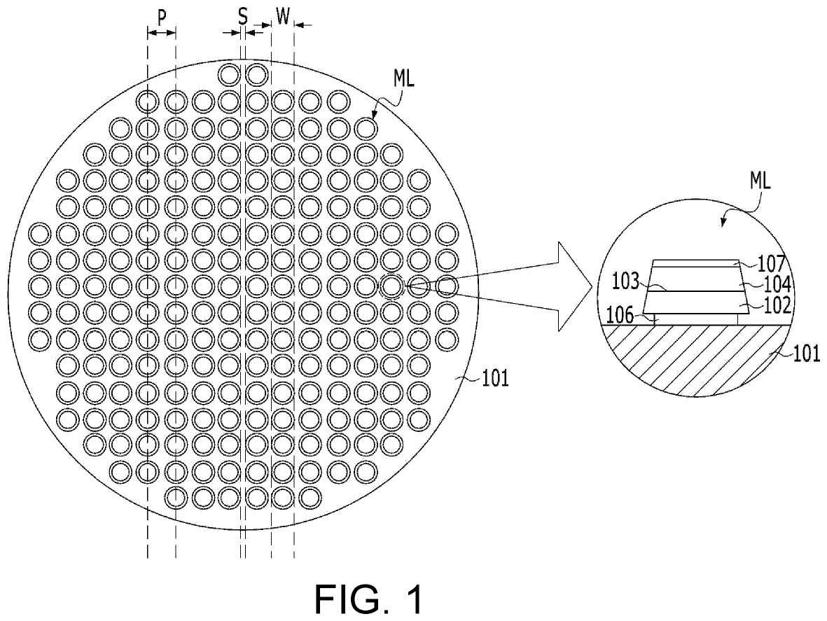

FIG. 1 is a view illustrating a plurality of micro-LEDs (ML) that are to be transported by the transfer head according to the preferred embodiment of the present invention. The micro-LED (ML) is manufactured on the growth substrate 101 and is positioned thereon.

The growth substrate 101 is formed on a conductive substrate or an insulating substrate. For example, the growth substrate 101 may be formed of at least one of sapphire, SiC, Si, GaAs, GaN, ZnO, Si, GaP, InP, Ge, and Ga₂O₃.

The micro-LED (ML) may include a first semiconductor layer 102, a second semiconductor layer 104, an active layer 103 formed between the first semiconductor layer 102 and the second semiconductor layer 104, a first contact electrode 106, and a second contact electrode 107.

The first semiconductor layer 102, the active layer 103, and the second semiconductor layer 104 may be formed using processes, such as Metal Organic Chemical Vapor Deposition (MOCVD), Chemical Vapor Deposition (CVD), Plasma-Enhanced Chemical Vapor Deposition (PECVD), Molecular Beam Epitaxy (MBE), and Hydride Vapor Phase Epitaxy (HVPE).

The first semiconductor layer 102, for example, may be realized as a p-type semiconductor layer. The p-type semiconductor layer may be formed of a semiconductor material satisfying a compositional formula: In xAl yGa 1-x-yN (0≤x≤1, 0≤y≤1, 0≤x+y≤1). For example, the p-type semiconductor layer may be formed of a semiconductor material selected from among GaN, AlN, AlGaN, InGaN, InN, InAlGaN, AlInN, and the like and may be doped with p-type dopants, such as Mg, Zn, Ca, Sr, and Ba.

The second semiconductor layer 104, for example, may be formed in such a manner as to include an n-type semiconductor layer. The n-type semiconductor layer may be formed of a semiconductor material satisfying a compositional formula: InₓAl_{y}Ga_{1-x-y}N (0≤x≤1, 0≤y≤1, 0≤x+y≤1). For example, the n-type semiconductor layer may be formed of a semiconductor material selected from among GaN, AlN, AlGaN, InGaN, InN, InAlGaN, AlInN, and the like and may be doped with n-type dopants, such as Si, Ge, and Sn.

However, the present invention is not limited to these semiconductor materials. The first semiconductor layer 102 may include the n-type semiconductor layer, and the second semiconductor layer 104 may include the p-type semiconductor layer.

The active layer 103 is a region where an electron and a hole are recombined. Due to the recombination of the electron and the hole, the active layer 103 transitions to a low energy level, and may generate light having a wavelength corresponding to the low energy level. The active layer 103, for example, may be formed in such a manner as to include a semiconductor material satisfying a compositional formula: InₓAl_{y}Ga_{1-x-y}N (0≤x≤1, 0≤y≤1, 0≤x+y≤1). The active layer 103 may be formed in such a manner as to have Single Quantum Well or Multi Quantum Well (MQW). In addition, the active layer 103 may include Quantum Wire or Quantum Dot.

The first contact electrode 106 may be formed on the first semiconductor layer 102, and the second contact electrode 107 may be formed on the second semiconductor layer 104. The first contact electrode 106 and/or the second contact electrode 107 may include one or more layers, and may be formed of various conductive materials including conductive oxides and conductive polymers.

The plurality of micro-LEDs (ML) formed on the growth substrate 101 may be cut along a cutting line using a laser or the like or be separated into individual micro-LEDs (ML) using an etching process. By a laser lift-off process, the plurality of micro-LEDs (ML) may be put into a state of being separable from the growth substrate 101.

In FIG. 1, ‘P’ indicates a pitch distance between the micro-LEDs (ML), ‘S’ indicates a separation distance between the micro-LEDs (ML), and ‘W’ indicates a width of the micro-LED (ML). In FIG. 1, it is illustrated that the micro-LED (ML) has a circular cross-sectional shape, but is limited to this shape. The micro-LED (ML) has a cross-sectional shape other than the circular cross-sectional shape, such as a rectangular cross-sectional shape, according to a method for manufacturing the micro-LED (ML) on the growth substrate 101.

2. Step of Mounting the Micro-LED on the Circuit Substrate

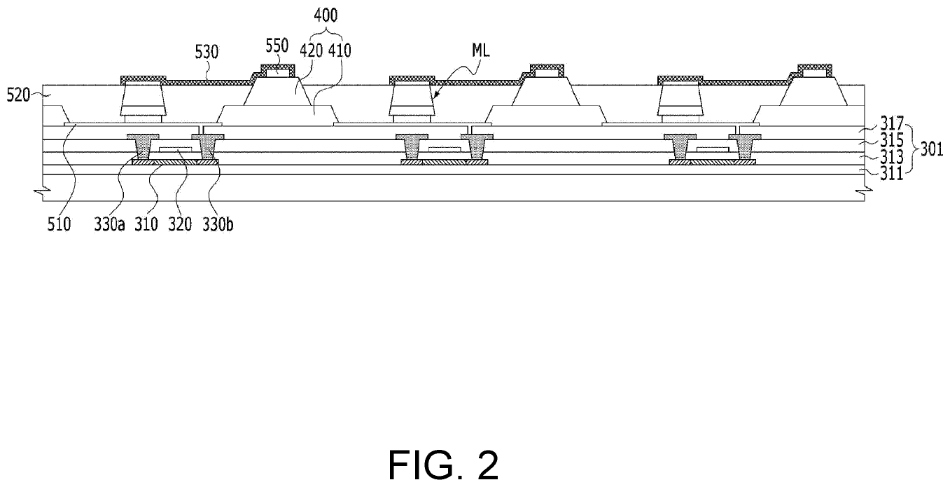

FIG. 2 is a view illustrating a micro-LED structure formed as a result of being transported and mounted to the circuit substrate by the transfer head according to the preferred embodiment of the present invention.

A circuit substrate 301 may be formed of various materials. For example, the circuit substrate 301 may be formed of a transparent glass material having SiO₂ as a main component. However, the circuit substrate 301 is not necessarily limited to this material and may be formed of a transparent plastic material and thus may have the plasticity. The plastic material may be an organic material selected from a group consisting of polyethersulphone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (TAC), and cellulose acetate propionate (CAP), which are insulating organic materials.

In the case of an image of a bottom emission type that is realized in the direction of the circuit substrate 301, the circuit substrate 301 needs to be formed of a transparent material. However, in the case of an image of a top emission type that is realized in the opposite direction of the circuit substrate 301, the circuit substrate 301 does not necessarily need to be formed of a transparent material. In this case, the circuit substrate 301 may be formed of metal.

In a case where the circuit substrate 301 is formed of metal, the circuit substrate 301 may include one or more materials selected from a group consisting of iron, chromium, manganese, nickel, titanium, molybdenum, stainless steel (SUS), Invar alloy, Inconel alloy, and Kovar alloy, but is not limited to these materials.

The circuit substrate 301 may include a buffer layer 311. The buffer layer 311 may provide a flat surface and may block penetration by a foreign material or moisture. For example, the buffer layer 311 may contain an inorganic material, such as silicon oxide, silicon nitride, silicon oxynitride, aluminum oxide, aluminum nitride, titanium oxide, or titanium nitride, or an organic material, such as polyimide, polyester, acrylic, and may be formed as a complex layer in which a plurality of layers formed of these materials are stacked on top of each other.

A thin film transistor TFT may include an active layer 310, a gate electrode 320, a source electrode 330a, and drain electrode 330b.

A thin film transistor TFT of a top gate type in which the active layer 310, the gate electrode 320, the source electrode 330a, and the drain electrode 330b are sequentially formed will be described below. However, the present embodiment is not limited to the thin film transistor TFT of a top gate type and may employ various types of thin film transistors TFT, such as a thin film transistor TFT of a bottom gate type.

The active layer 310 may include, for example, amorphous silicon or polycrystalline silicon. However, the present embodiment is not limited to these materials, and the active layer 310 may contain various materials. As a selective embodiment, the active layer 310 may contain an organic semiconductor material or the like.

As another selective embodiment, the active layer 310 may contain an oxide semiconductor material. For example, the active layer 310 may include an oxide of a material selected from among metal elements, such as zinc (Zn), indium (In), gallium (Ga), tin (Sn), cadmium (Cd), and germanium (Ge), in Groups 12, 13, and 14, and combinations of these elements.

A gate insulating film 313 is formed on top of the active layer 310. The gate insulating film 313 serves to insulate the active layer 310 and the gate electrode 320 from each other. The gate insulating film 313 may be formed as a multi- or single-layer film formed of an inorganic material, such as silicon oxide and/or silicon nitride.

the gate electrode 320 is formed on top of the gate insulating film 313. The gate electrode 320 may be connected to a gate line (not illustrated) along which an on/off signal is applied to the thin film transistor TFT.

the gate electrode 320 may be formed of a low-resistance metal material. The gate electrode 320 may be formed as a single layer or a multi-layer that is formed of, for example, one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), considering the adherence to an adjacent layer, the surface flatness of a stacked layer, the forming property, and the like

An inter-layer insulation film 315 is formed on top of the gate electrode 320. The inter-layer insulation film 315 insulates the source electrode 330a, the drain electrode 330b, and the gate electrode 320 from each other. The inter-layer insulation film 315 may be formed as a multi- or single-layer film formed of an inorganic material. Examples of the inorganic material may include a metal oxide and a metal nitride and, specifically, may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), zinc oxide (ZrO₂), and the like.

The source electrode 330a and the drain electrode 330b are formed on top of the inter-layer insulation film 315. The source electrode 330a and the drain electrode 330b each are formed as a single layer or a multi-layer that is formed of one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu). The source electrode 330a and the drain electrode 330b are connected to a source region and a drain region, respectively, of the active layer 310.

A planarization layer 317 is formed on top of the thin film transistor TFT. The planarization layer 317 is formed in such a manner as to cover the thin film transistor TFT and thus planarizes a stepped upper surface resulting from forming the thin film transistor TFT. The planarization layer 317 may be formed of a single- or multi-layer film formed of an organic material. Examples of the organic material may include common universal polymers, such as polymethylmethacrylate (PMMA) and polystyrene (PS), polymer derivatives having phenolic-based groups, acrylic-based polymers, imide-based polymers, aryl ether-based polymers, amide-based polymers, fluorine-based polymers, p-xylene-based polymers, vinyl alcohol-based polymers, blends of these polymers, and the like. In addition, the planarization layer 317 may be formed as a complex layer in which an inorganic insulating film and an organic insulating film are stacked on top of each other.

A first electrode 510 is positioned on top of the planarization layer 317. The first electrode 510 may be electrically connected to the thin film transistor TFT. Specifically, the first electrode 510 may be electrically connected to the drain electrode 330b through a contact hole formed in the planarization layer 317. The first electrode 510 may have various shapes. For example. The first electrode 510 may be formed to an island-like shape by patterning. A bank layer 400 defining a pixel region may be arranged on top of the planarization layer 317. The bank layer 400 may include an accommodation concave region in which the micro-LED (ML) is to be accommodated. As one example, the bank layer 400 may include a first bank layer 410 in which the accommodation concave region is formed. A height of the first bank layer 410 may be determined by a height of the micro-LED (ML) and a field of view. The size (width) of the accommodation concave region may be determined by resolution, pixel density, and the like of a display device. In one implementation example, the first bank layer 410 may have a greater height than the micro-LED (ML). The accommodation concave region may have a rectangular cross-sectional shape, but the embodiments of the present invention are not limited to this shape. The accommodation concave region may have various cross-sectional shapes including polygonal, rectangular, circular, conical, oval, and triangular cross-sectional shapes and the like.

The bank layer 400 may further include a second bank layer 420 on top of the first bank layer 410. The first bank layer 410 and the second bank layer 420 have different heights. The second bank layer 420 may have a smaller width than the first bank layer 410. A conductive layer 550 may be arranged on top of the second bank layer 420. The conductive layer 550 may be arranged in a direction parallel with a data line or a scan line and may be electrically to the second electrode 530. However, the present invention is not limited to this arrangement. The conductive layer 550 may be arranged on top of the first bank layer 410 without arranging the second bank layer 420. Alternatively, the second electrode 530 may be formed, as a common electrode common to pixels P, on the entire substrate 301 without arranging the second bank layer 420 and a conductive layer 500. The first bank layer 410 and the second bank layer 420 may include a material absorbing at least one portion of light, a light reflecting material, or a light scattering material. The first bank layer 410 and the second bank layer 420 may include a translucent or opaque insulating material for visible light (for example, light in a wavelength range of 380 nm to 750 nm).

As one example, the first bank layer 410 and the second bank layer 420 each may be formed of: thermoplastic resin, such as polycarbonate (PC), polyethyleneterephthalate (PET), polyethersulfone, polyvinylbutyral, polyphenylene ether, polyamide, polyetherimide, norbornene system resin, methacrylic resin, or annular polyolefin-based resin; thermoset resin, such as epoxy resin, phenolic resin, urethane resin, acrylic resin, vinyl ester resin, imide-based resin, urethane-based resin, urea resin, or melamine resin; or an organic insulating material, such as polystyrene, polyacrylonitrile, or polycarbonate. However, the first bank layer 410 and the second bank layer 420 each are not limited to these materials.

As another example, the first bank layer 410 and the second bank layer 420 each may be formed of an inorganic insulating material, such as an inorganic oxide or nitride, such as SiOx, SiNx, SiNxOy, AlOx, TiOx, TaOx, or ZnOx. However, the first bank layer 410 and the second bank layer 420 each are not limited to these materials. In one implementation example, the first bank layer 410 and the second bank layer 420 each may be formed of an opaque material, such as a black matrix material. Examples of the insulating black matrix material may include: resin or paste including organic resin, glass paste and black pigment; metal particles, for example, nickel, aluminum, molybdenum and alloys thereof; a metal oxide particle (for example, a chromium oxide); and a metal nitride particle (for example, a chromium nitride). In a modification example, the first bank layer 410 and the second bank layer 420 may be a distributed Bragg reflector (DBR) having a high reflectivity or a mirror reflector formed of metal.

The micro-LED (ML) is arranged on the accommodation concave region. The micro-LED (ML) may be electrically connected in the first electrode 510 in the accommodation concave region.

The micro-LED (ML) emits light having wavelengths for red, green, blue, white, and the like. It is also possible to realize white light using a fluorescent material or by combining colors. An individual micro-LED (ML) or a plurality of micro-LEDs (ML) may be picked from the growth substrate 101 by the transfer head according to the embodiment of the present invention from being transferred to the circuit substrate 301 and then may be accommodated in the accommodation concave region of the circuit substrate 301.

The micro-LED (ML) includes a p-n diode, the first contact electrode 106 arranged in one side of the p-n diode, and the second electrode 107 positioned in the opposite direction of the first contact electrode 106. The first contact electrode 106 may be in contact with the first electrode 510, and the second electrode 107 may be in contact with the second electrode 530.

The first electrode 510 may include a reflective film formed of Ag, Mg, Al, Pt, Pd, Au, Ni, Nd, Ir, Cr, a compound of these, or the like, and a transparent or translucent electrode formed on top of the reflective film. The transparent or translucent electrode may include at least one selected from a group consisting of indium tin oxide (ITO), indium zinc oxide (IZO), zinc oxide (ZnO), indium oxide (In₂O₃), indium gallium oxide (IGO), and aluminum zinc oxide (AZO).

A passivation layer 520 surrounds the micro-LED (ML) in the accommodation concave region. The passivation layer 520 occupies a space between the bank layer 400 and the micro-LED (ML), and thus covers the accommodation concave region and the first electrode 510. The passivation layer 520 may be formed of an organic insulating material. For example, the passivation layer 520 may be formed of acrylic, poly (methyl methacrylate) (PMMA), benzocyclobutene (BCB), polyimide, acrylate, epoxy, or polyester, but is not limited to these materials.

The passivation layer 520 is formed to a height at which an upper portion of the micro-LED (ML), for example, the second electrode 107, is not covered, and thus the second electrode 107 is exposed. The second electrode 530 electrically connected to the exposed second electrode 107 of the micro-LED (ML) may be formed on top of the passivation layer 520.

The second electrode 530 may be arranged on top of the micro-LED (ML) and the passivation layer 520. The second electrode 530 may be formed of a transparent conductive material, such as ITO, IZO, ZnO, or In₂O₃.

A vertical-type micro-LED (ML) in which the first and second electrodes 106 and 107 are arranged on upper and lower surfaces, respectively, of the micro-LED (ML) are described above for illustrative purposes. However, according to the preferred embodiment of the present invention, a flip-type or lateral-type micro-LED (ML) in which the first and second electrodes 106 and 107 are both arranged on any one of the upper and lower surfaces of the micro-LED (ML) may be provided. In this case, the first and second electrodes 510 and 530 may be correspondingly arranged.

3. Transfer Head Transferring the Micro-LED

The transfer head is a component that serves to absorb the micro-LED on a first substrate 101 using an absorption force and then transferring the absorbed micro-LED to a second substrate. The first substrate here is a substrate from which the transfer head absorbs the micro-LED, and may be the growth substrate 101 or a temporary substrate. The second substrate is a substrate to which the micro-LED absorbed from the first substrate is transferred and may be a temporary substrate, the circuit substrate 301, a target substrate, or a display substrate. In addition, the absorption forces here include a vacuum suction force, an electrostatic force, a magnetic force, a van der Waals force, and the like. Therefore, the transfer head for a micro-LED display according to the present invention may absorb the micro-LED (ML) using the adsorption force, such as a vacuum suction force, an electrostatic force, a magnetic force, or a van der Waals force. The transfer head, if capable of generating a vacuum suction force, an electrostatic force, a magnetic force, or a van der Waals force, is not limited in structure. In this case, the transfer head is formed in such a manner as to have a suitable structure suitable according to the absorption force in use, and thus may efficiently absorb the micro-LED (ML).

Embodiments of the transfer head that use the vacuum suction force, among the absorption forces, will be described below. However, it is noted that, the transfer heads described in steps other than in a transfer step, that is, before and after the transfer step, include the transfer head that uses the electrostatic force, the magnetic force, the van der Waals force, or the like in addition to the vacuum suction force.

3-1. First Embodiment of the Transfer Head

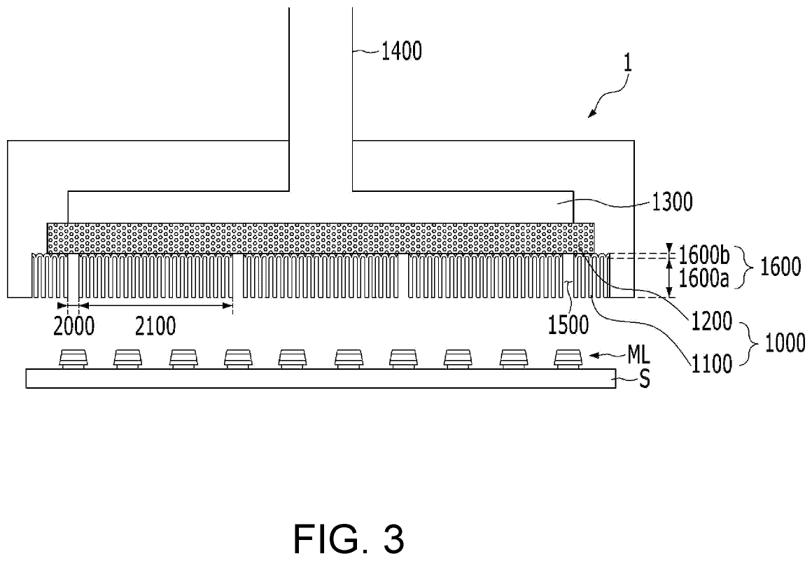

FIG. 3 is a view illustrating a preferred first embodiment of a transfer head 1 according to the present invention.

As illustrated in FIG. 3, a transfer head 1 according to the present invention includes a porous member 1000 that has pores. The transfer head 1 transports the micro-LED (ML) from the first substrate to the second substrate by applying vacuum the porous member 1000 or releasing the applied vacuum.

The porous member 1000 is configured to include a material containing a plurality of pores inside. The material has a structure in which pores are arranged in order or randomly, and may be configured to include powder, a thin film/thick film, and a bulk form that have a pore density of approximately 0.2 to 0.95. Pores of the porous member 1000 are divided by size into micro-pores having a diameter of 2 nm or smaller, meso pores having a diameter of 2 to 50 nm, and macro-pores having a diameter of 50 nm or larger. The porous member 1000 includes at least some of these pores. Materials of the porous member 1000 are possibly divided by constituent elements into organic materials, inorganic (ceramic) materials, metal materials, and hybrid-type porous materials. The porous member 1000 includes an anodic oxide film 1600 of which pores are formed in a predetermined arrangement. The porous member 1000 may have a power form, a coating-film form, or a bulk form. The power may have various forms, such as a sphere, a hollow sphere, a fiber, and a tube. The power may be used as is. It is also possible to manufacture a coating film and a bulk form using the power as a starting material.

When internal spaces in pores are randomly present and are connected to each other in a manufacturing process, such as sintering and foaming, the pores are arbitrary in form, and thus the pores in the porous member 1000 have an arbitrary pore structure. In a case where the pores in the porous member 1000 have a random pore structure, a plurality of pores are connected to each other inside the porous member 1000, and thus an airflow path is formed in the porous member 1000 in a manner that passes therethrough from top to bottom.

In a case where the pore in the porous member 1000 has a vertical-pore structure, a pore in the vertical form forms a through-hole in the inside of the porous member 1000 in a manner that passes through the porous member 1000 from top to bottom. Thus, the airflow path is formed. The vertical-pore structure here means that a pore is formed in the upward-downward direction in the porous member 1000 and does not mean that the pore is completely vertical. Thus, at least one of the top and bottom of the pore may be closed. The pore may be open at the top and the bottom. A vertical pore may be formed when the porous member is manufactured. A separate hole may be drilled after the porous member is manufactured. The vertical pore may be formed in the entire porous member 1000 and may be formed in only one portion of the porous member 1000.

The arbitrary pore means that a pore is randomly oriented, and the vertical pore means that a pore is oriented in the upward-downward direction.

The porous member 1000 employs a double structure and thus is configured to include first and second porous members 1100 and 1200.

The second porous member 1200 is provided on top of the first porous member 1100. The first porous member 1100 includes an absorption member 1100 in such a manner as to be configured to serve to vacuum-absorb the micro-LED (ML). The second porous member 1200 is positioned between a vacuum chamber 1300 and the first porous member 1100 and serves to transfer vacuum pressure of the vacuum chamber 1300 to the first porous member 1100 and to support the first porous member 1100. The second porous member 1200 may include support member 1200 supporting the absorption member 1100.

The first and second porous members 1100 and 1200 may have different porosity properties. For example, the first and second porous members 1100 and 1200 may have different properties in terms of an arrangement of the pores, sizes, and the like of the pores and in terms of a material, a shape, and the like of the porous member 1000.

In terms of the arrangement of the pores, in the first porous member 1100, pores may be uniformly arranged, and in the second porous member 1200, pores may be randomly arranged. In terms of the sizes of the pores, one of the first and second porous members 1100 and 1200 may have larger-sized pores than the other one. The size of the pore here may be an average size of the pores and may be the greatest size among the sizes of the pores. In terms of the material of the porous member 1000, one of the first and second porous members 1100 and 1200 may be formed of one selected from among an organic material, an inorganic (ceramic) material, a metal material, and a hybrid porous material, and the other may be formed of a material other than the selected material, among the organic material, the inorganic (ceramic) material, the metal material, and the hybrid porous material.

In terms of the internal pores of the porous member 1000, the first and second porous members 1100 and 1200 may have different arrangements of internal pores. Specifically, the first porous member 1100 may be a porous member having vertical pores that are uniformly arranged. The first porous member 1100 is configured with a porous member having the vertical pore and therefore is configured to include the absorption member 1100 serving to absorb the micro-LED (ML). The absorption members 1100 may include: an absorption member 1100 that is provided as the anodic oxide film 1600 and has a pore formed during a manufacturing process or has the vertical pore through the use of an absorption hole formed separately from the pore; an absorption member 1100 that is provided as a mask 3000 in which an opening portion 3000a is formed and has the vertical pore through the use of the opening portion 3000a; an absorption member 1100 in which the vertical pore is formed through a laser process; and an absorption member 1100 in which the vertical pore is formed by etching. In this manner, the absorption member 1100 may be variously configured in such a manner as to employ a structure that has a vertical pore. The second porous member 1200 may be a porous member having arbitrary pores that are randomly arranged. The second porous member 1200 may include the support member 1200 supporting the absorption member 1100 as configured.

In this manner, the first and second porous members 1100 and 1200 are configured to have different arrangements and sizes of the pores and different materials and internal pores. Thus, the transfer head 1 may have various functions. Furthermore, the first and second porous members 1100 and 1200 may perform functions complementary to each other.

The number of the first and second porous members 1100 and 1200 is limited to 2, but the number of the porous member is not limited to 2. The porous members, if capable of performing functions complementary to each other, are not limited in number. Two or more porous members may be provided. The porous member 1000 is illustrated and will be described below as being configured to have a double structure that includes the first and second porous members 1100 and 1200.

The second porous member 1200 may be a porous member having arbitrary pores, and may be configured as a porous support serving to support the first porous member 1100. The second porous member 1200, if capable of supporting the first porous member 1100, is not limited in material. The second porous member 1200 may be configured as a stiff porous support effective in preventing the center portion the first porous member 1100 from being warped. For example, the second porous member 1200 may be formed of a ceramic material. The second porous member 1200 may serve not only to prevent the first porous member 1100 provided as a thin film type from being deformed due to the vacuum pressure, but also to distribute the vacuum pressure of the vacuum chamber 1300 and thus transfer the distributed vacuum pressure to the first porous member 1100. The vacuum pressure distributed or spread by the second porous member 1200 is transferred to an absorption region of the first porous member 1100 and thus is used for absorbing the micro-LED (ML). Furthermore, the vacuum pressure is transferred to a non-absorption region of the first porous member 1100 and thus is used for the second porous member 1200 to absorb the first porous member 1100.

In addition, the second porous member 1200 may be a porous buffer for buffering shock occurring when the first porous member 1100 and the micro-LED (ML) are brought into contact with each other. The second porous member 1200, if capable of buffering the shock to the first porous member 1100, is not limited in material. In a case where the first porous member 1100 is brought into contact with the micro-LED (ML) and vacuum-absorbs the micro-LED (ML), the first porous member 1100 may collide with the micro-LED (ML) and thus damage the micro-LED (ML). The second porous member 1200 may be configured as a soft porous buffer that contributes to preventing this collision and damage. For example, the second porous member 1200 may be formed of a porous elastic material, such as a sponge.

The first porous member 1100 vacuum-absorbing the micro-LED (ML) includes an absorption region 2000 that absorbs the micro-LED (ML) and a non-absorption region 2100 that does not absorb the micro-LED (ML). The absorption region 2000 is a region to which the vacuum pressure of the vacuum chamber 1300 is transferred and absorbs the micro-LED (ML). The non-absorption region 2100 is a region to which the vacuum pressure of the vacuum chamber 1300 is not transferred and does not absorb the micro-LED (ML).

The non-absorption region 2100 may be realized by forming a cover portion on at least one portion of a surface of the first porous member 1100. The cover portion is formed in such a manner as to cover a pore formed in at least one portion of the surface of the first porous member 1100.

The cover portion, if capable of covering the pore in the surface of the first porous member 1100, is not limited in material, shape, and thickness. It is preferable that the cover portion is additionally formed as photoresist (PR) (including dry film PR), a PDMS material, or a metal material. It is also possible that the covering portion is formed through the use of configuration itself of the first porous member 1100. At this point, regarding the configuration of the first porous member 1100, in a case where the first porous member 1100 described below is configured as the anodic oxide film 1600, the cover portion is a barrier layer or a metal base material.

Each absorption region 2000 may be formed in such a manner that a size of an area in the horizontal direction thereof is smaller than a size of an area in the horizontal direction of an upper surface of the micro-LED (ML). Accordingly, vacuum leakage is prevented while vacuum-absorbing the micro-LED (ML). Thus, vacuum-absorbing may be easily performed.

The absorption region 2000 may be formed suitably for a configuration of the first porous member 1100. Specifically, in a case where the first porous member 1100 is the anodic oxide film 1600 including the barrier layer within which pores are not formed and the porous layer within which pores are formed, at least one portion of the barrier layer may be removed, and thus the absorption region 2000 may be formed only with the porous layer within which a plurality of pores is formed. Alternatively, at least one portion of the anodic oxide film 1600 may be all etched in the upward-backward direction, and thus an absorption hole 1500 having a greater width than the pore in the porous layer may be formed, thereby forming the absorption region 2000.

Alternatively, the first porous member 1100 may be configured as a wafer, such as sapphire or silicon wafer, and the absorption region 2000 may be formed by a vertical pore formed by etching.

Alternatively, in a case where the first porous member 1100 is the absorption member 1100 that is provided as the mask 3000 in which the opening portion 3000a having a predetermined pitch distance is formed, the absorption region 2000 may be formed by an opening-portion forming region in which the opening portion 3000a in the mask 3000 is formed. At this point, the mask 3000, if configured in such a manner as to have a thin film form, is not limited in material.

The absorption member 1100 may be divided into the absorption region 2000 absorbing the micro-LED (ML) that is a transfer target on a first substrate 101, and the non-absorption region 2100 that does not absorb the micro-LED (ML) that is a non-transfer target on the first substrate 101.

The support member 1200 may be provided on top of the absorption member 1100 and may be formed of a porous material. As one example, the support member 1200 may be formed of a porous material having arbitrary pores.

The transfer head 1 configured to include the absorption member 1100 and the support member 1200, which are as described above, may selectively absorb the micro-LED (ML) on the first substrate 101 and may transfer the selected micro-LED (ML) to a second substrate 301.

The absorption member 1100 may be formed of at least one material selected from among the anodic oxide film 1600, a wafer substrate, an invar, a metal, a non-metal, a polymer, a sheet of paper, a photoresist, and PDSM.

In a case where the absorption member 1100 is formed of a metal material, the absorption member 1100 has the advantage of preventing static electricity from occurring when transferring the micro-LED (ML). In a case where the absorption member 1100 is formed of a non-metal, the absorption member 1100 has the advantage of minimizing an effect that the absorption member 1100 formed of a material having a metal property has on the micro-LED (ML) having a metal property. In a case where the absorption member 1100 is formed of a material, such as ceramic or glass quartz, the absorption member 1100 is advantageous in securing the rigidity and has a low thermal expansion coefficient. Thus, the occurrence of a positional error due to thermal deformation of the absorption member 1100 can be minimized when transferring the micro-LED (ML). In a case where the absorption member 1100 is formed of a material, such as silicon or PDMS, although a lower surface of the absorption member 1100 is brought into direct contact with an upper surface of the micro-LED (ML), the absorption member 1100 serves to buffer shock. Thus, damage due to a collision with the micro-LED (ML) can be minimized. In a case where the absorption member 1100 is formed of a resin material, the absorption member 1100 has the advantage of being easily manufactured.

The absorption member 1100 may be supported by the support member 1200 that has an arbitrary pore communicating with the absorption region 2000 in such a manner that air flows.

The support member 1200 absorbs the non-absorption region 2100 of the absorption member 1100 using the vacuum suction force, and thus supports the absorption member 1100. Furthermore, the support member 1200 also communicates with the absorption region 2000 of the absorption member 1100 in such a manner that air flows, and thus may absorb the micro-LED (ML) using the absorption region 2000.

The first embodiment of the transfer head 1 is configured to include the absorption member 1100, the support member 1200, and the vacuum chamber 1300, which are as described above. The vacuum pressure of the vacuum chamber 1300 is decreased by the porous material of the support member 1200, and then is transferred to the absorption region 2000 of the absorption member 1100. Thus, the micro-LED (ML) may be absorbed. In this case, the vacuum pressure of the vacuum chamber 1300 is transferred to the non-absorption region 2100 of the absorption member 1100 by the porous material of the support member 1200. Thus, the absorption member 1100 may be absorbed.

The first embodiment of the transfer head 1 according to the present invention may be configured to include the absorption member 1100 that is provided as the anodic oxide film 1600 having a vertical pore, and the support member 1200 that has an arbitrary pore and supports the absorption member 1100.

A barrier layer 1600b formed when manufacturing the anodic oxide film 1600 is removed, and thus the top and bottom of a vertical pore communicate with each other in the upward-downward direction. As a result, the absorption region 2000 may be formed. Alternatively, the absorption region 2000 may be formed by the absorption hole 1500 that has a greater width than the vertical pore formed when manufacturing the anodic oxide film 1600 and that is formed in such a manner as to be open at the top and bottom in the upward-downward direction.

The non-absorption region 2100 may be formed by the cover portion covering at least one of the top and bottom of the vertical pore formed when manufacturing the anodic oxide film 1600. The barrier layer 1600b formed when manufacturing the anodic oxide film 1600 may be configured as the cover portion.

The absorption member 1100 is provided as the anodic oxide film 1600 having a vertical pore. The absorption region 2000 is configured that absorbs the micro-LED (ML) with the vacuum suction force through the absorption hole 1500 that has a greater width than the vertical pore. The non-absorption region 2100 is configured that does not absorb the micro-LED (ML) through the cover portion closing at least one of the top and bottom of the vertical pore.

First, the anodic oxide film 1600 providing the absorption member 1100 means a film that is formed by anodically oxidizing a metal that is a base material. The pore means a hole that is formed while the metal is anodically oxidized and thus the anodic oxide film 1600 is formed. For example, in a case where the metal that is a base material is aluminum (Al) or an aluminum alloy, when the base material is anodically oxidized, the anodic oxide film 1600 formed of anodic aluminum oxide (Al₂O₃) is formed on a surface of the base material. The anodic oxide film 1600 described above is divided into the barrier layer 1600b within which a pore is not formed, and a porous layer 1600a within which pores are formed. The barrier layer 1600b is positioned on top of the base material, and the porous layer 1600a is positioned on top of the barrier layer 1600b. In this manner, the anodic oxide film 1600 having the barrier layer 1600b and the porous layer 1600a is formed on a surface of the base material, and the base material is removed. Then, on the anodic oxide film 1600 formed of anodic aluminum oxide (Al₂O₃) remains.

The anodic oxide film 1600 has pores that are formed to have a uniform diameter and a vertical form and are regularly arranged. Therefore, when the barrier layer 1600b is removed, the pore has a structure that is open at the top and bottom in the vertical direction. Accordingly, it is easy to form the vacuum pressure in the vertical direction.

The anodic oxide film 1600 includes the absorption region 2000 that vacuum-absorbs the micro-LED (ML) and the non-absorption region 2100 that does not absorb the micro-LED (ML). The barrier layer 1600b formed when manufacturing the anodic oxide film 1600 is removed, and thus the vertical pore is open at the top and bottom in the upward-downward direction. As a result, the absorption region 2000 of the anodic oxide film 1600 is formed.

Thus, the absorption member 1100 is provided as the anodic oxide film 1600 having a vertical pore and is divided into the absorption region 2000 that absorbs the micro-LED (ML) using vacuum suction force through the vertical pore, and the non-absorption region 2100 that does not absorb the micro-LED (ML) because at least one of the top and bottom of the vertical pore is closed.

The support member 1200 is provided on top of the anodic oxide film 1600, and the vacuum chamber 1300 is provided on top of the support member 1200. According to operation of a vacuum port supplying vacuum, the vacuum chamber 1300 serves to apply vacuum, which is to be provided to the support member 1200 and the anodic oxide film 1600, to a plurality of pores in the vertical form in the absorption member 1100 or serves to release the vacuum. When absorbing the micro-LED (ML), the vacuum applied to the vacuum chamber 1300 is transferred to the plurality of pores in the anodic oxide film 1600, and thus a vacuum absorption force to be exerted on the micro-LED (ML) is provided.

The absorption member 1100 may selectively transfer the micro-LED (ML) or simultaneously transfer the micro-LEDs (ML) according to a pitch distance between the absorption regions 2000.

The absorption region 2000 of the absorption member 1100 may be formed by the porous layer 1600a within which vertical pores are formed by removing at least one portion of the barrier layer 1600b. Alternatively, as illustrated in FIG. 3, the absorption region 2000 may be formed by the absorption hole 1500 that has a greater width than the vertical pore formed when manufacturing the anodic oxide film 1600 and that is formed in such a manner as to be open at the top and bottom in the upward-downward direction.

In this manner, the absorption region 2000 may be configured as the porous layer 1600a by removing the barrier layer 1600b. Alternatively, the absorption region 2000 may be configured by both the barrier layer 1600b and the porous layer 1600a. FIG. 3 is a view illustrating the absorption region 2000 configured by removing both the barrier layer 1600b and the porous layer 1600a.

As illustrated in FIG. 3, in the first embodiment, the absorption region 2000 is illustrated and described as being formed by the absorption hole 1500 that is formed in the anodic oxide film 1600 in a manner that passes therethrough from top to bottom.

In addition to the pore in the anodic oxide film 1600 that occurs naturally, the absorption hole 1500 is formed in the absorption member 1100. The absorption hole 1500 is formed in the anodic oxide film 1600 in a manner that passes from the upper surface thereof to the lower surface thereof. The absorption hole 1500 is formed in such a manner as to have a greater width than the pore. A vacuum absorption area for the micro-LED (ML) can be increased much more, in the configuration in which the absorption hole 1500 is formed in such a manner as to have a greater width than the pore, than in a configuration in which the absorption region 2000 that absorbs the micro-LED (ML) is formed and the micro-LED (ML) is absorbed only with the pore.

The anodic oxide film 1600 and the pore, which are described above, are formed, and then the anodic oxide film 1600 is etched in the vertical direction. As a result, the absorption hole 1500 may be formed. Since the absorption hole 1500 is formed by etching, the absorption hole 1500 may be easily formed without any damage to a lateral surface of the pore. Accordingly, the occurrence of damage to the absorption hole 1500 can be prevented from occurring.

The non-absorption region 2100 may be a region where the absorption hole 1500 is not formed. The non-absorption region 2100 may be a region where the pore is closed at least one of the top and bottom in the upward-downward direction. The non-absorption region 2100 may be formed by the cover portion that closes at least one of the top and bottom of the vertical pore formed when manufacturing the anodic oxide film 1600. In the case of the first embodiment, the cover portion may be the barrier layer 1600b that is formed when manufacturing the anodic oxide film 1600. The barrier layer 1600b may be formed on at least one portion of upper and lower surfaces of the anodic oxide film 1600 and may function as the cover portion.

As illustrated in FIG. 3, the non-absorption region 2100 in the first embodiment may be formed in such a manner that one of the top and bottom of the pore in the vertical form is closed by the barrier layer 1600b when manufacturing the anodic oxide film 1600.

FIG. 3 illustrates that the barrier layer 1600b is positioned as an upper portion of the anodic oxide film 1600 and that the porous layer 1600a having pores is positioned as a lower portion thereof. However, the anodic oxide film 1600 illustrated in FIG. 3 may be turned upside down in such a manner that the barrier layer 1600b is positioned as the lower portion of the anodic oxide film 1600. In this manner, the non-absorption region 2100 may be configured.

One of the top and bottom of the pore in the non-absorption region 2100 is described above as being closed by the barrier layer 1600b. However, a coating layer may be added to the other thereof that is not closed by the barrier layer 1600b. Thus, the non-absorption region 2100 may be configured in such a manner that the top and bottom of the pore are both closed. Regarding the configuration of the non-absorption region 2100, a configuration in which upper and lower surfaces of the anodic oxide film 1600 are both closed has an advantage over a configuration in which one of the upper and lower surfaces of the anodic oxide film 1600 is closed, in that the likelihood of a foreign material remaining in the pore in the non-absorption region 2100 is decreased.

As described above, the absorption region 2000 of the absorption member 1100 may be formed by the porous layer 1600a within which vertically pores are formed by removing at least one portion of the barrier layer 1600b. Alternatively, the absorption region 2000 may be formed by the absorption hole 1500 that has a greater width than the vertical pore formed when manufacturing the anodic oxide film 1600 and that is formed in such a manner as to be open at the top and bottom in the upward-downward direction.

As one example, the absorption region 2000, as illustrated in FIG. 3, may be formed in such a manner that a pitch distance in the column direction (the x-direction) between the absorption regions 2000 is three times a pitch distance in the column direction (the x-direction) between the micro-LEDs (ML) on a substrate S. The substrate S here may mean the first substrate (for example, the growth substrate 101 or a temporary substrate).

Specifically, the transfer head 1 is formed in such a manner that the pitch distance in the x-direction between the absorption regions 2000 is three times the pitch distance in the x-direction between the micro-LEDs arranged on the first substrate and that a pitch distance in the y-direction between the absorption regions 2000 is the same as a pitch distance in the y-direction between the micro-LEDs arranged on the first substrate. Thus, the micro-LED (ML) arranged on the first substrate may be selectively absorbed. With the configuration as described above, the transfer head 1 may vacuum-absorb only the micro-LED (ML) in a column corresponding to the multiple of three times the pitch distance on the substrate S and may transport the absorbed micro-LED (ML). In this case, the transfer head 1 may absorb the micro-LED (ML) that is positioned at the first, fourth, seventh, and tenth positions starting from the left side of FIG. 3.

Alternatively, the transfer head (1) is formed in such a manner that the pitch distance in the x-direction between the absorption regions 2000 is three times the pitch distance in the x-direction between the micro-LEDs arranged on the first substrate and that the pitch distance in the y-direction between the absorption regions 2000 is three times the pitch distance in the y-direction between the micro-LEDs arranged on the first substrate. Thus, the micro-LED (ML) arranged on the first substrate may be selectively absorbed.

Alternatively, the transfer head 1 is formed in such a manner that a pitch distance in the diagonal direction between the absorption regions 2000 is the same as a pitch distance in the diagonal direction between the micro-LEDs (ML) arranged on the first substrate. Thus, the transfer head 1 may selectively absorb the micro-LED (ML) arranged on the first substrate.

In this manner, the pitch distances in the column direction (the x-direction) and in the row direction (the y-direction) of the absorption regions 2000 are not limited to the one in the accompanying drawings. The transfer head 1 may be formed in such a manner that the pitch distance in the x-direction between the absorption regions 2000 is an integer multiple of three or more times the pitch distance in the x-direction between the micro-LEDs arranged on the first substrate and that the pitch distance in the y-direction between the absorption regions 2000 is an integer multiple of three or more times the pitch distance in the y-direction between the micro-LEDs arranged on the first substrate. Alternatively, the transfer head 1 may be formed in such a manner as to be suitable for a pixel arrangement, such as one in the diagonal direction on the micro-LED (ML) on the substrate, in which the micro-LED (ML) is transferred to a substrate (for example, a circuit substrate 301 or the second substrate, such as a target substrate or a display substrate).

3-2. Second Embodiment of the Transfer Head

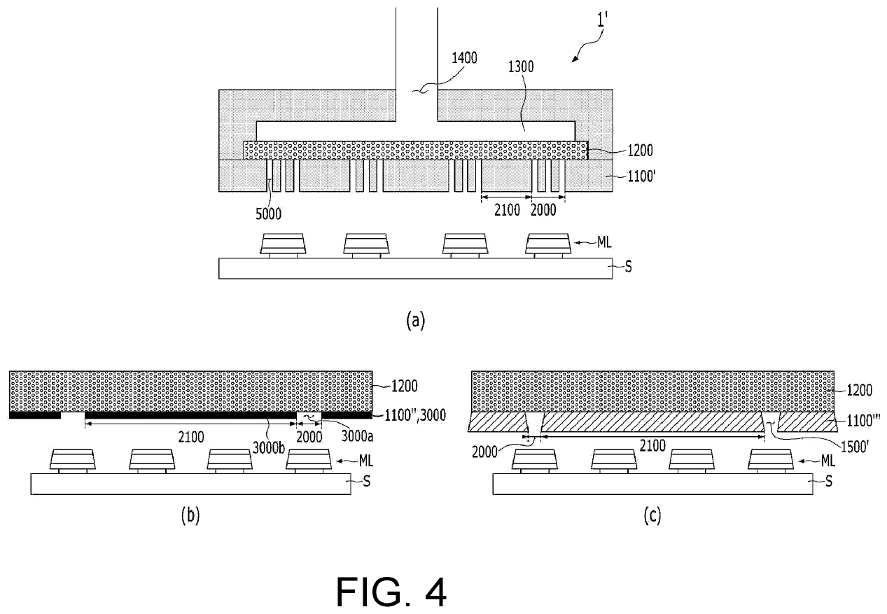

FIG. 4(a) is a view illustrating a second embodiment of transfer head 1′ according to the present invention. The second embodiment is different from the first embodiment in that an absorption member 1100′ is not provided as the anodic oxide film 1600.

The second embodiment may be configured to include an absorption member 1100′ that has a vertical pore formed by etching and the support member 1200 supporting the absorption member 1100′ on an upper surface of the absorption member 1100′. In the absorption member 1100′ in the second embodiment, a through-hole 5000 formed by etching forms one absorption region 2000. In FIG. 4(a), it is illustrated that a plurality of vertically pores constitutes one absorption region 2000. Alternatively, one vertical pore formed by etching may form one absorption region 2000.

The absorption member 1100′ is divided into the absorption region 2000 that is formed as a result of forming the through-hole 5000 and that absorbs the micro-LED (ML) and the non-absorption region 2100 that is formed as a result of not forming the through-hole 5000. The absorption member 1100′ may be formed of a material of a wafer substrate w.

The through-hole 5000 may be a vertical pore formed by etching. The through-hole 5000 is formed in the absorption member 1100′ in a manner that passes therethrough from top to bottom. Thus, the absorption region 2000 may be provided. The through-hole 5000 may perform the same function as the absorption hole 1500 forming the absorption region 2000 of the transfer head in the first embodiment.

The through-hole 5000 may be formed by etching a portion of an upper surface or a low surface of the wafer substrate w in the depth direction. The etching methods here include a wet etching method, a dry etching method, and the like that are usually used in a semiconductor manufacturing process.

The absorption region 2000 of the absorption member 1100′ in the second embodiment is configured as the through-hole 5000. Therefore, the through-hole 5000 for forming the absorption region 2000 is formed by etching, and a plurality of absorption regions 2000 is formed by the same process. Thus, the plurality of absorption regions 2000 may be provided for absorbing the micro-LED (ML) on the substrate S. In this case, the absorption region 2000 is formed in such a manner that an area thereof is smaller than an area in the horizontal direction of the upper surface of the micro-LED (ML). Thus, the vacuum leakage can be prevented.

The absorption regions 2000 including the through-hole 5000 may be formed in such a manner that the pitch distance in the column direction (the x-direction) therebetween is the same as, or an integer multiple of three times the pitch distance in the column direction (the x-direction) between the micro-LEDs arranged on the first substrate and that the pitch distance in the row direction (the y-direction) between the absorption regions 2000 is the same as, or an integer multiple of three times the pitch distance in the row direction (the y-direction) between the micro-LEDs arranged on the first substrate. In FIG. 4(a), as one example, it is illustrated that the absorption regions 2000 are illustrated and described as being formed in such a manner that the pitch distance in the column direction (the x-direction) therebetween is the same as the pitch distance in the column direction (the x-direction) between the micro-LEDs (ML) on the substrate S.

In the second embodiment, the through-holes 5000, each constituting one absorption region 2000, may be formed at a predetermined pitch distance, and pluralities of through-holes 5000 may be formed at a predetermined pitch distance, considering the pitch distance between the absorption regions 2000. In FIG. 4(a), it is illustrated that as one example, one absorption region 2000 is formed as three through-holes 5000. However, the through-holes 5000 constituting the absorption region 2000 are limited in number. However, the absorption region 2000 is formed in such a manner that the area thereof is smaller than the area in the horizontal direction of the upper surface of the micro-LED (ML). Thus, it is preferable that a plurality of through-holes 5000 is formed in such a manner that the area of the absorption region 2000 is smaller than the area in the horizontal direction of the upper surface of the micro-LED (ML).

The support member 1200 supporting the absorption member 1100′ on an upper surface of the absorption member 1100′ may be combined with top of the absorption member 1100′ in the second embodiment. As in the second embodiment, in a case where tens of thousands of through-holes are formed in the wafer substrate w provided in the form of a thin plate by etching and where a support member is provided, there is a high likelihood that the absorption member 1100′ will be broken due to a great vacuum suction force. Therefore, it is necessary to support the absorption member 1100′ using the support member 1200, such as a porous ceramic member.

The vacuum pressure is decreased by an arbitrary pore in the support member 1200, and then is transferred to the through-hole 5000 in the absorption member 1100′. Thus, the transfer head 1′ in the second embodiment may absorb the micro-LED (ML). Furthermore, the vacuum pressure is transferred to the non-absorption region 2100 of the absorption member 1100′ by the arbitrary pore in the support member 1200. The transfer head 1′ may absorb the absorption member 1100′.

3-3. Third Embodiment of the Transfer Head

FIG. 4(b) is an enlarged view illustrating one portion of a porous member constituting a third embodiment of the transfer head. In the third embodiment, the mask 3000 in which the opening portion 3000a is formed is configured as a first porous member. The first porous member in the third embodiment may be an absorption member 1100″ provided as the mask 3000 in which the opening portion 3000a is formed. Constituent elements in the third embodiment, which are different in feature from those in the first embodiment, will be described below. A detailed description of a constituent element that is the same or similar to that in the first embodiment is omitted.

As illustrated in FIG. 4(b), the absorption member 1100″ provided as the mask 3000 may be provided underneath a lower surface of the support member 1200. The opening portions 3000a in the mask 3000 are formed in such a manner as to be spaced apart at a predetermined distance. Thus, that absorption region 2000 absorbing the micro-LED (ML) may be formed. A surface of the mask 3000 in which the opening portion 3000a is not formed may form the non-absorption region 2100 where the micro-LED (ML) is not absorbed.

The opening portions 3000a in the mask 3000 may be formed in such a manner that a pitch distance therebetween is the same as the pitch distance between the micro-LEDs (ML) on the growth substrate 101. Alternatively, the opening portions 3000a may be formed in such a manner as to have a predetermined pitch distance therebetween in order to selectively absorb the micro-LED (ML).

In FIG. 4(b), it is illustrated that in a case where the substrate S is the growth substrate 101, the opening portions 3000a in the mask 3000 are formed in such a manner that the pitch distance therebetween is three times the pitch distance in the column direction (the x-direction) of the micro-LED (ML) on the growth substrate 101. Thus, the transfer head may selectively absorb the first and fourth micro-LEDs (ML) on the substrate S.

The mask 3000 may include the opening portion 3000a and a non-opening region 3000b. The non-opening region 3000b covers one portion of the lower surface of the support member 1200 in which an arbitrary pore is formed, and thus a great vacuum absorption force may be formed in the opening portion 3000a.

A gas flow path is formed in the entire inside of the support member 1200 in which an arbitrary pore is formed, and thus the vacuum absorption force for absorbing the micro-LED (ML) may be formed on the entire lower surface thereof. Therefore, in a case where the mask 3000 is provided a surface of the support member 1200, a portion of the mask 3000 in which the opening portion 3000a is positioned may be substantially the absorption region 2000 that absorbs the micro-LED (ML). In other words, in the third embodiment, the mask 3000 is provided on the lower surface of the support member 1200, and thus the absorption region 2000 that substantially absorbs the micro-LED may be limited. In this case, the opening portion 3000a provided in the mask 3000 may correspond to a vertical pore.

The surface of the mask 3000 in which the opening portion 3000a is not formed serves as a cover portion to cover the pore in the lower surface of the support member 1200. Thus, the vacuum pressure that is formed by being transferred from the vacuum chamber 1300 to the support member 1200 may be increased due to the opening portion 3000a in the mask 3000.

As illustrated in FIG. 4(b), the mask 3000 may be formed in such a manner that an area of the opening portion 3000a therein is smaller than the area in the horizontal direction of the upper surface of the micro-LED (ML). In this case, it is preferable that the mask 3000 is formed of an elastic material. The mask 3000 with this configuration serves to buffer shock to prevent damage to the micro-LED (ML) when the transfer head absorbs the micro-LED (ML).

Specifically, when absorbing the micro-LED (ML), at least one portion of the upper surface of the micro-LED (ML) is brought into contact with at least one portion of the non-opening region 3000b which is formed in the vicinity of the opening portion 3000a in the mask 3000 and in which the opening portion 3000a is not formed, and thus the micro-LED (ML) may be absorbed. In other words, the area in the horizontal direction of the upper surface of the micro-LED (ML), which is as large as an area of the opening portion 3000a in the mask 3000 minus from an area in the horizontal direction of the upper surface of the micro-LED (ML), is brought into contact with an exposed surface of the mask 3000, and thus may be absorbed to the transfer head. A portion brought into direct contact with the micro-LED (ML) is the exposed surface of the mask 3000, and thus the micro-LED (ML) may be absorbed to the transfer head without any damage.

Alternatively, the opening portion 3000a in the mask 3000 may be formed in such a manner that an area thereof is greater than a size of the area in the horizontal direction of the upper surface of the micro-LED (ML). In this case, the vacuum pressure of the second porous member 1200 that is transferred through the vacuum chamber 1300 is formed due to the opening portion 3000a in the mask 3000, and the micro-LED (ML) is absorbed to the lower surface of the support member 1200. Thus, the micro-LED (ML) may be absorbed.

The mask 3000 may be formed of one selected from among an invar material, a metal material, a paper material, and an elastic material (PR, DDMS). However, in a case where the opening portion 3000a described above is formed in such a manner that the area thereof is smaller than the area in the horizontal direction of the upper surface of the micro-LED (ML), the mask 3000 serves to form the absorption region 2000 and to buffer shock. Thus, it is preferable that the mask 3000 is formed of an elastic material.

In a case where the mask 3000 is formed of an invar material, the mask 3000 has a low thermal expansion coefficient. Thus, an interface can be prevented from being warped due to a thermal effect.

Alternatively, in a case where the mask 3000 is formed of a metal material, the opening portion 3000a can be easily formed. Because the metal material is easy to process, the opening portion 3000a can be easily formed in the mask 3000. As a result, the effect of improving the convenience of manufacturing can be achieved. In addition, in a case where the mask 3000 is formed of a metal material, when a metal bonding method is used as a means of boding the micro-LED (ML) to the first contact electrode 106 of the circuit substrate 301, the upper surface of the micro-LED (ML) may be heated through the mask 3000 of the transfer head without applying electric power to the circuit substrate 301. Accordingly, a bonding metal (alloy) may be heated, and the micro-LED (ML) may be bonded to the first contact electrode 106.

Alternatively, the mask 3000 may be formed of a film material. In a case where the transfer head to which the mask 3000 is provided absorbs the micro-LED (ML), a foreign material may be attached to a surface of the mask 3000. The mask 3000 may be reused after cleaning. However, it is inconvenient to perform a cleaning process each time. Therefore, in a case where the mask 3000 is formed of a film material, when a foreign material is attached, the mask 3000 itself may be removed and may be easily replaced. In addition, the mask 3000 may be formed of a paper material. In a case where a foreign material is attached to the surface of the mask 3000 formed of a paper material, without performing the cleaning process, the mask 3000 itself may also be removed and may be easily replaced.

Alternatively, the mask 3000 may be formed of an elastic material. In this case, the mask 300 may serve as a buffer to prevent damage to the micro-LED (ML) corresponding to the non-absorption region 2100.

Specifically, when the transfer head descends, a transportation error may occur due to a mechanical tolerance. Thus, the micro-LED (ML) corresponding to the non-absorption region 2100 is brought into contact with the non-absorption region 2100. In this case, the mask 3000 formed of an elastic material tolerates the transportation error, and thus the damage to the micro-LED (ML) brought into contact with the non-absorption region 2100 can be prevented.

The mask 3000 may be configured in such a manner as have the opening portion 3000a in a different shape. Specifically, the mask 3000 may be formed in such a manner that an inner diameter of the opening portion 3000a in a contact surface that is brought into direct contact with the lower surface of the support member 1200 is greater than the area in the horizontal direction of the upper surface of the micro-LED (ML) and that the inner diameter gradually increases toward the upper surface of the micro-LED (ML). Thus, an inner lateral surface of the opening portion 3000a may be slopingly formed in such a manner that the inner diameter thereof gradually increases downward with respect to a direction in which the transfer head descends. With this configuration, when the micro-LED (ML) is absorbed to the absorption region 2000 of the transfer head, the mask 3000 may serve to guide the micro-LED (ML) to a vacuum absorption position in such a manner that the micro-LED (ML) is properly absorbed to the absorption region 2000.

The mask 3000 may be absorbed to the lower surface of the support member 1200 due to the vacuum suction force. The transfer head to which the mask 3000 is provided applies vacuum to the support member 1200 and vacuum-adsorbs the micro-LED (ML).

The transfer head may release the vacuum applied to the support member 1200 and thus may transfer the mask 3000 and the micro-LED (ML), which are vacuum-adsorbed to the lower surface of the support member 1200, to the circuit substrate 301. The micro-LED (ML) transferred to the circuit substrate 301 may be bonded to the first contact electrode 106 of the circuit substrate 301 by applying electric power to the circuit substrate 301. Subsequently, the transfer head forms the vacuum pressure through the vacuum port and applies vacuum to the support member 1200, and may absorb back the mask 3000 transferred to the circuit substrate 301. The micro-LED (ML) is in a state of being bonded to the first contact electrode 106, and therefore only the mask 3000 may be vacuum-absorbed to the lower surface of the support member 1200. According to the present invention, the transfer head is described as absorbing back the mask 3000 transferred to the circuit substrate 301. However, the mask 3000 may be removed using another suitable means.

In this manner, the transfer head including the mask 3000 much more increases the vacuum pressure with which the micro-LED (ML) is vacuum-adsorbed, through the opening portion 3000a in the mask 3000. The micro-LED (ML) is brought into direct contact with the lower surface of the support member 1200 that is uniformly flattened with the increased vacuum pressure. Thus, deviation of the micro-LED (ML) that may occur when vacuum-absorbing the micro-LED (ML) can be prevented.

3-4. Fourth Embodiment of the Transfer Head

FIG. 4(c) is an enlarged view illustrating respective portions of the first and second porous members that constitute a fourth embodiment of the transfer head. In the fourth embodiment, an absorption member 1100′″ having a vertical pore with a great upper end width and a small lower end width is configured as the first porous member. An absorption hole 1500′ in the fourth embodiment is formed in such a manner that have a great upper end width and a small lower end width. The absorption hole 1500′ forms the absorption region 2000 that absorbs the micro-LED (ML), and a region in which the absorption hole 1500′ is not formed forms the non-absorption region 2100 that does not absorb the micro-LED (ML).

As illustrated in FIG. 4(c), the absorption hole 1500′ is formed in the absorption member 1100′″ in a manner that passes therethrough from top to bottom. Furthermore, the absorption hole 1500′ is formed in such a manner that a width there gradually decreases toward an absorption surface to which the micro-LED (ML) is absorbed. Thus, the absorption hole 1500′ may have an inclined inner lateral surface.

The absorption hole 1500′ may be formed in such a manner that a lower end width thereof that is the smallest inner width is smaller than a width in the horizontal direction of the micro-LED (ML). If only the vacuum pressure with which the micro-LED (ML) is absorbed is formed, although the absorption hole 1500′ is formed in such a manner that the width thereof gradually decreases toward the absorption surface and that the lower end width is thus smaller than a width in the horizontal direction of the upper surface of the micro-LED (ML), a process of absorbing the micro-LED (ML) may be performed without the deviation of the micro-LED (ML) and a decrease in absorption efficiency.

The absorption hole 1500′ may be formed by laser processing in such a manner that the width thereof gradually increases toward the absorption surface. However, with the absorption hole 1500′ of this type, when absorbing the micro-LED having a relatively smaller size than a packaged LED or a heavy semiconductor chip, it is more difficult to satisfy the precision of alignment that reflects a mechanical error of the transfer head. In addition, when an error of positional alignment occurs due to the mechanical error of the transfer head, the vacuum leakage may occur in the absorption hole 1500′ due to the greater lower end width. In addition, since the absorption hole 1500′ is formed in such a manner as to have the great lower end width, an area in the horizontal direction of a lower surface of the non-absorption region of the absorption member is decreased. Accordingly, the lower surface thereof becomes sharp, and thus the micro-LED (ML) may be damaged.

However, as in the fourth embodiment, when the absorption hole 1500′ is formed in such a manner that the width thereof gradually decreases toward the absorption surface, the absorption of the micro-LED (ML) may be performed with relatively low precision of alignment. For the reason for this is because the absorption hole 1500′ is formed in such a manner that the lower end width is smaller than the width in the horizontal direction of the micro-LED (ML). Thus, when the absorption hole 1500′ is positioned only within the width of the upper surface of the micro-LED (ML), the micro-LED (ML) may be absorbed to the absorption hole 1500′. Accordingly, although the precision of alignment of the transfer head with respect to the micro-LED (ML) is relatively low, the effect of absorbing the micro-LED (ML) without the decrease in the efficiency of the absorption of the micro-LED (ML) can be achieved.

In addition, since the absorption hole 1500′ is formed in such a manner that the lower end width thereof is smaller than the width in the horizontal direction of the micro-LED (ML), when the absorption hole 1500′ is positioned with the width of the upper surface of the micro-LED (ML), the micro-LED (ML) is absorbed. Thus, the likelihood of the vacuum leakage from the absorption hole 1500′ is decreased. Furthermore, since the absorption hole 1500′ is formed in such a manner that the lower end width is smaller than an upper end width of the absorption hole 1500′, relatively higher vacuum pressure is formed, when compared with the case of the upper end width. Thus, the micro-LED (ML) may be absorbed without deviation. In addition, although a separation distance between the micro-LEDs (ML) is decreased to several μm, the lower end with of the absorption hole 1500′ is smaller than the width in the horizontal direction of the micro-LED (ML). Thus, easy absorption is possible. In addition, when forming the vacuum pressure, air flows through the absorption hole 1500′ of which the width gradually increases toward the upper end thereof and then is discharged to the outside. Accordingly, the likelihood of a vortex flow is decreased. Thus, the likelihood of the non-absorption of the micro-LED (ML) resulting from non-formation of the vacuum pressure due to the vortex flow can be decreased.

With the increase in the upper end width of the absorption hole 1500′, the vacuum pressure of the absorption member 1100′″ may be uniformly formed. With the increase in the upper end width of the absorption hole 1500′, air discharged from the inside of the absorption hole 1500′ to the outside thereof may be smoothly collected in one place. Thus, a uniform vacuum pressure may be formed in the absorption hole 1500′. As a result, the transfer head may absorb the micro-LEDs (ML) together at the same time. Furthermore, the micro-LEDs (ML) may be absorbed to the absorption surface with no one left behind. Thus, the efficiency of absorption can be improved.

A cross-section of the absorption hole 1500′ is circular when viewed from a lower surface of the absorption member 1100′″. For example, in a case where the absorption hole 1500′ is formed using a laser in such a manner that the width thereof gradually decreases toward the abortion surface, it is easier to form the absorption hole 1500′ having a circular cross-section.

As illustrated in FIG. 4(c), as one example, the absorption regions 2000 may be formed in such a manner that the pitch distance therebetween is three times the pitch distance in the x-direction of the micro-LED (ML) on the substrate S. The present invention is not limited to this pitch distance between the absorption regions 2000.

3-5. Fifth Embodiment of the Transfer Head

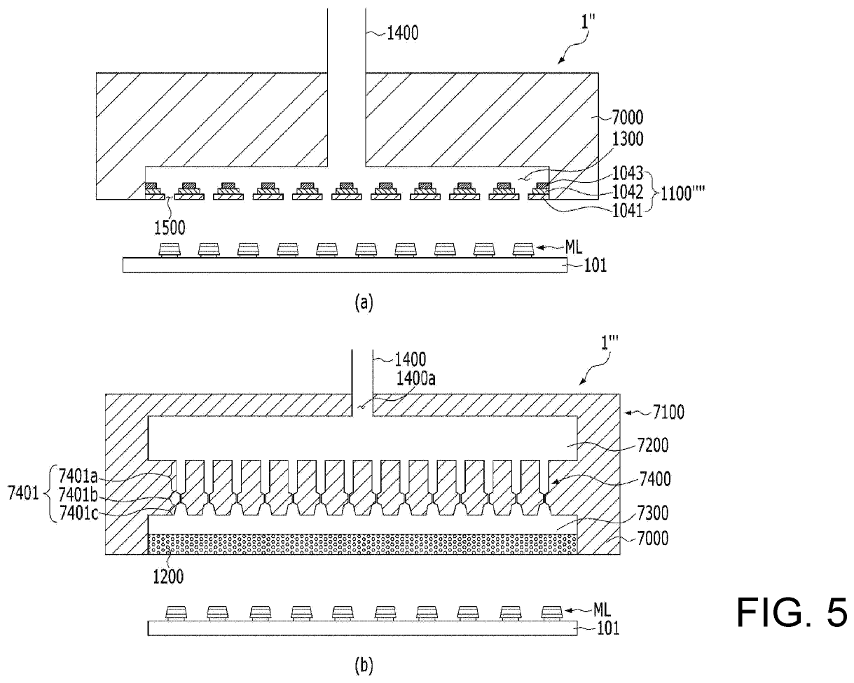

FIG. 5(a) is a view illustrating a fifth embodiment of a transfer head 1″ according to the present invention. The fifth embodiment is configured to include an absorption member 1100″″ having a vertical pore formed by a laser or by etching. The absorption members 1100″″ in the fifth embodiment are formed by stacking a plurality of absorption members on top of each other. As illustrated in FIG. 5(a), the absorption members 1100″″ may be configured to include a first absorption member 1041 that is brought into direct contact with the micro-LED (ML), a second absorption member 1042 stacked on top of the first absorption member 1041, and a third absorption member 1043 stacked on top of the second absorption member 1042. In this case, the number of the absorption members 1100″″ is not limited to 3.

The absorption members 1041, 1042, and 1043 may be provided in the shape of a thin plate in order to easily form the vertical absorption hole 1500. However, the absorption member in the shape of a thin plate has a small thickness, and the rigidity of the absorption member is decreased. In the fifth embodiment, a plurality of absorption members, for example, the absorption members 1041, 1042, and 1043 in the shape of a thin plate in each of which the absorption hole 1500 are formed are stacked on top of each other, and thus can improve the rigidity.

The absorption hole 1500 may be easily formed in the absorption member 1100″″ in the shape of a thin plate. The vertical absorption hole 1500 is formed each of the absorption members 1041, 1042, and 1043. As many absorption holes 1500 as the number of the micro-LEDs (ML) are formed, and thus all the micro-LEDs (ML) on the first substrate 101 may be simultaneously absorbed. Alternatively, the absorption holes 1500 are formed in such a manner that the pitch distance therebetween is three or more times the pitch distance in at least one direction between the micro-LEDs (ML) on the first substrate 101, and thus the micro-LED (ML) may be selectively absorbed.

The respective absorption holes 1500 in the absorption members 1041, 1042, and 1043 may be formed in such a manner as to correspond to each other. Each of the absorption holes 1500 may be formed in such a manner that a width thereof gradually increases toward an upper end thereof.

Specifically, as illustrated in FIG. 5(a), the absorption hole 1500 in the first absorption member 1041 may be formed in such a manner that the width thereof is smaller than the width in the horizontal direction of the upper surface of the micro-LED (ML). The absorption hole 1500 in the second absorption member 1042 that is formed in a manner that corresponds to the absorption hole 1500 in the first absorption member 1041 is formed in such a manner that the width thereof is greater than the width of the absorption hole 1500 in the first absorption member 1041. The absorption hole 1500 in the third absorption member 1043 is formed in such a manner that the width thereof is greater than the width of the absorption hole 1500 in the second absorption member 1042. In other words, the absorption member 1100″″ in the fifth embodiment, as illustrated in FIG. 5(a), may be formed in such a manner that the width of the absorption hole 1500 gradually increases toward an upper end of the absorption hole 1500 in the first absorption member 1041. In addition, the absorption member 1100″″ in the fifth embodiment, as illustrated in FIG. 5(a), may be formed in such a manner that the width of the absorption hole 1500 gradually decreases toward a lower end of the absorption hole 1500 in the third absorption member 1043.

The absorption hole 1500 is formed in such a manner that the width thereof gradually decreases toward the lower end thereof, and thus may serve to collect the vacuum pressure that is widely distributed. Thus, the vacuum suction force for absorbing the micro-LED (ML) may be effectively formed.

In addition, in a case where the absorption hole 1500 in the absorption member 1100″″ is formed in such a manner that the width thereof gradually increases toward the upper end thereof, the absorption members 1041, 1042, and 1043 are stacked on top of each other, there is an advantage in that it is easy to produce alignment according to the concentricity of the absorption hole 1500. When the plurality of the absorption members, for example, the absorption members 1041, 1042, and 1043 are stacked on top of each other, a process of aligning the holes 1500 in the absorption members 1041, 1042, and 1043 is performed. In this case, a center axis of the absorption hole 1500 in the first absorption member 1041 in which the absorption hole 1500 that is brought into direct contact with the micro-LED (ML) and absorbs the micro-LED (ML) is formed may be a reference axis. Since the absorption hole 1500 in the first absorption member 1041 is formed in such a manner that the width thereof is smaller than the width in the horizontal direction of the upper surface of the micro-LED (ML), the width thereof may be very small. In a case where the absorption hole 1500 is formed in such a manner that the width thereof gradually increases toward the upper end thereof, the upper absorption hole 1500 has a greater width than the reference absorption hole 1500. Therefore, when the concentricity with respect to the center axis of the reference absorption hole 1500 is provided, a range where the mechanical tolerance is allowed can be increased. In other words, in a case where the upper absorption hole 1500 is moved to provide the concentricity of the reference absorption hole 1500 and the absorption hole 1500, the reference absorption hole 1500 may be positioned within the width of the upper absorption hole 1500 although the concentricity of the upper absorption hole 1500 and the reference absorption hole 1500 is not precisely provided due to the mechanical tolerance because the width of the upper absorption hole 1500 is greater than the width of the reference absorption hole 1500. Thus, the absorption hole 1500 is properly aligned and air is properly discharged. Accordingly, the micro-LED (ML) may be absorbed.

In addition, when the micro-LED (ML) on the first substrate 101 is absorbed with the absorption surface, the absorption member 1100″″ in which the absorption hole 1500 is formed in such a manner that the width thereof gradually increases toward the upper end thereof may absorb the micro-LED (ML) although the precision of alignment of the transfer head 1″ with respect to the micro-LED (ML) is low. For example, in the case of the absorption member in which the absorption hole is formed in such a manner that the width thereof gradually decreased toward the upper end thereof, the micro-LED (ML) may not be properly absorbed due to outside air introduced into the absorption hole when the precision of alignment of the transfer head with respect to the micro-LED (ML). Therefore, the very high precision of the transfer head may be required. However, due to the mechanical tolerance, it is difficult to move the transfer head to a desired position. Thus, it may be difficult to satisfy the requirement for the high precision of the transfer head. Thus, an absorption rate of the micro-LED (ML) may be decreased.

However, in the fifth embodiment, the absorption member 1100″″ in which the absorption hole 1500 is formed in such a manner that the width thereof gradually increases toward the upper end is provided. Thus, the micro-LED (ML) may be absorbed although the precision of alignment of the transfer head 1″ with respect to the micro-LED (ML) is low. Thus, the high efficiency of transfer of the micro-LED (ML) can be achieved.

In a case where a structure in which a plurality of absorption members 1100″″ are formed to be stacked on top of each other with a bonding member interposed therebetween is employed, the absorption members may be formed of the same material or different materials. In this case, the absorption members 1100″″ may be formed of the material of the above-described absorption member 1100″″. Alternatively, the absorption members 1100″″ may be formed of one selected material or different materials.

The absorption member 1100″″ may be configured to include an anodic oxide film formed by anodically oxidizing a metal. In this case, it is preferable that the absorption member (for example, the first absorption member 1041) that is brought into direct contact with the micro-LED (ML) is configured as an anodic oxide film. However, in a case where the absorption member 1100″″ is configured to include the anodic oxide film, only the absorption member that is brought into direct contact with the micro-LED (ML) may be configured as the anodic oxide film. Alternatively, the plurality of absorption members (for example, the first, second, third absorption members 1041, 1042, and 1043) may be all configured as the anodic oxide film. In other words, the absorption member that is brought into direct contact with the micro-LED (ML) is configured as the anodic oxide film, the other absorption members may be formed of a different material. All absorption members 1100″″ may be formed of the same material as the anodic oxide film. In this case, a configuration of the anodic oxide film is the same as in the first embodiment, and thus a description thereof is omitted.

In addition, a thermal expansion coefficient of the anodic oxide film is 2 to 3 ppm/C.°. Thus, when the transfer head 1″ absorbs and transfers the micro-LED (ML), thermal deformation of the micro-LED (ML) due to ambient heat can be minimized. In the fifth embodiment, the effect of remarkably decreasing the likelihood of a positional error can be achieved.

As in the fifth embodiment, in a case where the absorption hole 1500 in the absorption member 1100″″ is formed in such a manner that the width thereof gradually increases toward the upper end thereof, the absorption hole 1500 may be formed in a manner that adjusts the width thereof, so that the absorption hole 1500 that is formed in the absorption member 1100″″ to be brought into direction contact with the micro-LED (ML) and absorbs one micro-LED (ML) does not interfere with a formation region of the absorption hole 1500 that absorbs other one micro-LED (ML).

The fifth embodiment may include a fixation support unit 7000 that fixedly supports the absorption member 1100″″. The fixation support unit 7000 may protect the absorption member 1100″″ and the vacuum chamber 1300 in such a manner as not to be exposed to the outside. Thus, a structure in which the absorption member 1100″″ and the vacuum chamber 1300 are formed inside the fixation support unit 7000 may be employed.

The fixation support unit 7000 may be formed of a metal material, such as aluminum (Al). The fixation support unit 7000, if capable of fixedly supporting the absorption member 1100″″, is not limited in material. In addition, the fixation support unit 7000, if capable of being provided over the absorption member 1100″″ and the vacuum chamber 1300 and having the absorption member 1100″″ and the vacuum chamber 1300 inside, is not limited in structure.

Alternatively, in the fifth embodiment, the support member 1200 formed of a porous material having arbitrary pores is provided over the absorption member 1100″″. The fifth embodiment may be configured in such a manner that the absorption member 1100″″, the support member 1200, and the vacuum chamber 1300 are provided inside the fixation support unit 7000. In this case, the support member 1200 may be the above-described second porous member 1200. The support member 1200 has the same configuration and functions as the second porous member 1200, and thus a detailed description thereof is omitted.

3-6. Sixth Embodiment of the Transfer Head

FIG. 5(b) is a view illustrating a sixth embodiment of a transfer head 1′″ according to the present invention. The transfer head 1′″ in the sixth embodiment is configured to include the absorption member 1100 and a distribution member 7100 that are provided as an anodic oxide film. Constituent embodiments different in feature from those in the first embodiment will be described below.

As illustrated in FIG. 5(b), the distribution member 7100 is configured to include a suction hole 1400a communication with a suction pipe 1400, an upper chamber 7200 communicating with the suction hole 1400a, and the air passage portion 7400 provided underneath the upper chamber 7200.

The distribution member 7100 may be formed of a metal material. Thus, the absorption member 1100 may be effectively supported in a fixed manner.

The suction hole 1400a communicating with the suction pipe 1400 may be formed in an upper portion of the suction pipe 1400 the distribution member 7100. The suction hole 1400a communicates with the suction pipe 1400, and through the suction hole 1400a, vacuum supplied from a vacuum pump may be transferred into the distribution member 7100. The upper chamber 7200 communicating with the suction hole 1400a may be provided inside the distribution member 7100. The upper chamber 7200 may transfer vacuum to the air passage portion 7400 provided underneath.

The air passage portion 7400 provided underneath the upper chamber 7200 in a manner that communicates with the upper chamber 7200. The air passage portion 7400 may be configured to include a plurality of air passages 7401 that are vertically formed. Therefore, the vacuum of the upper chamber 7200 may be transferred to the plurality of air passages 7401. The air passage portion 7400 may distribute the transferred vacuum to an entire upper surface of the absorption member 1100 provided under the distribution member 7100. Thus, the transfer head 1 may generate a uniform absorption force to be supplied to the absorption surface to which the micro-LED (ML) is absorbed.

As illustrated in FIG. 5(b), the air passage 7401 may be vertically formed, but in such a manner that a width thereof varies according to a position inside the air passage 7401 through which the vacuum passes. An intake portion 7401a to which the vacuum of the upper chamber 7200 is transferred may be formed in such a manner as to have an arbitrary width. A narrow portion 7401b having a smaller width than the intake portion 7401a may be formed in a lower portion of the intake portion 7401a. Air to be charged gains a fast flow speed while passing through the narrow portion 7401b. When the vacuum pressure with respect to the micro-LED (ML) is formed, discharging of the air that gains a fast flow speed while passing through the narrow portion 7401b brings about the effect of shortening the time for forming the vacuum pressure. A distribution portion 7401c is provided underneath the narrow portion 7401b.

The air passage portion 7400 is provided in the lowest portion of the distribution member 7100, and thus may be positioned over the absorption member 1100 that is provided under the distribution member 7100. In addition, the distribution portion 7401c of each of the plurality of air passages 7401 is positioned in the lowest portion of the air passage 7401. Thus, the distribution portion 7401c may be positioned over the absorption member 1100. Thus, the vacuum may be uniformly transferred to the upper surface of the absorption member 1100 after passing through the distribution portion 7401c. The narrow portion 7401b facilitates fast air discharging. The narrow portion 7401b facilitates wide distribution of the vacuum over the upper surface of the absorption member 1100 according to a width of the narrow portion 7401b. In this case, the air passage portion 7400 is configured to include the plurality of air passages 7401, and the vacuum is widely distributed over the upper surface of the absorption member 1100 according to the width of the distribution portion 7401c of each of all the air passages 7401. Thus, the vacuum may be uniformly distributed over the entire upper surface of the absorption member 1100. Thus, a uniform absorption force to be exerted on the micro-LED (ML) is generated on the entire absorption surface of the absorption member 1100. Accordingly, the problem of not absorbing the micro-LED (ML) due to non-formation of the vacuum pressure on one portion of an absorption surface of the absorption member 1100 can be solved.

The air paths 7401 of the air passage portion 7400 may be vertically formed in such a manner as to have the same width. In this case, the air paths 7401 may be easily formed. The advantage of easily providing the air passage portion 7400 is achieved.

The upper chamber 7200 that transfers the vacuum passing through the suction hole 1400a to the air passage portion 7400 may be provided over the air passage portion 7400. A lower chamber 7300 that transfers the vacuum passing through the air passage portion 7400 to the absorption member 1100 may be provided underneath the air passage portion 7400.

The vacuum supplied from the vacuum pump passes through the upper chamber 7200 and, through the air passage portion 7400, may be primarily distributed in a space over the absorption member 1100 in a uniform manner. In this case, the space over the absorption member 1100 may be a space formed by providing the absorption member 1100 under a lower surface of the distribution member 7100 in a manner that is spaced away therefrom, and may be a space where the lower chamber 7300 is provided. The vacuum that is primarily distributed through the air passage portion 7400 in a uniform manner may be transferred at a fast flow speed gained while passing through the narrow portion 7401b of the air passage portion 7400. The vacuum transferred at a fast flow speed to the lower chamber 7300 may shorten the time for forming the vacuum pressure of the absorption member 1100. The vacuum that is primarily distributed through the air passage portion 7400 in a uniform manner may be secondarily distributed over the absorption member 1100 through the lower chamber 7300.

A porous member 1200 having an absorption surface to which the micro-LED (ML) is absorbed may be provided under the lower chamber 7300 of the distribution member 7100. In FIG. 5(b), it is illustrated that the porous member 1200 having a single structure is provided. However, the porous member 1200 may be formed in such a manner to have a double structure that includes first and second porous members. In this case, the configurations of the absorption member 1100 and the support member 1200 in the first embodiment may be employed.

The porous member 1200 in the sixth embodiment is configured in such a manner as to have the same structure as the support member 1200 and may function as an absorption member absorbing the micro-LED (ML). Therefore, the porous member 1200 may be provided as an anodic oxide film. In this case, a configuration of the anodic oxide film is the same as that of the anodic oxide film in the first embodiment described above, and thus a detailed description thereof is omitted. Alternatively, the porous member 1200 may be configured as a porous member having pores that constitute the absorption member. Specifically, the porous member 1200 may be a porous member having a vertical pore formed by a laser or by etching.

A uniform vacuum may be transferred by the lower chamber 7300 to an entire area of the porous member 1200 functioning as the absorption member. Thus, it is possible to form uniform a vacuum pressure on an entire absorption surface of the porous member 1200, and thus the problem of not absorbing the micro-LED (ML) can be solved.

3-7. Seventh Embodiment of the Transfer Head

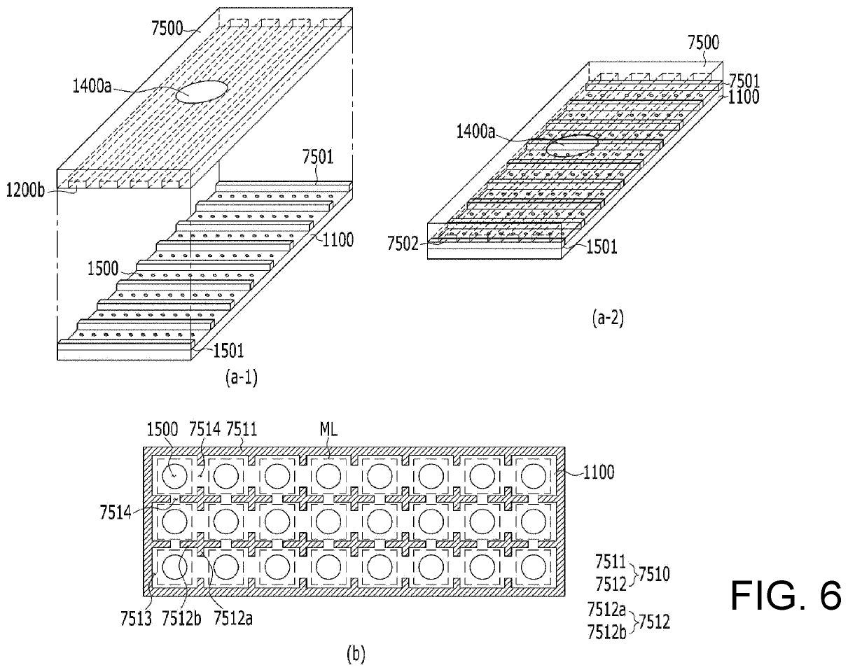

FIGS. 6(a-1) and 6(a-2) are views each illustrating a communication member 7500, a first support portion 7501, and the absorption member 1100 that constitute the seventh embodiment of the transfer head according to the present invention. FIG. 6(a-1) is a view illustrating a state where the communication member 7500 is not yet combined with the first support portion 7501 provided to top of the absorption member 1100. FIG. 6(a-2) is a view illustrating a state where the communication member 7500 is already combined with the first support portion 7501 provided on top of the absorption member 1100.

The seventh embodiment of the transfer head is configured to include the absorption member 1100 that serves to absorb the micro-LED (ML), the first support portion 7501 that is provided on top of the absorption member 1100, and the communication member 7500 that provided over the first support portion 7501 and is combined with the first support portion 7501.

The absorption member 1100 may employ the configuration of the porous member in the first to sixth embodiments and is not limited to this configuration. The absorption member 1100 is as described above, and thus a description thereof is omitted.

The absorption holes 1500 are formed in the absorption member 1100 in such a manner that they are spaced apart by a predetermined distance in the x (row) direction and in the y (column) direction. The absorption holes 1500 may be formed in such a manner that they are spaced apart by a distance in at least one of the x and y-directions that is three or more times the pitch distance in at least one of the x and y-directions between the micro-LEDs (ML) arranged on a substrate. The substrate here may be the first substrate that is the growth substrate 101 illustrated in FIG. 1 or a temporary substrate or may be the second substrate that is the circuit substrate 301 illustrated in FIG. 2 or a temporary substrate to which the micro-LED (ML) absorbed from the growth substrate 101 is transferred.

In the absorption member 1100 in the seventh embodiment of the transfer head according to the present invention, the absorption holes 1500 are illustrated and described above as being formed in such a manner that they are spaced apart by a distance in the x-direction that is three times the pitch distance in the x-direction between the micro-LED (ML) on the substrate and by a distance in the y-direction that is the same as the pitch distance in the y-direction therebetween. Alternatively, the absorption hole 1500 may be formed in such a manner that they are spaced apart by a distance as much as two times the pitch distance in at least one of the x and y-directions between the micro-LEDs (ML) on the substrate S.

The absorption member 1100 in which the absorption holes 1500 are formed in such a manner that they are spaced apart by a distance in the x-direction that is three times the pitch distance between the micro-LEDs (ML) on the substrate and by a distance in the y-direction as much as the pitch distance in the y-direction therebetween may selectively absorb the micro-LED (ML) on the substrate.

In a case where the absorption holes 1500 are formed in the absorption member 1100 in such a manner that they are spaced apart in at one of the x and y-directions by a distance that is three or more times the pitch distance in at least one of the x and y-directions between the micro-LEDs (ML) arranged on the substrate, an absorption hole non-formation portion 1501 in which the absorption hole 1500 is not formed may be formed between the absorption holes 1500.

Because vacuum that is supplied through the suction pipe 1400 is not transferred to the absorption hole non-formation portion 1501, the non-absorption region 2100 may be formed in the absorption surface of the absorption member 1100. In a case where the absorption member 1100 is the anodic oxide film 1600 that is provided as the barrier layer 1600b and the porous layer 1600a, the absorption hole non-formation portion 1501 may be formed by the barrier layer 1600b. The first support portion 7501 may be provided on top of the absorption hole non-formation portion 1501.

The first support portion 7501 may be provided on the absorption hole non-formation portion 1501 present between the absorption holes 1500. For example, in a case where a separation distance between the absorption holes 1500 is three times the pitch distance between the micro-LED (ML) arranged on the substrate, the first support portion 7501 may be provided on the absorption hole non-formation portion 1501 in which the absorption holes 1500 are formed in the y-direction in such a manner that they are spaced apart.

The first support portion 7501 is provided on an upper surface of the non-absorption region 2100 of the absorption member 1100 and serves to support a weight of the communication member 7500 that is combined with top of the first support portion 7501. Thus, although the absorption hole 1500 providing an airflow path in a vertical form is formed in the absorption member 1100, the strength of the absorption member 1100 can be prevented from being decreased.

Specifically, for easy forming of the absorption hole 1500, the absorption member 1100 in which the absorption hole 1500 in the shape of a fine-sized vertical hole is formed by a laser or by etching may be provided in such a manner as to have a small thickness. In this case, the small thickness of the absorption member 1100 may make it difficult for the absorption member 1100 to support weights of the communication member 7500, the vacuum chamber 1300, and the like that are combined with top of the absorption member 1100. However, in a case where, as in the seventh embodiment of the transfer head according to the present invention, the first support portion 7501 is provided on the non-absorption region 2100 formed by the absorption hole non-formation portion 1501, the first support portion 7501 serves as a border between the absorption region 2000 in which the absorption hole 1500 is formed between the first support portions 7501 and the non-absorption region 2100. The first support portion 7501 may serve as a partition in such a manner that the absorption region 2000 in which the absorption hole 1500 is formed between the first support portions 7501 serves as one vacuum formation compartment. Thus, a vacuum can be easily formed in the absorption region 2000.

The communication member 7500 that is combined with the first support portion 7501 and causes the absorption regions 2000, each of which is present between the first support portions 7501, to communicate with each other for airflow, may be positioned on top of the first support portion 7501. The communication member 7500 may be formed of a non-porous material, such as a metal material, and the suction hole 1400a may be formed therein. The suction hole 1400a may be formed in the communication member 7500 in a manner that passes therethrough from top to bottom. As illustrated in FIG. 6(a-2), in a case where the communication member 7500 is combined with top of the first support portion 7501, the suction pipe 1400 through which the vacuum supplied from the vacuum is transferred may be connected by the suction hole 1400a. Thus, the vacuum is transferred to the absorption member 1100, and the absorption force to be exerted on the micro-LED (ML) may occur.

An intersection groove 7502 intersecting the first support portion 7501 may be provided in a lower surface of the communication member 7500. Thus, the vacuum supplied through the suction hole 1400a is uniformly distributed over all the absorption regions 2000, each being present between the first support portions 7501, and thus airflow is possible. The absorption region 2000 of the absorption member 1100 may be formed by transferring the vacuum transferred through the suction hole 1400a to the absorption hole 1500 in the absorption member 1100. Therefore, the absorption regions 2000 of the absorption member 1100, each of which is present between the first support portions 7501, communicate with each other for airflow. Thus, when the vacuum supplied through the suction hole 1400a is uniformly distributed over all the absorption region 2000, a uniform absorption force may be exerted on the entire absorption surface of the absorption member 1100. Thus, the effect of increasing the absorption efficiency of the transfer head 1 can be achieved.

In FIGS. 6(a-1) and 6(a-2), it is illustrated that a plurality of intersection groove 7502 is provided in the lower surface of the communication member 7500 in such a manner as to intersect the first support portion 7501, in order that the absorption regions 2000, each of which is present between the first support portions 7501, are caused to communicate with each other for airflow. However, at least one intersection groove may be provided in order that the absorption regions 2000, each of which is present between the first support portions 7501, are caused to communicate with each other for airflow. In addition, the intersection groove 7502 is formed in the communication member 7500 in such a manner as to have a smaller width and a smaller thickness than the communication member 7500, and thus the absorption regions 2000, each of which is prevented between the first support portions 7501, may be caused to communicate with each other for airflow.

The communication member 7500 may be configured as a porous member having pores. In a case where the communication member 7500 is configured as a porous member having pores, the communication member 7500 combined with the first support portion 7501 is positioned between the vacuum chamber 1300 and the absorption member 1100 that is the first porous member 1100, and may function as the second porous member 1200 that transfers the vacuum pressure of the vacuum chamber 1300 to the absorption member 1100. The second porous member 1200 may be provided in such a manner as to have the same configuration as the above-described second porous member 1200.

3-8. Eighth Embodiment of the Transfer Head

FIG. 6(b) is a view illustrating the absorption member 1100 constituting an eighth embodiment of the transfer head, when viewed from above. The transfer head in the eighth embodiment may be configured to include the absorption member 1100 and second support portion 7510 that is combined with top of the absorption member 1100. The absorption member 1100 may be provided as the anodic oxide film 1600 and may employ the same configuration as the first porous member 1100. In addition, the support member 1200 may employ the same configuration of the described-above second porous member 1200. These are as described above, and thus detailed descriptions thereof are omitted. Constituent embodiments different in feature from those in the first embodiment will be described below.

The absorption member 1100 may be configured to include a vacuum pressure formation portion 7513 which is formed on the upper surface of the absorption member 1100 and to which the vacuum of the vacuum chamber is transferred. The vacuum that is applied by the vacuum chamber 1300 to the support member 1200 may be transferred to the vacuum pressure formation portion 7513, and thus the vacuum pressure may be formed. Thus, the absorption force may be exerted on the absorption region 2000, and thus the micro-LED (ML) may be absorbed to the absorption region 2000.

As illustrated in FIG. 6(b), the second support portion 7510 may be provided on the upper surface of the non-absorption region. The second support portion 7510 may be provided on the upper surface of the non-absorption region of the absorption member 1100 and may support weights of the support member 1200 and the vacuum chamber 1300 that are combined with top of the absorption member 1100.

The second support portion 7510 is provided on the upper surface of the non-absorption region of the absorption member 1100, and a periphery of the second support portion 7510 is continuously formed, and an arrangement in columns and rows is possible in a matrix form inside the second support portion 7510. The periphery means the upper surface of the absorption member 1100 that corresponds to a region other than a micro-LED presence region in which a plurality of micro-LEDs (ML) is present in a state of being absorbed to the absorption surface of the absorption member 1100.

As illustrated in FIG. 6(b), the second support portion 7510 may be configured to include a periphery support portion 7511 and an inside support portion 7512. The periphery support portion 7511 is continuously formed. The inside support portion 7512 is configured to include a column-direction support portion 7512a and row-direction support portion 7512b that are positioned inward from the periphery support portion 7511.

With a configuration of the periphery support portion 7511 that forms a continuous boundary, the second support portion 7510 provided on the upper surface of the non-absorption region 2100 may block flowing of outside air into the absorption region 2000. Thus, formation of the vacuum pressure by the vacuum pressure formation portion 7513 can be facilitated. As a result, the absorption force of the absorption region 2000 can occur more effectively.

The inside support portion 7512 may be formed to a cross shape that results from intersection of the column-direction support portion 7512a and the row-direction support portion 7512b. The cross-shaped support portion may be formed by the column-direction support portion 7512a and the row-direction support portion 7512b. Therefore, the second support portion 7510 may be configured to include the periphery support portion 7511 and the inside support portion 7512 that is formed by the column-direction support portion 7512a and the row-direction support portion 7512b.

A flow path 7514 may be formed between the periphery support portion 7511 and the cross-shaped support portion and between the cross-shaped support portions. Through the airflow path 7514, the vacuum of the support member 1200 to which the vacuum of the vacuum chamber 1300 is transferred may be uniformly distributed to the vacuum pressure formation portion 7513 that generates the absorption force with which the micro-LED (ML) is absorbed.

In a case where the micro-LED (ML) is absorbed to the absorption surface of the absorption member, the micro-LED (ML) is absorbed to one portion of the absorption surface, and the micro-LED (ML) is not absorbed to one other portion thereof. The reason for this is because the vacuum transferred from the vacuum chamber 1300 is transferred to one portion of the absorption member in a concentrated manner and thus the absorption region on which the absorption force is not exerted is present. However, in the eighth embodiment, the airflow path 7514 is formed inside the second support portion 7510, and thus, through the second support portion 7510, the vacuum transferred from the support member 1200 combined with top of the absorption member 1100 may be uniformly distributed to all the vacuum pressure formation portions 7513 on the upper surface of the absorption member 1100. Thus, the absorption force of the entire absorption surface of the absorption member 1100 can be uniformized, and the efficiency of transfer of the micro-LED (ML) by the absorption surface of the absorption member 1100 can be improved.

Alternatively, the airflow path 7514 may be provided between the column-direction support portion 7512a and the row-direction support portion 7512b and between the row-direction support portion 7512b and the row-direction support portion 7512b that are positioned in the same row.

The airflow path 7514, if capable of being positioned at a position for connecting the vacuum pressure formation portions 7513 with each other, is not limited in position. However, the periphery support portion 7511 formed on a periphery of the upper surface of the non-absorption region of the absorption member 1100 is continuously formed in order to block flowing of outside air into the vacuum pressure formation portion 7513. Therefore, it is preferable that the airflow path 7514 is formed between the inside support portions 7512 and thus connects the vacuum pressure formation portions 7513.

the absorption hole 1500 may be formed in the vacuum pressure formation portion 7513. The absorption hole 1500 formed in the vacuum pressure formation portion 7513 may be the absorption hole 1500 formed in the absorption member 1100. The absorption hole 1500 may be formed in such a manner as to have an inner diameter smaller than the area in the horizontal direction of the upper surface of the micro-LED (ML), and thus vacuum pressure formation portion 7513 may easily form the vacuum pressure.

3-9. Ninth Embodiment of the Transfer Head

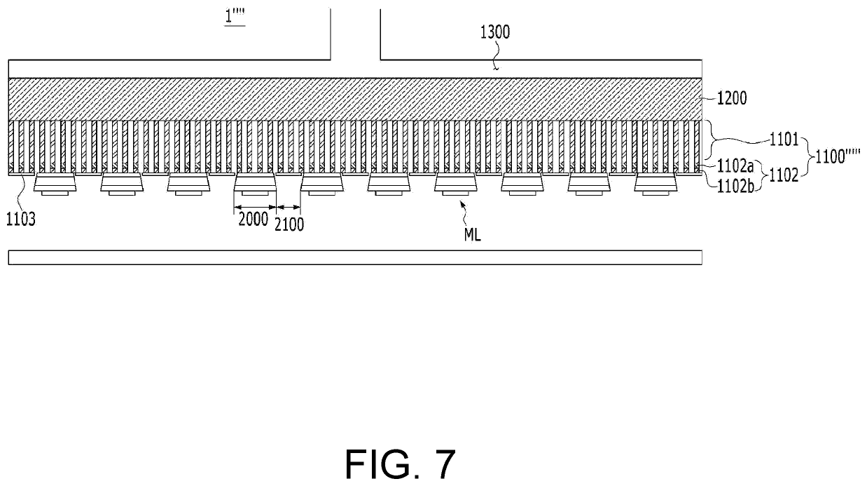

FIG. 7 is a view illustrating a ninth embodiment of a transfer 1 head″″ according to the present invention. The transfer head 1″″ in the ninth embodiment may be configured to have a structure in which different adsorption forces can be produced, and thus may absorb the micro-LED (ML).

As illustrated in FIG. 7, the transfer head 1″″ in the ninth embodiment may be configured to an absorption member 1100′″″ and the support member 1200. The absorption member 1100′″″ may be configured to include the first absorption force generation unit 1101 generating a first absorption force and the second absorption force generation unit 1102 generating a second absorption force and may be formed in such a manner to have a double structure. The transfer head 1″″ with this structure may absorb the micro-LED (ML) with the first absorption force and the second absorption force that are different from each other.

The absorption member 1100′″″ may be configured to include the first and second absorption force generation units 1101 and 1102 that generate different absorption forces and may be formed in such a manner to have a double structure. Thus, the transfer head 1″″ in the ninth embodiment may generate at least two different absorption forces from among a vacuum suction force, an electrostatic force, a magnetic force, or a van der Waals force.

First, the first absorption force generation unit 1101 may be a porous member in which a pore is formed by etching, laser processing, or the like, and be provided as an anodic oxide film. In the ninth embodiment, as one example, the first absorption force generation unit 1101 is illustrated and described as the anodic oxide film including the porous layer 1600a. The porous member or the anodic oxide film that constitutes the first absorption force generation unit 1101 has the same configuration as the porous member and the anodic oxide film that are described above. The first absorption force generation unit 1101 with this configuration may force the first absorption force. In this case, as one example, in the ninth embodiment, the first absorption force may be a vacuum suction force.

The second absorption force generation unit 1102 may be configured to include an upper layer 1102a and a lower layer 1102b. In this case, the upper layer 1102a may be formed on a lower surface of the first absorption force generation unit 1101, and the lower layer 1102b may be formed on a lower surface of the upper layer 1102a. The second absorption force generation unit 1102 with this configuration may generate the first absorption force and the second absorption force different from the first absorption force. As one example, in the ninth embodiment, the second absorption force may be an electrostatic force or a magnetic force.

The second absorption force that is generated by the second absorption force generation unit 1102 may be an electrostatic force, and the upper layer 1102a is an electrode layer, and the lower layer 1102b may be a dielectric layer that is formed on a lower surface of the electrode layer. A voltage may be applied to the electrode layer. In this case, dielectric polarization occurs in the dielectric layer, and accordingly, an electrostatic force is generated. The generated electrostatic force may be the second absorption force.

The electrode layer may be formed of a metal material, such as tungsten (W) or copper (Cu). The dielectric layer may be formed on the lower surface of the electrode layer by spray-coating a ceramic material or the like.

Alternatively, in a case where the second absorption force that is generated by the second absorption force generation unit 1102 is a magnetic force, the upper layer 1102a may be a magnetic layer, and the lower layer 1102b may be a protective layer that is formed on a lower surface of the magnetic layer.

A voltage is applied to the magnetic layer. In a case where the voltage is applied to the magnetic layer, the magnetic force is exerted on the magnetic layer. In this case, the magnetic force may be the second absorption force. The protective layer serves to protect the magnetic force and to prevent the upper surface of the micro-LED (ML) from being damaged due to the magnetic layer. Conceptionally, the magnetic force includes an electromagnetic force.

A blocking portion 1103 may be provided on a lower surface of the lower layer 1102b of the second absorption force generation unit 1102.

In a case where the second absorption force is an electrostatic force, the blocking portion 1103 may be formed of a material blocking of exertion of the electrostatic force on at least one portion of the lower surface of the lower layer 1102b that is a dielectric layer. Thus, although the electrostatic force occurs by the electrode layer and the dielectric layer of the second absorption force generation unit 1102, the electrostatic force is not exerted on a region where the blocking portion 1103 is positioned. The non-absorption region 2100 to which the micro-LED (ML) is not absorbed is formed by the blocking portion 1103 on the absorption member 1100, and thus the micro-LED (ML) is not absorbed to the non-absorption region 2100.

In a case where the second absorption force is a magnetic force, at least one portion of the lower surface of the lower layer 1102b may be formed of a material that can block a magnetic force. The lower layer 1102b may be selectively provided. Therefore, in a case where the lower layer 1102b functioning as the protective layer is not provided, the blocking portion 1103 may be provided on the lower surface of the upper layer 1102a that is a magnetic layer. In this case, although a magnetic force is exerted on the upper layer 1102a, a region where the blocking portion 1103 is formed is formed as the non-absorption region 2100, and thus the magnetic force does not occur. Thus, the micro-LED (ML) is not absorbed to the non-absorption region 2100.

In a case where the transfer head 1″″ absorbs the micro-LED (ML) using different absorption forces, the transfer head 1″″ sequentially may exert the first absorption force and the second absorption force and thus may absorb the micro-LED (ML). Alternatively, the transfer head 1″″ may exert the first absorption force and the second absorption force at the same time and thus may absorb the micro-LED (ML).

First, in a case where the transfer head 1″″ sequentially exerts the first absorption force and the second absorption force, the transfer head 1″″ may be positioned between the lower layer 1102b of the second absorption force generation unit 1102 and the upper surface of the micro-LED (ML) on the first substrate 101 in a manner that is spaced away therefrom.

The transfer head 1″″ may exert one force of the first absorption force by the first absorption force generation unit 1101 and the second absorption force by the second absorption force generation unit 1102. Thus, the micro-LED (ML) on the first substrate 101 may be raised toward a lower surface of the transfer head 1″″. With one force of the first absorption force and the second absorption force that are exerted by the transfer head 1″″, the micro-LED (ML) may be raised until brought into contact with the lower surface of the transfer head 1.

After the micro-LED (ML) is raised toward the lower surface of the transfer head 1″″, the other of the first absorption force and the second absorption force may be exerted. Thus, the micro-LED (ML) may be absorbed more firmly to the absorption region 2000 of the lower surface of the transfer head 1″″ where the blocking portion 1103 is not present.

In this manner, the transfer head 1″″ exerts one force of the first absorption force and the second absorption force and thus raises the micro-LED (ML). Thereafter, the transfer head 1″″ exerts the other force, and thus the micro-LED (ML) may be absorbed more firmly to the absorption region 2000 of the transfer head 1″″. The method in which one of the first absorption force and the second absorption force is first exerted and then the micro-LED (ML) is raised and in which the other force is exerted and then the micro-LED (ML) is absorbed more firmly can increase shock to the micro-LED (ML) while the transfer head 1″″ absorbs the micro-LED (ML). Thus, the effect of preventing the damage to the micro-LED (ML) can be achieved.

In a case where the force first exerted by the transfer head 1″″ is the first absorption force (for example, a vacuum suction force), vacuum is transferred by the vacuum pump to a pore in the anodic oxide film 1600 that occurs naturally, and thus the first absorption force may occur. With the first absorption force, the micro-LED (ML) may be raised toward the lower surface of the transfer head 1″″.

Then, the transfer head 1″″ may exert the second absorption force. In this case, the second absorption force is different from the first absorption force and may be one of the vacuum suction force, the electrostatic force, the magnetic force, and the van der Waals force. In the ninth embodiment, as one example, the second absorption force may be an electrostatic force or a magnetic force. After the first absorption force is exerted, with the second absorption force, the micro-LED (ML) may be absorbed more firmly to the absorption region 2000 of the transfer head 1″″.

As described above, in a case where the first absorption force that is a vacuum suction force is first exerted, although the transfer head 1″″ does not descend a long distance toward the upper surface of the micro-LED (ML), the advantage of easily raising the micro-LED (ML) with a comparatively great vacuum suction force can be achieved.

In addition, the second absorption force, that is, an electrostatic force or a magnetic force, which is exerted after the first absorption force, that is, a vacuum suction force, is exerted does not need to be great because the transfer head 1″″ absorbs the micro-LED (ML) with the micro-LED (ML) being in contact with the lower surface of the transfer head 1″″.

Alternatively, the second absorption force that is an electrostatic force or a magnetic force may be first exerted. In this case, the electrostatic force may occur through the electrode layer and the dielectric layer, or the magnetic force may occur through the magnetic layer. With the second absorption force that is an electrostatic force or a magnetic force, the micro-LED (ML) may be raised toward the lower surface of the transfer head 1″″.

Then, with the first absorption force that is a vacuum suction force, the micro-LED (ML) may be absorbed more firmly to the absorption region 2000 of the transfer head 1″″.

In a case where the second absorption force that is an electrostatic force or a magnetic force is exerted earlier than the first absorption force that is a vacuum suction force, with the second absorption force, the micro-LED (ML) may be brought into contact with the absorption region 2000 of the transfer head 1″″. Furthermore, with the first absorption force that is a vacuum suction force, the upper surface of the micro-LED that is brought into contact with the absorption region 2000 may be absorbed. In this case, vacuum pressure occurs between the upper surface of the micro-LED (ML) and the pore, and thus the micro-LED (ML) may be absorbed with a greater force.

The transfer head 1″″ may exert the first absorption force and the second absorption force at the same time and thus may absorb the micro-LED (ML). In this case, the transfer head 1″″ is positioned in such a manner as to be spaced away from the upper surface of the micro-LED (ML). Then, the transfer head 1″″ may cause the first absorption force generation unit 1101 and the second absorption force generation unit 1102 to generate the first absorption force and the second absorption force, respectively, and thus may absorb the micro-LED (ML).

In this manner, in a case where the first and second absorption forces are exerted at the same time, when one absorption force is too weak for the transfer head 1″″ to lift at least one of the micro-LEDs (ML) on the first substrate 101, the other absorption force may compensate for the weak absorption force. Thus, the micro-LED (ML) on the first substrate 101 may be easily absorbed to the absorption region 2000 of the transfer head 1″″.

As illustrated in FIG. 7, the support member 1200 formed of a porous ceramic material may be provided, as the second porous member 1200, on top of the absorption member 1100′″″ having a double structure.

In this case, the support member 1200 may communicate with a pore in the first absorption force generation unit 1101 of the absorption member 1100′″″. The first absorption force generation unit 1101 of the absorption member 1100′″″ is provided as an anodic oxide film. In a case where an absorption hole is formed in the anodic oxide film in a manner that passes therethrough, the support member 1200 may communicate with the absorption hole. Thus, in a case where the first absorption force is a vacuum suction force, a vacuum suction force occurs by the absorption hole, and thus the absorption region to which the micro-LED (ML) is absorbed may be formed.

In the ninth embodiment, the first absorption force and the second absorption force are described above as being a vacuum suction force and as an electrostatic force or a magnetic force, respectively. However, the first absorption force generation unit 1101 and the second absorption force generation unit 1102 may generate different forces, but in a different manner than in the ninth embodiment. In other words, the first absorption force may be at least one of a vacuum suction force, an electrostatic force, a magnetic force, a van der Waals force, and an adhesive force, and, among these forces, the second absorption force may be a force other than the first absorption force.

As one example, the first absorption force may be at least one of a vacuum suction force, an electrostatic force, a magnetic force, and a van der Waals force, and the second absorption force may be an adhesive force.

In this case, the micro-LED (ML) may be raised with the first absorption force and may be absorbed more firmly to the absorption region 2000 of the transfer head 1″″ with the adhesive force that is the second absorption force.

In a case where, with the adhesive force, the micro-LED (ML) is finally absorbed to the lower surface of the transfer head 1″″, an adhesion force that is greater than the above-described adhesive force may be provided for the micro-LED (ML) to be transferred to the second substrate or the like. The reason for this is to easily transfer the micro-LED (ML) absorbed to the lower surface of the transfer head 1″″.

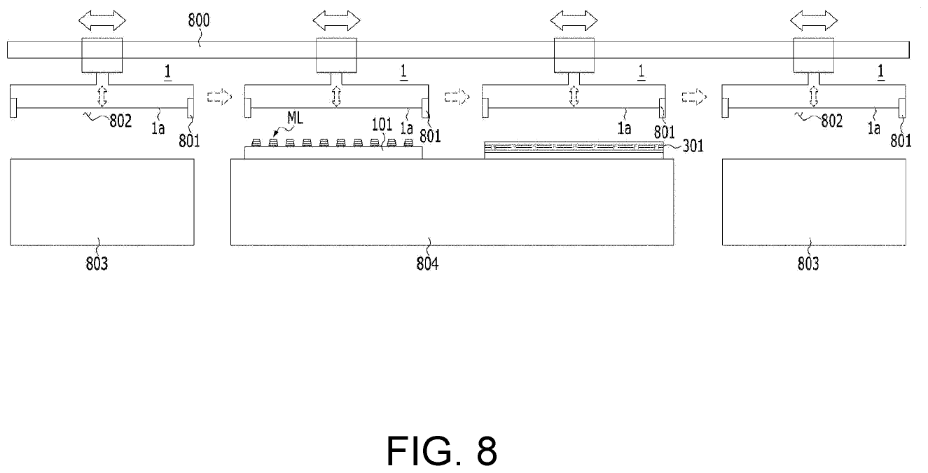

FIG. 8 is a view illustrating a cleaning step of cleaning an absorption surface of the transfer head.

An absorption surface 1a of each of the transfer heads 1, 1′, 1″, 1′″, and 1″″) in the first to ninth embodiments to which the micro-LED (ML) is absorbed may be cleaned in the cleaning step. In FIG. 8, for convenience, the cleaning step is described using the reference characters that are assigned when the transfer head 1 in the first embodiment is described.

The cleaning step may be performed before the micro-LED (ML) on the first substrate (for example, the growth substrate 101 or a temporary substrate) is absorbed or may be performed after the micro-LED (ML) on the first substrate 101 is transferred to the second substrate (for example, the circuit substrate 301, a target substrate, or a display substrate).

As illustrated in FIG. 8, in the cleaning step, the transfer head 1 may be mounted on a cleaning line member in a manner that is movable in the horizontal direction. In the cleaning step, an apparatus 803 performing the cleaning step, and the first substrate 101 and the second substrate 301 that are on top of a base member 804 may be sequentially arranged according to order of processing. In this case, order of arrangement in FIG. 8 is illustrated as one example and is not limited to this example. The cleaning step may be performed before the micro-LED (ML) on the first substrate 101 is absorbed and/or after the micro-LED (ML) is transferred to the second substrate 301.

When performing the cleaning step, a protrusion portion 801 that seals a cleaning space 802 in which the absorption surface 1a is cleaned may be additionally provided on the transfer head 1 in order to increase the cleaning efficiency of the cleaning space 802. The protrusion portion 801 may be provided on the periphery of the transfer head 1. The periphery here of the transfer head 1 may mean a region other than the micro-LED presence region in which the micro-LEDs (ML) is present in a state of being absorbed to the absorption surface 1a.

The cleaning step may be performed by at least one apparatus of a plasma generation apparatus 803, a purge gas injection apparatus 803, an ionic-wind injection apparatus 803, and a static electricity removal apparatus 803. In FIG. 8, for convenience, the same reference numeral is assigned to these apparatuses.

In a case where the cleaning step is performed by the plasma generation apparatus 803, plasma is generated to perform plasm treatment on the absorption surface 1a of the transfer head 1, and thus may clean the absorption surface 1a to remove a foreign material therefrom. The absorption surface 1a of the transfer head 1 is a surface to which the micro-LED (ML) is adsorbed. Therefore, when a foreign material occurring due to frequent absorbing is not removed by cleaning, the absorption force may be decreased. For example, when the absorption surface 1a of the transfer head 1 is configured as a porous member, the foreign material may block a pore. Thus, the absorption force is decreased. The plasma generation apparatus 803 generates plasma and thus may remove this foreign material on the absorption surface 1a that decreasing the absorption force. The plasm generated by the plasma generation apparatus 803 may burn the foreign material for being removed. The foreign material here may be a material formed on the absorption surface 1a of the transfer head 1 and may be a material present in the cleaning space 802 in which the absorption surface 1a is cleaned. The transfer head 1 from which the foreign material is removed by the plasma generated by the plasma generation apparatus 803 may transfer the micro-LED (ML) more effectively.

The cleaning step may be performed by the purge gas injection apparatus 803. In this case, the purge gas injection apparatus 803 may inject purge gas and may remove a foreign material or the like on the absorption surface 1a of the transfer head 1 that decreases the absorption force. The purge gas injection apparatus 803 may have a structure in which gas is injected through each of the plurality of injection nozzles mounted or may be configured in such a manner as to perform surface injection to inject a uniform amount of gas at uniform amount. A plate having a plurality of pores or holes is provided, as an upper plate, to perform the surface injection. Alternatively, a porous member may be provided.

For cleaning, the purge gas injection apparatus 803 may inject the purge gas to remove static electricity or the like that prevents the micro-LED (ML) from being absorbed to the absorption surface 1a. For example, the static electricity may occur due to contact, friction, stripping, or the like between the transfer head, the micro-LED (ML), and the circuit substrate 301 while the transfer head, of which the absorption surface is configured as a porous member, transfers the micro-LED (ML). Furthermore, the static electricity may occur due to airflow or the like inside a pore while the transfer head absorbs the micro-LED (ML) with a vacuum suction force.

In a case where the micro-LED (ML) is absorbed with an electrostatic force, static electricity needs to be positively induced. However, an electrostatic force, if not in use, needs to be removed when absorbing the micro-LED (ML). The purge gas injection apparatus 803 injects the purge gas and thus may remove the static electricity formed on the absorption surface 1a of the transfer head 1. The purge gas here, if capable of removing static electricity, is not limited. For example, the purge gas may an ionized gas. The static electricity occurring on the absorption surface 1a of the transfer head 1 may be removed while the ionized gas is injected toward the absorption surface 1a of the transfer head 1 of which the absorption surface 1a is configured as the porous member.

A foreign material may cause the transfer head 1 to be prevented from absorbing the micro-LED (ML). For example, because the transfer head 1 of which the absorption surface 1a is configured as a porous member has a plurality of fine-sized poles or fine-sized through-holes, a foreign material may be stuck on the absorption surface 1a of the porous member during a transfer process. Thus, this blocking may cause blocking the pore and the through-hole. The foreign material, when blocking the pore in the porous member, decreases the absorption force of the transfer head 1. In addition, the foreign material, when blocking a pore in one region of the porous member, may cause the lack of uniformity in the absorption force of the corresponding region to be exerted on the micro-LED (ML). Therefore, the foreign material needs to be removed from the absorption surface 1a of the porous member by cleaning. The purge gas injection apparatus 803 may inject the purge gas toward the absorption surface 1a to clean the absorption surface 1a for the removal of the foreign material. The purge gas here, if desirable for removing a foreign material, is not limited. For example, the purge gas may be inert gas, such as nitrogen or argon.

The cleaning step may be performed by the ionic-wind injection apparatus 803. Static electricity resulting from electrostatic charge may occur due to friction or the like between the growth substrate 101, the transfer head 1, and the micro-LED or between the circuit substrate 301 and the transfer head 1 while the transfer head 1 performs the transfer process. Thus, after the transfer head 1 absorbs the micro-LED (ML) from the growth substrate 101, during an unloading process of mounting the micro-LED (ML) on the circuit substrate 301, the micro-LED (ML) is unloaded onto the circuit substrate 301 in a state of being stuck to a wrong position on the transfer head 1, or cannot be unloaded. By injecting ionic wind, the ionic-wind injection apparatus 803 may clean the absorption surface 1a to remove the static electricity occurring thereon.

The cleaning step may be performed by the static electricity removal apparatus 803 removing static electricity. For example, the static electricity removal apparatus 803 may be an electron capture detector (ECD). The static electricity removal apparatus 803 may come into contact with the absorption surface 1a of the transfer head 1 and thus may remove the static electricity occurring due to friction while the transfer head 1 performs the transfer process.

The cleaning step may be performed by an apparatus that performs cleaning by wipe off a foreign material or an apparatus that performs cleaning by a cleaning solution. An apparatus, if capable of removing an obstacle preventing adsorption to the absorption surface 1a of the transfer head 1, is not limited. At this point, in a case where the cleaning solution is injected, a drying apparatus that dries the absorption surface 1a of the transfer head 1 may be additionally provided inside or outside an apparatus for injecting a cleaning solution.

4. Step of Separating the Micro-LED from the First Substrate

The transfer head (1, 1′, 1″, 1′″, 1″″) in the first embodiment to the ninth embodiment may perform a sept of separating the micro-LED (ML) from the first substrate 101 in order to perform a transfer step of absorbing the micro-LED (ML) from the first substrate (for example, the growth substrate 101 or a temporary substrate) and transferring the micro-LED (ML) to the second substrate (for example, the circuit substrate 301, a target substrate, or a display substrate).

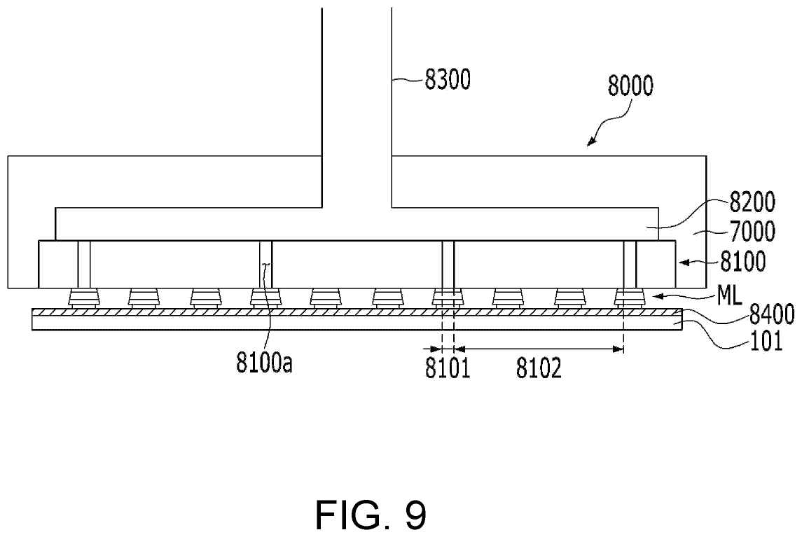

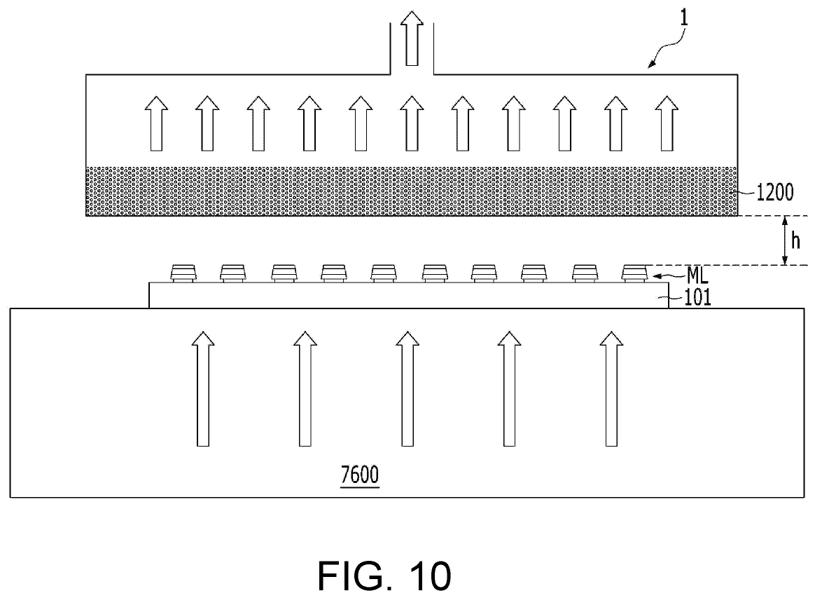

FIGS. 9 and 10 are views each illustrating an implementation example of separating the micro-LED (ML) from the first substrate 101. In order to separate the micro-LED (ML) from the first substrate 101, a separate apparatus may be used, or the transfer head serving to separate the micro-LED (ML) may be used. The transfer head serving to separate the micro-LED (ML) from the first substrate 101 may also serve to absorb the separated the micro-LED (ML) and to transfer the separated micro-LED (ML) to the second substrate.

The transfer head is illustrated, in FIGS. 9 and 10, as having a widely different structure than the transfer head in the first embodiment to the ninth embodiment, but may be provided to have the same structure. The transfer head, if capable of absorbing the micro-LED (ML) and separating the micro-LED (ML) from the first substrate 101 is not limited in structure.

The micro-LED (ML) separated from the first substrate 101 may be transported by the transfer head to the second substrate 301. In this case, the transfer head may be configured as a transfer head that uses at least one of a vacuum suction force, an electrostatic force, a magnetic force, and a van der Waals force.

In order to transfer the micro-LED (ML) on the first substrate (for example, the growth substrate 101 or a temporary substrate) to the second substrate (for example, the circuit substrate 301, a target substrate, or a display substrate), a step of separating the micro-LED (ML) from the first substrate 101 may be performed.

In order to separate the micro-LED (ML) from the first substrate 101, hot air is injected toward the absorption region 2000 of the transfer head. Accordingly, the micro-LED (ML) may be separated from the first substrate 101.

The transfer head may inject hot air toward the absorption region 2000 through the suction pipe 1400, using a means of supplying hot air. In this case, the transfer head may serve to absorb and transfer the micro-LED (ML), and additionally, may serve as a hot-air head 8000 that injects hot air for separating the micro-LED (ML) from the first substrate 101. In addition, the hot-air head 8000 that serves only to inject hot air toward the micro-LED (ML) may be separately provided in order to separate the micro-LED (ML) from the first substrate 101.

First, a method of separating the micro-LED (ML) from the first substrate 101 will be described with reference to FIG. 9 on the assumption that hot-air head 8000 that serves only to inject hot air is provided.

FIG. 9 is a view illustrating a state where the hot-air head 8000 injects hot air in a state of being brought into contact with the upper surface of the micro-LED (ML) on the first substrate 101. As illustrated in FIG. 9, the micro-LED (ML) on the first substrate 101 may be separated by the hot-air head 8000 from the first substrate 101.

The hot-air head 8000 is configured to include an injection unit 8100 injecting hot air and the fixation support unit 7000 supporting the injection unit 8100 at an upper surface of the injection unit 8100. Thus, the hot-air head 8000 may inject hot air toward the micro-LED (ML). In this case, the hot-air head 8000 may inject hot air toward the injection unit 8100 and thus may separate the micro-LED (ML) from the first substrate 101, and may bond the micro-LED (ML) transferred to the second substrate 301.

The injection unit 8100 includes an injection hole 8100a through which hot air is discharged, and injects hot air through the injection hole 8100a. The injection hole 8100a is formed in the injection unit 8100 in a manner that passes therethrough from top to bottom. If the injection hole 8100a is formed in such a manner as to have a width of several tens μm or less, the injection unit 8100 may be formed of a material, such as metal, non-metal, ceramic, glass, silicon (PDMS), or resin.

An injection region 8101 in which hot air is injected through the injection hole 8100a may be formed in the injection unit 8100. In addition, the non-injection region 8102 in which the injection hole 8100a is formed and in which hot is injected may be formed in the injection unit 8100. In this manner, the injection unit 8100 may be configured to include the injection region 8101 and the non-injection region 8102.

In a case where the injection unit 8100 is formed of a metal material, there is an advantage in that, when transferring the micro-LED (ML), static electricity can be prevented from occurring. In a case where the injection unit 8100 is formed of a non-metal material, there is an advantage in that an effect that the injection unit 8100 not having a metal property has on the micro-LED (ML) having a metal property can be minimized.

In a case where the injection unit 8100 is formed of ceramic, glass, quartz, or the like, the injection unit 8100 has structural rigidity and a low thermal expansion coefficient. Thus, the likelihood of occurrence of the positional error due to thermal deformation of the injection unit 8100 can be minimized when transferring the micro-LED (ML).

In a case where the injection unit 8100 is formed of a material, such as silicon or PDMS, although a lower surface of the injection unit 8100 is brought into direction with the upper surface of the micro-LED (ML), the injection 8100 serves as a buffer. Thus, the likelihood of damage to the injection unit 8100 due to collision with the micro-LED (ML) can be minimized.

In a case where the injection unit 8100 is formed of a resin material, the advantage of simply manufacturing the injection unit 8100 can be achieved.

The injection unit 8100 may be formed as an anodic oxide film manufactured by anodically oxidizing a metal. In this case, the anodic oxide film has the same configuration as the anodic oxide in the first embodiment. A detailed description of the configuration of the anodic oxide is omitted.

A hole in a vertical form is formed in the anodic oxide film by performing etching using a mask. This hole is formed in such a manner as to have a greater width than a pore that is naturally formed in the anodic oxide film. This hole serves as the injection hole 8100a in the hot-air head 8000. In this manner, in a case where the anodic oxide film is used as the material of the injection unit 8100, it is easy to form a shape of the injection hole 8100a vertically (in the z-axis direction) using the fact that the anodic oxide reacts with an etching solution and thus forms a vertical hole.

The injection holes 8100a may be formed in the injection unit 8100 in such a manner that they are spaced apart by a predetermined distance in the x (row) direction and/or in the y (column) direction to correspond, on a one-to-one basis, to the micro-LEDs (ML) arranged on the first substrate 101. Accordingly, simultaneous debonding of the micro-LEDs (ML) on the first substrate 101 may be performed.

Alternatively, the injection unit 8100 may selectively inject hot air toward only the micro-LED (ML) that is a transfer target. In this case, the injection holes 8100a may be formed in such a manner that they are spaced apart by a distance in at least one of the x- and y-directions that is three or more times the pitch distance in at least one of the x and y-directions between the micro-LEDs (ML) arranged on the first substrate 101.

The injection holes 8100a are formed in this manner, considering the pixel arrangement on the second substrate 301. The hot-air head 8000 with this configuration may be realized like the hot-air head 8000 illustrated in FIG. 9.

The fixation support unit 7000 is mounted in such a manner to support the injection unit 8100. Because the fixation support unit 7000 is formed of a metal material, the fixation support unit 7000 may be prevented from being warped. The fixation support unit 7000 has substantially the same thermal expansion coefficient as the injection unit 8100. Thus, when the injection unit 8100 is thermally deformed by thermal energy in a transfer space, the fixation support unit 7000 is thermally deformed together with the injection unit 8100. Thus, the injection unit 8100 can be prevented from being damaged.

A chamber 8200 is provided between the injection unit 8100 and the fixation support unit 7000. The chamber 8200 may be provided into an empty space formed between the upper surface of the injection unit 8100 and an inner lower surface of the fixation support unit 7000 and may supply uniform hot air to the injection holes 8100a in the injection unit 8100.

A pipe 8300 communicating with the chamber 8200 may be provided in the fixation support unit 7000. The chamber 8200 is provided between the pipe 8300 and a plurality of injection holes 8100a and serves to supply the hot air supplied through the pipe 8300 to the plurality of injection holes 8100a in a distributive manner. In other words, the hot air supplied through the pipe 8300 is diffused in the horizontal direction by the chamber 8200. Then, the diffused hot air passes through the injection hole 8100a in the injection unit 8100, flows along an injection surface of the injection unit 8100, and then is discharged to the outside.

A bond layer 8400 is provided on an upper surface of the first substrate 101. The bond layer 8400 may be formed on the entire upper face of the first substrate 101. Alternatively, the bond layer 8400 may be formed on the entire surface of the first substrate 101. When the micro-LED (ML) is arranged, the bond layer 8400 may fix the micro-LED (ML) in a state of being adhered. In addition, when the micro-LED (ML) is later separated from the first substrate 101, the bond layer 8400 makes stripping of the micro-LED (ML) possible. It is preferable that the bond layer 8400 is formed of, for example, a thermoplastic material. Thermoplastic resin or a thermal stripping material is suitable. In a case where thermoplastic resin is used, thermoplastic resin is plasticized by heating the bond layer 8400. Accordingly, an adhesion force between the bond layer 8400 and the micro-LED (ML) is decreased, and thus the micro-LED (ML) may be easily stripped. In addition, the thermal stripping material means a material in which a blowing agent or an expanding agent is contained and of which an adhesive area is reduced, thereby decreasing an adhesive force, when the blowing agent or the expanding agent is foamed or expanded by heating.

A strip layer (not illustrated) may be formed on top of the first substrate 101, and then the bond layer 8400 may be formed on top of the strip layer. The strip layer may be formed of, for example, fluorine coating, silicone resin, a water-soluble adhesive (for example, PVA), or polyimide.

In a case where the first substrate 101 is a temporary substrate and where the micro-LEDs (ML) on the first substrate 101 are simultaneously separated, it is preferable that the first substrate 101 is formed of a material having high thermal conductivity. In contrast, in a case where the micro-LED (ML) on the first substrate 101 is selectively separated, it is preferable that the first substrate 101 is formed of a material having low thermal conductivity.

As illustrated in FIG. 9, with the hot-air head 8000, in which the injection holes 8100a are formed spaced apart by a distance as much as three times the pitch distance in the x- and y-directions between the micro-LEDs (ML) arranged on the first substrate 101, the injection unit 8100 may inject hot air to upper surfaces of the first, fourth, seventh, and tenth micro-LEDs (ML), among the micro-LEDs (ML) present on the first substrate 101. Thus, the upper surfaces of the first, fourth, seventh, and tenth micro-LEDs (ML) present on the first substrate 101 may be heated. In other words, through the injection region 8101 of the injection unit 8100, the hot air may be selectively discharged, and thus the upper surface of the micro-LED (ML) that corresponds to the injection region 8101 may be heated.

A bonding force may disappear between the first, fourth, seventh, and tenth micro-LEDs (ML) on the first substrate 101, which are heated by the hot-air head 8000, and the bond layer 8400. In contrast, a bonding force acts between the micro-LEDs (ML) other than the first, fourth, seventh, and tenth micro-LEDs (ML) on the first substrate 101, which are heated, and the bond layer 8400. When the micro-LED (ML) that is a non-transfer target is fixed to the first substrate 101 until the bonding force disappears in a subsequent transfer cycle by the hot-air head 8000.

In this manner, the hot air supplied from the injection region 8101 may heat the micro-LED (ML) at a corresponding position. Accordingly, a region of the bond layer 8400 at a position that corresponds to the injection region 8101 may also be heated. The region of the bond layer 8400 that corresponds to the micro-LED (ML) that is a transfer target has a temperature gradient. When the bond layer 8400 is heated to a specific temperature or higher, a bonding force thereof disappears. For example, when the temperature of the bond layer 8400 is raised to a temperature of 200 C.° or higher, the bonding force thereof disappears. In this case, a bonding force between a lower surface of the micro-LED (ML), which is a transfer target, and the bond layer 8400 completely disappears or is decreased to a predetermined level.

The hot-air head 8000, as illustrated in FIG. 9, may inject hot air in a state of being in contact with the micro-LED (ML) and may heat the upper surface of the micro-LED (ML). Alternatively, the hot-air head 8000 may discharge the hot air in a state of being spaced away from the micro-LED (ML) for non-contact therewith and may heat the upper surface of the micro-LED (ML). However, thermal energy may be supplied to the bond layer 8400 in a more concentrated manner when the hot-air head 8000 and the micro-LED (ML) are in contact with each other than when the hot-air head 8000 and the micro-LED (ML) are not in contact with each other. Thus, the micro-LED (ML) can be easily stripped.

Because the non-injection region 8102 is a region in which the injection hole 8100a is not formed, the micro-LED (ML) at a position that corresponds to the non-injection region 8102 is not supplied with hot air. Therefore, a temperature of the lower surface thereof is not raised to a specific temperature or higher. The micro-LED (ML) on the first substrate 101 at the position that corresponds to the non-injection region 8102, as a non-transfer target, may be kept fixed to the bond layer 8400.

With the hot air selectively supplied by the hot-air head 8000, the micro-LEDs (ML) bonded by the bond layer 8400 to the first substrate 101 may be divided into the micro-LEDs (ML) that are a transfer target and the micro-LEDs (ML) that are a non-transfer target. There occurs a difference in a boding force on the bond layer 8400 between the micro-LED (ML) that is a transfer target and the micro-LED (ML) is a non-transfer target. Only the micro-LED (ML) that is a transfer target may be selectively separated from the first substrate 101.

A heater (not illustrated) may be provided on the first substrate 101. When the hot-air head 8000 applies hot air through the upper surface of the micro-LED (ML), the heater provided on the first substrate 101 operates, and thus increases the temperature of the lower surface of the micro-LED (ML). Thus, a specific temperature at which the bonding force of the bond layer 8400 disappears may be reached more easily.

The micro-LED (ML) selectively separated by the hot-air head 8000 from the first substrate 101 may be absorbed to the transfer head and may be transferred to the second substrate.

Hot air is injected to the absorption region of the transfer head through the suction pipe 1400. Thus, the transfer head may function as the hot-air head 8000. In this case, the transfer head may have the same configuration and structure as the hot-air head 8000. The transfer head that serves to inject hot air may form a vacuum in the injection hole 8100a in the hot-air head 8000, and thus may absorb only the micro-LED (ML) that is a transfer target, with a vacuum suction force. In a case where the transfer head forms the vacuum in the injection hole 8100a in the hot-air head 8000 and thus absorbs the micro-LED (ML), the hot-air head 8000 may be a transfer head serving to absorb and transfer a micro-LED and to inject hot air. The transfer head having these functions may absorb the micro-LED (ML) using the vacuum suction force.

When the micro-LED (ML) is stripped from the bond layer 8400 of the first substrate 101, the injection hole 8100a may serve as a path for injecting hot air toward the micro-LED (ML). In a case where the stripped micro-LED (ML) that is a transfer target is absorbed, the injection hole 8100a may function as the absorption hole 1500 for supplying the vacuum pressure formed by the vacuum pump to the transfer target the micro-LED (ML). In this manner, the injection hole 8100a serves both to inject hot air and to form vacuum. In a case where hot air is injected through the injection hole 8100a, the injection region 8101 may be formed in the injection hole 8100a. In a case where vacuum is formed in the injection hole 8100a and the micro-LED (ML) is absorbed, the absorption region 2000 absorbing the micro-LED (ML) may be formed by the injection hole 8100a.

In a case where hot air is injected to the absorption region 2000 of the transfer head 1 and thus the transfer head 1 serves as the hot-air head 8000, the injection unit 8100 of the hot-air head 8000 may function as the absorption member 1100. The transfer head 1 having this function may separate the micro-LED (ML) from the first substrate 101, may absorb the separated the micro-LED (ML) that is a transfer target, and may transfer the transfer target to the second substrate.

The absorption member 1100 of the transfer head 1 that serves both to inject hot air, which is performed by the hot-air head 8000, and to absorb and transfer a micro-LED (ML) may have the same configuration as the absorption member 1100 of each of the transfer heads (1, 1′, 1″, 1′″, and 1″″) in the first to ninth embodiments above described. As one example, the absorption member 1100 may be configured as an anodic oxide film. The absorption member 1100 is as described above, and thus a description thereof is omitted.

As described above, the micro-LED (ML) on the first substrate 101 may be separated from the first substrate 101 using a method in which hot air is injected with the transfer head serving both to inject hot air and to absorb and transfer a micro-LED or with the separate hot-air head 8000 serving to inject hot air. In this case, with the pitch distance between the injection regions 8101 provided in the hot-air head 8000, the micro-LED (ML) on the first substrate 101 may be selectively separated from the first substrate 101.

In addition, the transfer head that further serves as the hot-air head 8000 may separate the micro-LED (ML) from the first substrate 101 and then may serve to absorb the micro-LED (ML) separated from the first substrate 101 and to transport the absorbed the micro-LED (ML) to the second substrate 301. In this case, the absorption region 2000 absorbing the micro-LED (ML) is formed according to the pitch distance between the injection holes 8100a, and thus, the transportation of the micro-LED (ML) to the second substrate 301 that reflects the pixel arrangement is possible.

According to the present invention, the hot-air head 8000 is illustrated and described above as being configured to include the injection unit 8100 and the fixation support unit 7000. However, the hot-air head 8000 is not limited to this structure. The hot-air head 8000, if capable of separating the micro-LED (ML) from the first substrate 101 using heat and forming the absorption force for absorbing the micro-LED (ML), is not limited in structure. In other words, the hot-air head 8000, if capable of serving to separate the micro-LED (ML) from the first substrate 101 using heat without being supplied with hot air, is not limited in structure. As one example, the injection unit 8100 supplying hot air may be configured to have the same double structure as the transfer head including the absorption member 1100 and the support member 1200 in the first embodiment.

FIG. 10 is a view illustrating a state where the micro-LED (ML) is separated using a separation-force generation apparatus 7600. An arrow illustrated on the transfer head 1 in FIG. 10 indicates a direction in which the absorption force on the micro-LED (ML) is generated. In addition, an arrow illustrated on the separation-force generation apparatus 7600 in FIG. 10 indicates a direction in which the separation-force generation apparatus 7600 generates a separation force on the micro-LED (ML).

As illustrated in FIG. 10, in a state where the vacuum suction force is generated, the transfer head 1 may separate the micro-LED (ML) from the first substrate 101 using the separation-force generation apparatus 7600.

The separation-force generation apparatus 7600 serves to remove an adhesion force between the micro-LED (ML) and the first substrate 101. The separation-force generation apparatus 7600 having this function may remove the adhesion force between the first substrate 101 and the micro-LED (ML) before the transfer head 1 serving to transport the micro-LED (ML) from the first substrate 101 to the second substrate 301 absorbs the micro-LED (ML).

The transfer head 1, provided together with the separation-force generation apparatus 7600, that absorbs the micro-LED (ML) separated by the separation-force generation apparatus 7600 from the first substrate 101 may be a transfer head using at least one of a vacuum suction force, an electrostatic force, a magnetic force, and a van der Waals force. As one example, the transfer head 1 that uses the vacuum suction force together with the separation-force generation apparatus 7600 is illustrated and will be described below.

In a case where the transfer head 1 uses the vacuum suction force, the transfer head 1 may have the same configuration as in the first embodiment to the ninth embodiment. In this case, the transfer head 1 may be configured to include a porous member with pores that employs the same configuration as an absorption member serving to absorb the micro-LED (ML). In this case, the porous member may have the same structure as the second porous member 1200. Therefore, the same reference characters is assigned for description. The second porous member 1200 is described above as functioning as the absorption member with reference to FIG. 10. However, the first porous member 1100 in the first embodiment may be provided under the second porous member 1200, and thus the micro-LED (ML) may be absorbed. A description of the same constituent element is omitted and a constituent element that is different in feature will be described below.

As illustrated in FIG. 10, the separation-force generation apparatus 7600 may operate in a state where the transfer head 1 and the micro-LED (ML) are spaced apart.

The separation-force generation apparatus 7600 may be configured in such a manner as to emit light to an adhesion surface between the micro-LED (ML) and the first substrate 101 and thus to separate the micro-LED (ML) from the first substrate 101.

In this case, the micro-LED (ML) may be in a state of being bonded to the first substrate 101 through an adhesion layer (not illustrated). The adhesion layer is formed of a material of which an adhesion force disappears when illuminated with light. The light here may be laser light or ultraviolet light. When the separation-force generation apparatus 7600 emits laser light or ultraviolet light to the adhesion layer, temperature of the adhesion layer absorbing the laser light or the ultraviolet light is rapidly increased by energy of the laser light or the ultraviolet light. Thus, the adhesion layer is vaporized and the adhesion force thereof disappears. Accordingly, it is possible to separate the micro-LED (ML) from the first substrate 101.

Subsequently, in a state where the transfer head 1 and the micro-LED (ML) are brought into contact with each other or are spaced apart, the micro-LED (ML) is raised. Thus, it is possible that the micro-LED (ML) is absorbed to a surface of the transfer head 1.

The separation-force generation apparatus 7600 may be configured in such a manner as to apply heat to the adhesion surface between the micro-LED (ML) and the first substrate 101 and thus to separate the micro-LED (ML) from the first substrate 101.

In this case, the micro-LED (ML) may be in a state of being bonded to the first substrate 101 through the adhesion layer (not illustrated). The adhesion layer is formed of a thermoplastic material of which an adhesion force disappears when heated. A sheet formed of thermoplastic resin, a thermal strip material, or the like is suitable as the thermoplastic material. In a case where the thermoplastic resin is used, the adhesion layer is heated, and thus the thermoplastic resin is plasticized. Accordingly, an adhesion force between the adhesion layer and the micro-LED (ML) is decreased, and thus the micro-LED (ML) may be easily stripped. The thermal stripping material means a material of which an adhesive force can be decreased by foaming or expanding due to heating and which is used to simply strip the micro-LED (ML). That is, the thermal stripping material means a material in which a blowing agent or an expanding agent is contained and of which the adhesive area is reduced, thereby causing the adhesive force to disappear, when the blowing agent or the expanding agent is foamed or expanded by heating.

When the separation-force generation apparatus 7600 applies heat to the adhesion layer, the adhesive force of the adhesion layer disappears. Thus, it is possible to separate the micro-LED (ML) from the first substrate 101. Subsequently, in a state where the transfer head 1 and the micro-LED (ML) are brought into contact with each other or are spaced apart, the micro-LED (ML) is raised. Thus, it is possible that the micro-LED (ML) is absorbed to the surface of the transfer head 1.

The separation-force generation apparatus 7600 may be configured in such a manner as to remove a magnetic force of the adhesion surface between the micro-LED (ML) and the first substrate 101 and thus to separate the micro-LED (ML) from the first substrate 101.

In this case, the micro-LED (ML) may be in a state of being bonded to the first substrate 101 with the magnetic force. The magnetic force applied by the separation-force generation apparatus 7600 has a polarity opposite to a plurality of a magnetic material added to the micro-LED (ML), and preferably, is greater than a magnetic force between the micro-LED (ML) and the first substrate 101. Accordingly, the magnetic force of the adhesion surface between the micro-LED (ML) and the first substrate 101 may be removed.

Alternatively, the micro-LED (ML) may be in a state of being to the first substrate 101 with an electromagnetic force. The separation-force generation apparatus 7600 may block supplying of electric power for the electromagnetic force, and thus may remove the magnetic force of the adhesion surface between the micro-LED (ML) and the first substrate 101.

The separation-force generation apparatus 7600 may be configured in such a manner as to emit an electromagnetic wave to the adhesion surface between the micro-LED (ML) and the first substrate 101 and thus to separate the micro-LED (ML) from the first substrate 101. When the separation-force generation apparatus 7600 emits the electromagnetic wave to the adhesion layer, the adhesive force of the adhesion layer disappears. Thus, it is possible to remove the micro-LED (ML) from the first substrate 101. Accordingly, the micro-LED (ML) is raised in the state wherein the transfer head 1 and the micro-LED (ML) are spaced apart. Thus, it is possible that the micro-LED (ML) is absorbed to the surface of the transfer head 1.

The separation-force generation apparatus 7600 may be configured in such a manner as to remove an electrostatic force of the adhesion surface between the micro-LED (ML) and the first substrate 101 and thus to separate the micro-LED (ML) from the first substrate 101. In this case, the micro-LED (ML) may be in a state of being bonded to the first substrate 101 with the electrostatic force. The separation-force generation apparatus 7600 may remove the electrostatic force of the adhesion surface between the micro-LED (ML) and the first substrate 101.

The separation-force generation apparatus 7600 may be configured in such a manner as to remove a vacuum suction force of the adhesion surface between the micro-LED (ML) and the first substrate 101 and thus to separate the micro-LED (ML) from the first substrate 101. In this case, the micro-LED (ML) may be in a state of being bonded to the first substrate 101 with the vacuum suction force. The separation-force generation apparatus 7600 may remove the vacuum suction force of the adhesion surface between the micro-LED (ML) and the first substrate 101.

As illustrated in FIG. 10, a lower end portion of the transfer head 1 may be kept spaced by a predetermined h away from the micro-LED (ML). In a state where the transfer head 1 exerts the vacuum suction force, in a case where the micro-LED (ML) is separated from the first substrate 101 using the separation-force generation apparatus 7600, the micro-LED (ML) may be raided toward the transfer head 1 and may be vacuum-absorbed to the surface of the transfer head 1. In this case, damage to the micro-LED (ML) that occurs in a method of bringing the transfer head 1 and the micro-LED (ML) into contact with each other and transferring the micro-LED (ML) can be prevented.

In this manner, the separation-force generation apparatus 7600 may be configured in such a manner that only the micro-LED (ML) that is a transfer target is selectively separated, among the micro-LEDs (ML) on the first substrate 101. Thus, the transfer head 1 may absorb the separated micro-LED (ML) and may transfer the separated micro-LED (ML) to the second substrate 301.

5. Step of Adjusting the Pitch Distance Between the Micro-LEDs

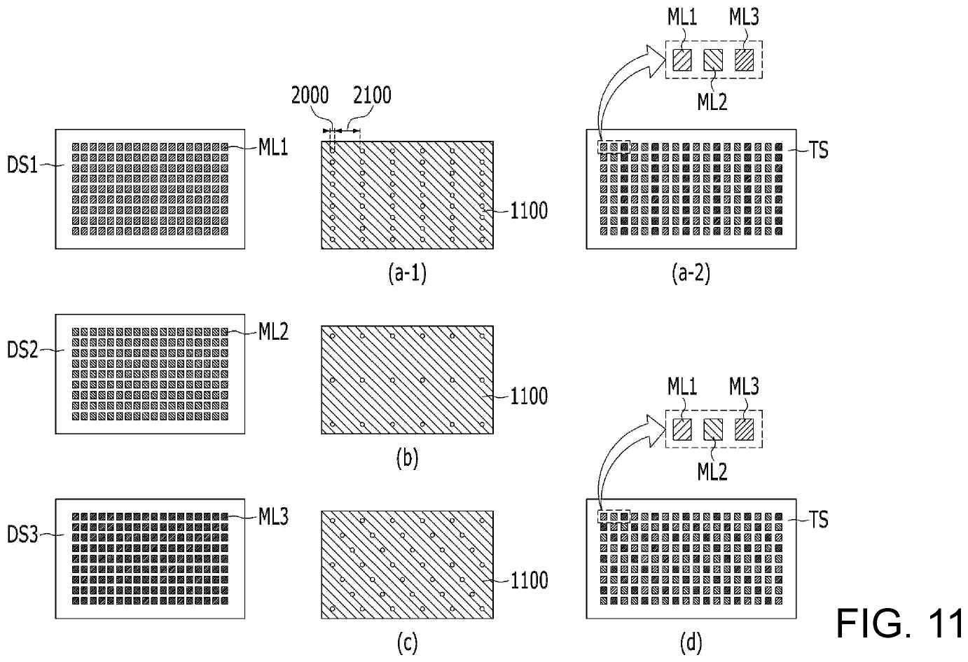

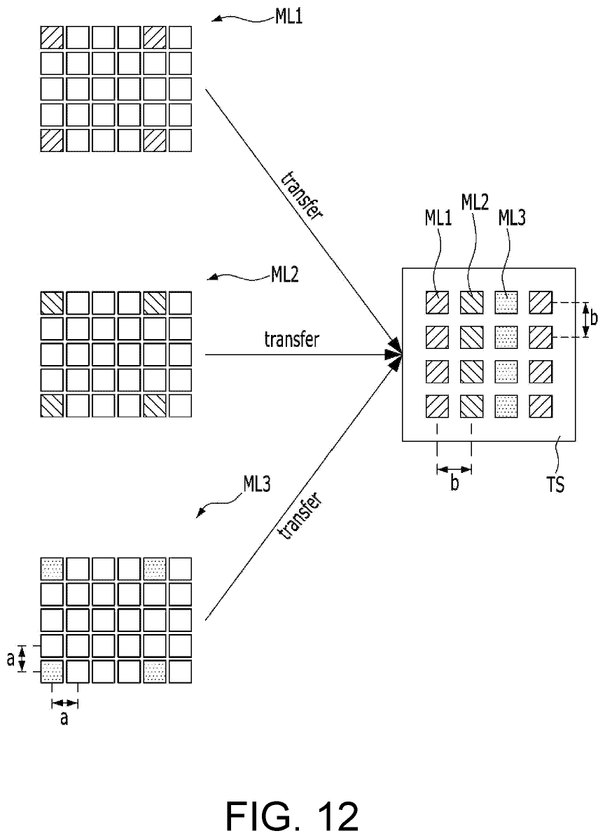

An implementation example of an arrangement of the absorption regions 2000 of the transfer head according to the present invention will be described below with reference to FIGS. 11 and 12. The micro-LED (ML) that is an absorption target and that is absorbed by the absorption region 2000 may be one of red, green, and blue micro-LEDs (ML1, ML2, and ML3) and a white micro-LED. According to the arrangement of the absorption regions 2000, the red, green, blue micro-LEDs (ML1, ML2, and ML3) are transferred to the second substrate (the circuit substrate 301) in such a manner as to be spaced apart, and thus a pixel arrangement is made.

The absorption regions 2000 are formed in such a manner as to be spaced apart by a predetermined distance in the column direction (the x-direction) and the row direction (the y-direction). The absorption regions 2000 may be formed in such a manner that they are spaced apart by a distance in at least one of the column direction and the row direction (the y-direction) as much as two or more times the pitch distance in the column direction (the x-direction) and the row direction (the y-direction) between the micro-LEDs (ML) arranged on the first substrate.

As illustrated in FIG. 11(a-1), in a case where the pitch distance in the column direction (the x-direction) between the micro-LEDs (ML) on each of the donor substrates (DS1, DS2, and DS3) is P(n), and where the pitch distance in the row direction (the y-direction) is P(m), a pitch distance in the column direction (the x-direction between the absorption regions 2000 may be 3P(n) and a pitch distance in the row direction (the y-direction) may be P (m). 3P(n) means three times the pitch distance P(n) in the column direction (the x-direction) between the micro-LED (ML) on each of the donor substrates (DS1, DS2, and DS3). With this configuration, the transfer head 1 may vacuum-absorb the micro-LEDs (ML) in the column that corresponds to a multiple of three times the pitch distance and may transport the absorbed micro-LEDs (ML). At this point, the micro-LED (ML) that is transported to the column that corresponds to a multiple of three times the pitch distance may be one of red, green, and blue micro-LEDs (ML1, ML2, and ML3) and a white micro-LED. With this configuration, the micro-LEDs (ML) in the same color that are mounted on a target substrate TS may be transferred in a state of being spaced apart by a distance of P(m). The target substrate TS illustrated in FIG. 11 may be the circuit substrate 301, as the second substrate, illustrated in FIG. 2, and may be a temporary substrate or a carrier substrate, as the second substrate, that is transferred from the growth substrate 101. In addition, a donor unit or the donor substrate may be a growth substrate, a temporary, or a carrier substrate, as the first substrate.

The transfer head 1 in which the absorption regions 2000 are formed at the pitch distance described above may selectively absorb the micro-LED (ML) arranged on the donor unit. The donor unit includes the first donor substrate DS1 on which the red micro-LEDs (ML1) are arranged, the second donor substrate DS2 on which the green micro-LEDs (ML2) are arranged, and the third donor substrate DS3 on which the blue micro-LED (ML3) are arranged.

The micro-LEDs (ML) arranged on each of the donor substrates are arranged at a predetermined distance in the column direction (the x-direction) and the row direction (the y-direction). The red, green, blue micro-LEDs (ML1, ML2, and ML3) that are arranged on the first to third donor substrates (DS1, DS2, and DS3), respectively, are arranged in such a manner as to be spaced apart by the same pitch distance in the column direction (the x-direction) and the row direction (the y-direction).

The separation distance in the column direction (the x-direction) between the absorption regions 2000 illustrated in FIG. 11(a-1) is three times the pitch distance in the column direction (the x-direction) between the micro-LEDs (ML) arranged on the donor unit, and the separation distance in the row direction (the y-direction) is as much as the pitch distance in the row direction (the y-direction) between the micro-LEDs (ML) arranged on the donor unit. The transfer head 1′ in which the absorption regions 2000 are formed in this manner travels back and forth three times between each of the first to third donor substrates (DS1, DS2, and DS3) and the target substrate TS to transfer the red, green, and blue micro-LEDs (ML1, ML2, and ML3) to the target substrate TS. Thus, the red, green, and blue micro-LEDs (ML1, ML2, and ML3) are formed in a 1×3 pixel arrangement.

Specifically, as illustrated in FIG. 11, the red micro-LEDs (ML1) are arranged at a predetermined distance on the first donor substrate DS1. The transfer head 1 descends toward the first donor substrate DS1 and selectively absorbs the red micro-LED (ML1) present at a position that corresponds to the absorption region 2000. With reference to FIG. 11(a-1), the transfer head 1 selectively vacuum-absorbs only the red micro-LEDs (ML1) that correspond to the first, fourth, seventh, tenth, 13-rd, and 16-th columns. When the absorbing is completed, the transfer head 1 ascends, then moves horizontally, and is positioned over the target substrate TS. Thereafter, the transfer head 1 descends and simultaneously transfers the red micro-LEDs (ML1).

Then, the transfer head 1 absorbs the green micro-LEDs (ML2) on the second donor substrate (DS2) and transfers the absorbed green micro-LEDs (ML2) to the target substrate TS. At this time, the transfer head 1 is positioned a distance as much as the pitch distance in the x-direction between the micro-LEDs (ML), to the right side of the drawing, away from the red micro-LEDs (ML1) already transferred to the target substrate TS, and simultaneously transfers the green micro-LEDs (ML2) to the target substrate TS.

Then, the transfer head 1 moves to over the third donor substrate DS3. Thereafter, by performing the same process as when transferring the red micro-LEDs (ML1), the transfer head 1 absorbs the blue micro-LEDs (ML3) on the third donor substrate DS3 and transfers the absorbed blue micro-LEDs (ML3) to the target substrate TS. At this point time, the transfer head 1 is positioned a distance as much as the pitch distance in the x-direction between the micro-LEDs (ML), to the right side of the drawing, away from the green micro-LEDs (ML2) already transferred to the target substrate TS, and simultaneously transfers the blue micro-LEDs (ML3) to the target substrate TS.

The target substrate TS with the 1×3 pixel arrangement that is made in this manner may be realized as in FIG. 11(a-2). With this configuration, the micro-LED (ML) may be transferred in such a manner that the pitch distance in the x-direction between the same types of the micro-LEDs (ML) on the second substrate is three times the pitch distance in the x-direction between the same types of the micro-LEDs (ML) on the first substrate and that the pitch distance in the y-direction between the same types of the micro-LEDs (ML) on the second substrate is as much as the pitch distance in the y-direction between the same types of the micro-LEDs (ML) on the first substrate.

Alternatively, as illustrated in FIG. 11(b), the absorption regions 2000 may be formed in such a manner that the pitch distance in the column direction (the x-direction) therebetween is 3P(n) and that the pitch distance in the row direction (the y-direction) therebetween is 3P(m). With this configuration, the transfer head 1 may vacuum-absorb the micro-LEDs (ML) in the column that corresponds to a multiple of three times the pitch distance and in the row that corresponds to a multiple of three times the pitch distance may transport the absorbed micro-LEDs (ML).

The transfer head 1 with the configuration described above may transfer the micro-LED (ML) in such a manner that the pitch distance in the x-direction between the same types of the micro-LEDs (ML) on the second substrate is three times the pitch distance in the x-direction between the same types of the micro-LEDs (ML) on the first substrate and that the pitch distance in the y-direction between the same types of the micro-LEDs (ML) on the second substrate is three times the pitch distance in the y-direction between the same types of the micro-LEDs (ML) on the first substrate. At this point, the micro-LED (ML) that is transported to the column and the row that correspond to a multiple of three times the pitch distance may be one of red, green, and blue micro-LEDs (ML1, ML2, and ML3). With this configuration, the micro-LEDs (ML) in the same color that are mounted on the target substrate TS may be transferred in a state of being spaced apart by a distance of 3P(n) in the column direction and by a distance of 3P(m) in the row direction.

The separation distance in the column direction (the x-direction) between the absorption regions 2000 illustrated in FIG. 11(b) is three times the pitch distance in the column direction (the x-direction) between the micro-LEDs (ML) arranged on the donor unit, and the separation distance in the row direction (the y-direction) is three times the pitch distance in the row direction (the y-direction) between the micro-LEDs (ML) arranged on the donor unit.

As illustrated in FIG. 11(b), the transfer head 1′ in which the absorption regions 2000 are formed in such a manner that the pitch distance in the column direction (the x-direction) is 3P(n) and the pitch distance in the row direction (the y-direction) is 3P(m) travels back and forth nine times between each of the first to third donor substrates (DS1, DS2, and DS3) and the target substrate TS to transfer the red, green, and blue micro-LEDs (ML1, ML2, and ML3) to the target substrate TS. Thus, the red, green, and blue micro-LEDs (ML1, ML2, and ML3) are formed in the 1×3 pixel arrangement.

Specifically, during the first transfer, the transfer head 1 selectively absorbs the red micro-LEDs (ML1) from the first donor substrate DS1 and simultaneously the absorbed red micro-LEDs (ML1) to the target substrate TS. During the second transfer, the transfer head 1 selectively absorbs the green micro-LEDs (ML2) from the second donor substrate DS2, is positioned a distance as much as the pitch distance in the x-direction between the micro-LED (ML), to the right side of the drawing, away from the red micro-LEDs (ML1) already transferred to the target substrate TS, and simultaneously transfers the green micro-LEDs (ML2) to the target substrate TS. During the third transfer, the transfer head 1 selectively absorbs the blue micro-LEDs (ML3) from the third donor substrate DS3, is positioned a distance as much as the pitch distance in the x-direction between the micro-LEDs (ML), to the right side of the drawing, away from the green micro-LEDs (ML2) already transferred to the target substrate TS, and simultaneously transfers the blue micro-LEDs (ML3) to the target substrate TS.

During the fourth transfer, the transfer head 1 selectively absorbs the red micro-LEDs (ML1) from the first donor substrate DS1, is positioned a distance as much as the pitch distance in the y-direction between the micro-LEDs (ML), to the lower side of the drawing, away from the green micro-LEDs (ML2) already transferred to the target substrate TS, and simultaneously transfers the red micro-LEDs (ML1) to the target substrate TS. During the fifth transfer, the transfer head 1 selectively absorbs the green micro-LEDs (ML2) from the second donor substrate DS2, is positioned a distance as much as the pitch distance in the x-direction between the micro-LEDs (ML), to the right side of the drawing, away from the red micro-LEDs (ML1) transferred during the fourth transfer to the target substrate TS, and simultaneously transfers the green micro-LEDs (ML2) to the target substrate TS. During the sixth, the transfer head 1 selectively absorbs the blue micro-LEDs (ML3) from the third donor substrate DS3, is positioned a distance as much as the pitch distance in the x-direction between the micro-LEDs (ML), to the right side of the drawing, away from the green micro-LEDs (ML2) transferred during the fifth transfer to the target substrate TS, and simultaneously transfers the blue micro-LEDs (ML3) to the target substrate TS.

During the seventh transfer, the transfer head 1 selectively absorbs the red micro-LEDs (ML1) from the first donor substrate DS1, is positioned a position as much as the pitch distance in the y-direction between the micro-LEDs (ML), to the lower side of the drawing, away from the blue micro-LEDs (ML3) already transferred to the target substrate TS, and simultaneously transfers the red micro-LEDs (ML1) to the target substrate TS. During the eighth transfer, the transfer head 1 selectively absorbs the green micro-LEDs (ML2) from the second donor substrate DS2, is positioned a position as much as the pitch distance in the x-direction between the micro-LEDs (ML), to the right side of the drawing, away from the red micro-LEDs (ML1) already transferred during the seventh transfer to the target substrate TS, and simultaneously transfers the green micro-LEDs (ML2) to the target substrate TS. During the ninth, the transfer head 1 selectively absorbs the blue micro-LEDs (ML3) from the third donor substrate DS3, is positioned a position as much as the pitch distance in the x-direction between the micro-LEDs (ML), to the right side of the drawing, away from the green micro-LEDs (ML2) transferred during the eighth transfer to the target substrate TS, and simultaneously transfers the blue micro-LEDs (ML3) to the target substrate TS.

The target substrate TS with the 1×3 pixel arrangement that is made in this manner may be realized as in FIG. 11(d).

Alternatively, as illustrated in FIG. 11(c), the absorption region 2000 may be formed in such a manner that the pitch distance therebetween is the same as the pitch distance in the diagonal direction between the micro-LEDs (ML) arranged on the donor substrate. The transfer head 1 with this configuration travels back and forth three times between each of the first to third donor substrates (DS1, DS2, and DS3) and the target substrate TS to transfer the red, green, and blue micro-LEDs (ML1, ML2, and ML3) to the target substrate TS. Thus, the red, green, and blue micro-LEDs (ML1, ML2, and ML3) are formed in the 1×3 pixel arrangement.

In addition, the transfer head 1 with the above-described configuration may transfer the micro-LEDs (ML) in such a manner that the pitch distance in the diagonal direction between the same types of the micro-LEDs (ML) on the second substrate is the same as the pitch distance in the diagonal direction between the same types of the micro-LEDs (ML) on the first substrate.

Specifically, during the first transfer, the transfer head 1 selectively absorbs the red micro-LEDs (ML1) from the first donor substrate DS1 and simultaneously the absorbed red micro-LEDs (ML1) to the target substrate TS. During the second transfer, the transfer head 1 selectively absorbs the green micro-LEDs (ML2) from the second donor substrate DS2, is positioned a distance as much as the pitch distance in the x-direction between the micro-LED (ML), to the right side of the drawing, away from the red micro-LEDs (ML1) already transferred to the target substrate TS, and simultaneously transfers the green micro-LEDs (ML2) to the target substrate TS. During the third transfer, the transfer head 1 selectively absorbs the blue micro-LEDs (ML3) from the third donor substrate DS3, is positioned a distance as much as the pitch distance in the x-direction between the micro-LEDs (ML), to the right side of the drawing, away from the green micro-LEDs (ML2) already transferred to the target substrate TS, and simultaneously transfers the blue micro-LEDs (ML3) to the target substrate TS.

The target substrate TS with the 1×3 pixel arrangement that is made in this manner may be realized as in FIG. 11(d).

Alternatively, the absorption regions 2000 of the transfer head 1 may be formed in such a manner that the pitch distance in the x-direction therebetween is two times the pitch distance in the x-direction between the micro-LEDs (ML) arranged on the first substrate and that the pitch distance in the y-direction therebetween is two times the pitch distance in the y-direction between the micro-LEDs (ML) arranged on the first substrate. Thus, the transfer head 1 may selectively absorb the micro-LED (ML) arranged on the first substrate. In this case, the first substrate may include the first to third donor substrates (DS1, DS2, and DS3).

Therefore, the absorption regions 2000 may be formed in such a manner that the pitch distance therebetween is two times the pitch distance in the column direction (the x-direction) between the micro-LEDs (ML) arranged on the donor unit and the pitch distance in the row direction (the y-direction) therebetween is two times the pitch distance in the column direction (the y-direction). The transfer head 1 with this configuration travels back and forth three times between each of the first to third donor substrates (DS1, DS2, and DS3) and the target substrate TS to transfer the red, green, and blue micro-LEDs (ML1, ML2, and ML3) to the target substrate TS. Thus, the red, green, and blue micro-LEDs (ML1, ML2, and ML3) are formed in a 2×2 pixel arrangement.

The transfer head 1 with the configuration described above may transfer the micro-LED (ML) in such a manner that the pitch distance in the x-direction between the same types of the micro-LEDs (ML) on the second substrate is two times the pitch distance in the x-direction between the same types of the micro-LEDs (ML) on the first substrate and that the pitch distance in the y-direction between the same types of the micro-LEDs (ML) on the second substrate is two times the pitch distance in the y-direction between the same types of the micro-LEDs (ML) on the first substrate.

The absorption regions 2000 are formed in such a manner that the pitch distance therebetween is two times the pitch distance in the column direction (the x-direction) between the micro-LEDs (ML) on the donor unit. Thus, with only a total of three micro-LEDs (ML1, ML2, ML3), the 2×2 pixel arrangement may be made on the target substrate TS. In this case, there is an unoccupied region on which the micro-LED (ML) is additionally mounted. Considering an improvement in individual light emitting characteristic or visibility of the micro-LED (ML), the presence of a defective micro-LED (ML), and the like, the micro-LED (ML) to be added to the 2×2 pixel arrangement may be transferred to the unoccupied region. Thus, with a total of four micro-LEDs (ML), the 2×2 pixel arrangement may be made.

The transfer head 1 travels back and forth one time between one of the first to third donor substrates (DS1, DS2, and DS3) and the target substrate TS to additionally transfer one of the red, green, and blue micro-LEDs (ML1, ML2, and ML3) to the target substrate TS. Thus, a total of four micro-LEDs, that is, the red, green, and blue micro-LEDs (ML1, ML2, and ML3) and one additional micro-LED, may be formed in the 2×2 pixel arrangement. In this case, the micro-LED (ML) that is additionally transferred may be one of the red, green, and blue micro-LEDs (ML1, ML2, and ML3).

Accordingly, the light emitting characteristic or visibility of the micro-LED (ML) can be enhanced. Because the micro-LED (ML) transfer is not properly performed, the micro-LED (ML) may be left behind or the defective micro-LED (ML) may be present. In this case, a quality micro-LED (ML) may be additionally mounted. Thus, display image quality can be improved.

This configuration can find application in a structure in which with a 3≤x≤3 pixel arrangement is made only three micro-LEDs (ML1, ML2, and ML3).

The absorption regions 2000 may be formed in such a manner that the pitch distance in the column direction (the x-direction) therebetween is three times the pitch distance in the column direction (the x-direction) between the micro-LEDs (ML) arranged on the donor unit and the pitch distance in the row direction (the y-direction) therebetween is three times the pitch distance in the column direction (the y-direction). The transfer head 1 with this configuration travels back and forth three times between each of the first to third donor substrates (DS1, DS2, and DS3) and the target substrate TS to transfer the red, green, and blue micro-LEDs (ML1, ML2, and ML3) to the target substrate TS. Thus, the red, green, and blue micro-LEDs (ML1, ML2, and ML3) are formed in the 3×3 pixel arrangement.

Alternatively, the transfer head 1 may simultaneously absorb all the micro-LEDs (ML) on the substrate S for transportation thereof in a case where the absorption regions 2000 are formed in such a manner that the pitch distance in the column direction (the x-direction) therebetween is the same as the pitch distance in the column direction (the x-direction) between the micro-LEDs (ML) arranged on the substrate S and that the pitch distance in the row direction (the y-direction) therebetween is the same as the pitch distance in the row direction (the y-direction) between the micro-LEDs (ML).

The absorption regions 2000 may be formed in such a manner that the pitch distance therebetween is greater than the pitch distance between the micro-LEDs (ML) on the donor substrate 101 so that the micro-LEDs (ML) to be transferred the target substrate (TS) have a greater pitch distance than those on the donor substrate 101. Thus, the micro-LED (ML) on the donor substrate 101 may be transferred to the target substrate (TS) with the increased pitch distances being equal.

Specifically, the transfer head 1 selectively absorbs the donor substrate (for example, the micro-LEDs (ML) arranged on the growth substrate 101). However, the pitch distance in one direction between the absorption regions 2000 is M/3 times (where M is an integer that is equal to or greater than 4) the pitch distance arranged on the first substrate (the donor substrate). The transfer head 1 with this configuration may transfer the micro-LED in such a manner that the pitch distance in one direction between the same types of the micro-LEDs (ML) on the second substrate (the target substrate) is M/3 times (where M is an integer that is equal to or greater than 4) the pitch distance in one direction between the micro-LEDs (ML) on the first substrate.

With reference to 12, a second pitch distance b between the micro-LEDs (ML) on the target substrate TS is M/3 times a first pitch distance a between the micro-LEDs (ML) on the donor unit. In this case, the pitch distance between the absorption regions 2000 for absorbing the micro-LEDs (ML) to be transferred to the target substrate TS is M/3 times (where M is an integer that is equal to or greater than 4) the pitch distance between the micro-LEDs (ML) on the donor substrate 101.

The absorption regions 2000 that absorbs the micro-LED (ML) on the donor substrate may be formed in such a manner that the pitch distance therebetween is 4 or more times the first pitch distance between the micro-LEDs (ML) on the donor substrate, in order that the micro-LEDs (ML) is transferred to the target substrate TS in a state where the pitch distance between the micro-LEDs (ML) to be transferred is the second pitch distance b as much as M/3 times the first pitch distance between the micro-LEDs (ML) on the donor substrate. As one example, the absorption region 2000 that absorbs the micro-LED (ML) on the donor substrate is described below as being formed in such a manner that the pitch distance therebetween is four times the first pitch distance a between the micro-LEDs (ML) on the donor substrate. A maximum pitch distance here of the absorption region 2000 is a minimum distance for realizing pixels on the target substrate TS.

The transfer head 1 including the absorption region 2000 formed in such a manner that the pitch distance therebetween is four times the first pitch distance a between the micro-LEDs (ML) on the donor substrate may absorb the micro-LEDs (ML) on the donor substrate and may transfer the micro-LEDs (ML) in such a manner that the pitch distance between the micro-LEDs (ML) is the second pitch distance b as much as M/3 times the first pitch distance a between the micro-LEDs (ML) on the donor substrate as on the target substrate TS illustrated in FIG. 12.

Specifically, the red micro-LEDs (ML1) are arranged the first pitch distance a on the first donor substrate DS1. The green micro-LEDs (ML2) are arranged the first pitch distance a on the second donor substrate (DS2), and the blue micro-LEDs (ML3) are also arranged the first pitch distance a on the third donor substrate DS3.

During the first transfer, the transfer head 1 descends toward the first donor substrate DS1 and selectively absorbs the red micro-LEDs (ML1) present at positions that correspond to the absorption regions 2000, respectively, in the first row and first column, the first row and fifth column, the fifth row and first column, and the fifth row and fifth column. Then, the transfer head 1 moves to over the target substrate TS and simultaneously transfers the red micro-LEDs (ML1) to the target substrate TS. During the second transfer, the transfer head 1 absorbs the green micro-LEDs (ML2) in the first row and first column, the first row and fifth column, the fifth row and first column, and the fifth row and fifth column on the second donor substrate (DS2). Thereafter, the transfer head 1 moves by a distance as much as the second pitch distance b in the x-direction between the micro-LED (ML), to the right side of the drawing, away from the red micro-LEDs (ML1) already transferred to the target substrate TS, and simultaneously transfers the green micro-LEDs (ML2) to the target substrate TS. Thereafter, during the third transfer, the transfer head 1 moves to over the third donor substrate DS3. The transfer head 1 absorbs the blue micro-LEDs (ML3) in the first row and first column, the first row and fifth column, the fifth row and first column, and the fifth row and fifth column on the third donor substrate DS3 and transfers the absorbed blue micro-LEDs (ML3) to the target substrate TS. In this case, the transfer head 1 moves by a distance as much as the second pitch distance b in the x-direction between the micro-LED (ML), to the right side of the drawing, away from the green micro-LEDs (ML2) already transferred during the second transfer to the target substrate TS, and simultaneously transfers the blue micro-LEDs (ML3) to the target substrate TS.

Thereafter, during the fourth transfer, the transfer head 1 selectively absorbs the red micro-LEDs (ML1) at positions that correspond to the absorption regions 2000, respectively, from the first donor substrate DS1, moves by a distance as much as the second pitch distance b in the y-direction, to the lower side of the drawing, away from the red micro-LEDs (ML1) transferred during the first transfer to the target substrate TS, and simultaneously transfers the red micro-LEDs (ML1) to the target substrate TS. Thereafter, during the fifth transfer, the transfer head 1 selectively absorbs the green micro-LEDs (ML2) at positions that correspond to the absorption regions 2000, respectively, from the second donor substrate DS2, moves by a distance as much as the second pitch distance b in the x-direction, to the right side of the drawing, away from the red micro-LEDs (ML1) transferred during the fourth transfer to the target substrate TS, and simultaneously transfers the green micro-LEDs (ML2) to the target substrate TS. Thereafter, during the sixth transfer, the transfer head 1 selectively absorbs the blue micro-LEDs (ML3) at positions that correspond to the absorption regions 2000, respectively, from the third donor substrate DS3, moves by a distance as much as the second pitch distance b in the x-direction, to the right side of the drawing, away from the green micro-LEDs (ML2) transferred during the fifth transfer to the target substrate TS, and simultaneously transfers the blue micro-LEDs (ML3) to the target substrate TS.

Thereafter, during the seventh transfer, the transfer head 1 selectively absorbs the red micro-LEDs (ML1) at positions that correspond to the absorption regions 2000, respectively, from the first donor substrate DS1, moves by a distance as much as the second pitch distance b in the y-direction, to the lower side of the drawing, away from the red micro-LEDs (ML1) already transferred during the fourth transfer to the target substrate TS, and simultaneously transfers the red micro-LEDs (ML1) to the target substrate TS. Thereafter, during the fifth transfer, the transfer head 1 selectively absorbs the green micro-LEDs (ML2) in the same manner as during the fifth transfer, moves by a distance as much as the second pitch distance b in the x-direction, to the right side of the drawing, away from the red micro-LEDs (ML1) transferred during the seventh, and simultaneously transfers the green micro-LEDs (ML2). Thereafter, during the ninth transfer, the transfer head 1 absorbs the blue micro-LEDs (ML3) in the same manner as during the sixth transfer, moves by a distance as much as the second pitch distance b in the x-direction, to the right side of the drawing, away from the green micro-LEDs (ML2) transferred during the eighth, and simultaneously transfers the blue micro-LEDs (ML3).

In this manner, with the absorption regions 2000, the pitch distance between which is 4-four times the first pitch distance a between the micro-LEDs (ML) on the donor substrate, the micro-LEDs (ML1, ML2, and ML3) may be transferred to the target substrate TS in a such a manner that the equal pitch distances in the column direction (the x-direction) and the row direction (the y-direction) on the target substrate TS are greater than the pitch distances in the column direction (the x-direction) and the row direction (the y-direction) between the micro-LEDs (ML) on the donor substrate.

With the arrangement of the absorption regions 2000, the transfer head 1 travels back and forth 9-nine times between each of the first to third donor substrates (DS1, DS2, and DS3) and the target substrate TS to transfer the red, green, and blue micro-LEDs (ML1, ML2, and ML3) to the target substrate TS. Thus, three micro-LEDs (ML1, ML2, and ML3) may be formed in the 1×3 pixel arrangement on the target substrate TS, and the same types of the micro-LEDs (ML) may be transferred into the same column.

A method of transferring the same type of the micro-LEDs (ML) into the same column is not limited to that described above. In addition to the method described above, the transfer head 1 may transfer the micro-LEDs (ML) using a suitable method of transferring the same types of micro-LEDs (ML) in the same column on the target substrate TS.

Alternatively, the transfer head 1 may move at a position in the column direction (the x-direction) and row direction (the y-direction) over the target substrate TS and may transfer three micro-LEDs (ML1, ML2, and ML3) in such a manner as to make the 1×3 arrangement that is different from the arrangement in which the same types of the micro-LEDs (ML) are transferred into the same column.

Specifically, the transfer head 1 may move by a distance as much as the second pitch distance b in the x-direction rightward from the same types of the micro-LEDs (ML) already transferred, may move by a distance as much as the second pitch distance b in the y-direction downward therefrom and may transfer the micro-LEDs (ML).

During the fourth transfer, the transfer head 1 selectively absorbs the red micro-LEDs (ML1) from the first donor substrate DS1, moves by a distance as much as the second pitch distance b in the y-direction downward from the red micro-LEDs (ML1) already transferred during the first transfer to the target substrate TS, moves by a distance as much as the second pitch distance b in the x-direction rightward therefrom, and simultaneously transfers the red micro-LEDs (ML1) to the target substrate TS. Thereafter, during the fifth transfer, the transfer head 1 selectively absorbs the green micro-LEDs (ML2) on the second donor substrate (DS2), moves by a distance as much as the second pitch distance b in the y-direction downward from the green micro-LEDs (ML2) already transferred during the second transfer to the target substrate TS, moves by a distance as much as the second pitch distance b in the x-direction rightward therefrom, and simultaneously transfers the green micro-LEDs (ML2) to the target substrate TS. Thereafter, during the sixth transfer, the transfer head 1 selectively absorbs the blue micro-LEDs (ML3) on the third donor substrate (DS3), moves by a distance as much as the second pitch distance b in the y-direction downward from the blue micro-LEDs (ML3) transferred during the third transfer to the target substrate TS, moves by a distance as much as the second pitch distance b in the x-direction rightward therefrom, and simultaneously transfers the blue micro-LEDs (ML3) to the target substrate TS.

As described above, the transfer head moves by a distance as much as the second pitch distance b in the x-direction rightward from the same type of the micro-LEDs (ML) already transferred, moves by a distance as much as the second pitch distance b in the y-direction downward therefrom, and transfers the blue micro-LEDs (ML). Thus, an arrangement in which the same types of the micro-LEDs (ML) are arranged in the diagonal direction on the target substrate TS.

As described with reference to FIG. 12, in a case where the absorption regions 2000 are formed in such a manner that the micro-LEDs (ML) on the first substrate are transferred to the second substrate with the pitch distance therebetween on the second substrate being greater than the pitch distance on the first substrate, the pitch distance may be increased after an individualization process without a separate film expansion mean. The effect of increasing pitch distances between tens or tens of thousands of micro-LEDs (ML) in an equal manner can be achieved.

The pitch distance between the absorption regions 2000 is described above as being four times the first pitch distance a between the micro-LEDs (ML) on the donor substrate. However, the absorption region 2000 is not limited to this pitch distance. The pitch distance between the absorption regions 2000 may be four or more times the first pitch distance a. Accordingly, the pitch distance between the micro-LEDs (ML) to be transferred to the target substrate TS may be further increased and transferred. In addition, the pitch distance between the micro-LEDs (ML) transferred on the target substrate TS are illustrated as an equal distance. However, the pitch distance between the micro-LEDs (ML) mounted on the target substrate TS do not need to be equal. As one example, the micro-LEDs (ML) may be mounted in such a manner that the pitch distance between the micro-LEDs (ML) within a unit pixel is smaller than the pitch distance between the micro-LEDs (ML) adjacent to the unit pixel.

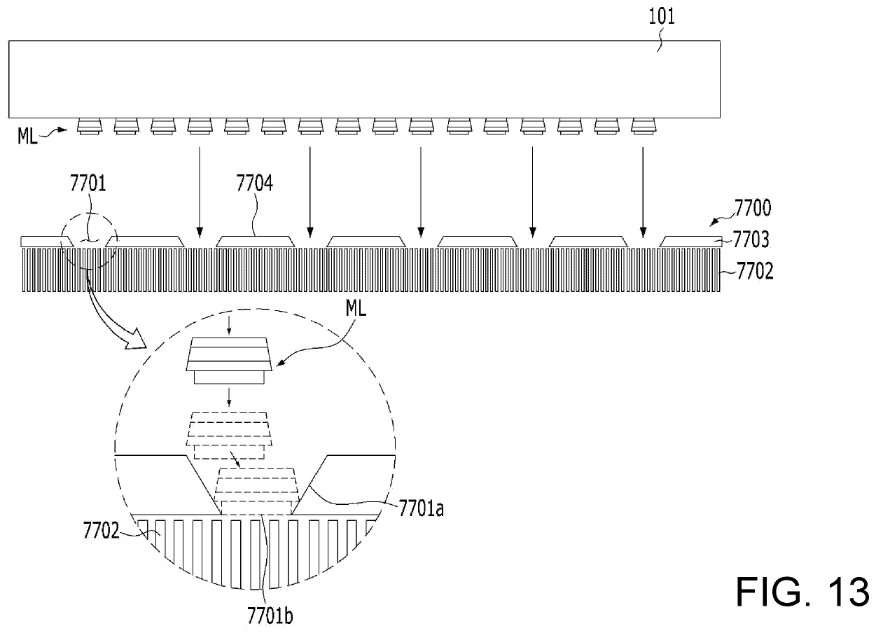

FIG. 13 is a view illustrating a state where the pitch distance between the micro-LED (ML) is corrected using a positional error correction carrier 7700.

Before the micro-LEDs (ML) separated from the first substrate 101 and the micro-LEDs (ML) absorbed to the transfer head are transferred to the second substrate (for example, the circuit substrate 301, a target substrate, or a display substrate), the pitch distance between the micro-LEDs (ML) may be adjusted, and an alignment position of the micro-LED (ML) may be corrected using a means of correcting the positional error of the micro-LED (ML). A bonding pad provided to the second substrate may function as the bond layer 8400. As one example, the positional error correction carrier 7700 may constitute a means of correcting the alignment position of the micro-LED (ML).

A method for manufacturing a micro-LED display is configured to include: a step of preparing a positional error correction carrier 7700 that includes a loading groove 7701 having a bottom surface 7701b and an oblique portion 7701a and accommodating a micro-LED (ML), and a non-loading surface 7704 provided in the vicinity of the loading groove 7701; a positional error correction step of transferring the micro-LED (ML) on a first substrate 101 to the positional error correction carrier 7700 and correcting a positional error of the micro-LED (ML); and a step of transferring the micro-LED (ML) in the positional error correction carrier 7700 to a second substrate 301. The pitch distance between the micro-LEDs (ML) may be corrected using the method for manufacturing a micro-LED display.

As illustrated in FIG. 13, the alignment position of the micro-LED (ML) may be corrected by the positional error correction carrier 7700. The positional error correction carrier 7700 may receive the micro-LED (ML) from the transfer head or the first substrate 101. In this case, the transfer head may be configured as the transfer head in the first embodiment to the ninth embodiment.

First, as one example, the reception of the micro-LED (ML) from the first substrate 101 by the positional error correction carrier 7700 and the correction of the pitch distance between the micro-LEDs (ML) thereby are described with reference to FIG. 13.

The step of preparing the positional error correction carrier 7700 in order to correct the pitch distance between the micro-LED (ML) using the positional error correction carrier 7700 may be performed. In the step of preparing the positional error correction carrier 7700, the positional error correction carrier 7700 is prepared that includes the loading groove 7701 including the bottom surface 7701b and the oblique portion 7701a and accommodating the micro-LED (ML), and the non-loading surface 7704 provided in the vicinity of the loading groove 7701.

Then, the positional error correction step may be performed. In the positional error correction step, the micro-LED (ML) on a first substrate 101 may be transferred to the positional error correction carrier 7700, and the positional error of the micro-LED (ML) may be corrected. Thus, when the micro-LED (ML) is transferred to the second substrate including the bonding pad, an error of alignment between the micro-LED (ML) and the bonding pad may be minimized.

If the accuracy of alignment of the micro-LED (ML) separated from the first substrate 101 and absorbed to the transfer head is low when transferring the micro-LED (ML) to the second substrate, although the transfer precision of the transfer head or the accuracy of alignment of the bonding pad on the second substrate is high, a transfer defect may occur. Therefore, before transferring the micro-LED (ML) to the second substrate, it is important to correct the alignment position of the micro-LED (ML). The positional error correction carrier 7700 may receive the micro-LED separated from the transfer head and may correct the positional error.

As illustrated in FIG. 13, the micro-LED (ML) may be accommodated in the loading groove 7701 including the oblique portion 7701a, and an alignment position may be corrected before the micro-LED (ML) is transferred to the second substrate.

The loading groove 7701 may include the bottom surface 7701b and the oblique portion 7701a. The loading groove 7701 accommodates the micro-LED (ML) received from the transfer head 1 or the first substrate 101.

The loading groove 7701 is formed in such a manner that a width of the bottom surface 7701b thereof is smaller than an entrance end of the oblique portion 7701a. The loading groove 7701 is formed in such a manner that the width of the bottom surface 7701b is smaller than an entrance end of the oblique portion 7701a and is the same as a width of the lower surface of the micro-LED (ML). Thus, the micro-LED (ML) is guided to the oblique portion 7701a and is seated on the bottom surface 7701b. Accordingly, a position of the micro-LED (ML) is corrected.

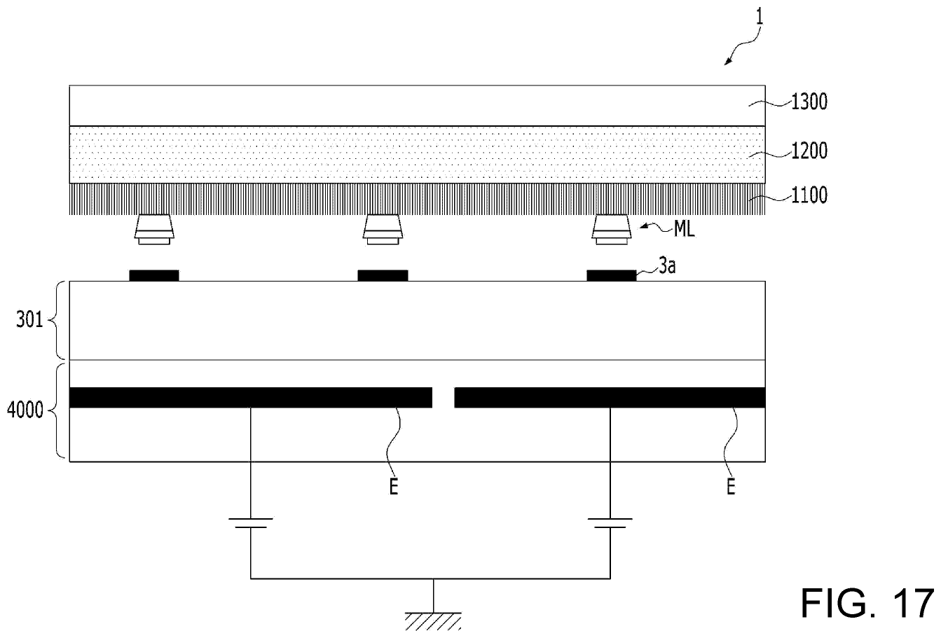

The oblique portion 7701a is formed in such a manner that a width thereof is greater than a width of the bottom surface 7701b and is inclined. Thus, the oblique portion 7701a serves to guide moving of the micro-LED (ML) detached from the first substrate 101 or the transfer head to the bottom surface 7701b. Specifically, the micro-LED (ML) may be guided to the bottom surface 7701b and may be seated thereon. FIG. 13 illustrates an enlarged portion of the loading groove 7701. With reference to FIG. 17, the detached micro-LED (ML) falls toward the bottom surface 7701b of the loading groove 7701. The micro-LED (ML) has the positional error before falling. A width of the oblique portion 7701a gradually decreases toward the bottom surface 7701b. Thus, when the micro-LED (ML) falls within a range of the width of the oblique portion 7701a, the positional error of the micro-LED (ML) with respect to the bottom surface 7701b is decreased, and thus is precisely seated on the bottom surface 7701b.

In a case where the width of the oblique portion 7701a is greater than the width of the bottom surface 7701b, when the micro-LED (ML) is accommodated in the loading groove 7701, a range where the positional error of the micro-LED (ML) with respect to the loading groove 7701 is allowed is increased. Specifically, the oblique portion 7701a extends upward from the bottom surface 7701b, and thus opening portion of the loading groove 7701 is formed. A width of the opening portion of the loading groove 7701 may be the largest of widths of the oblique portion 7701a. The micro-LED (ML) detached from the first substrate 101 or the transfer head may fall toward the loading groove 7701 from a height that corresponds to the width of the opening portion of the loading groove 7701. In this case, although the position alignment precision of the first substrate 101 or the transfer head with respect to the positional error correction carrier 7700 is relatively low, the micro-LED (ML) may be accommodated in the loading groove 7701. With this structure, a range where the positional error between the loading groove 7701 and the micro-LED (ML) is allowed may be increased.

The bottom surface 7701b on which the micro-LED (ML) is seated may absorb the micro-LED (ML) using an absorption force. The absorption force may be one of a vacuum suction force, an electrostatic force, a magnetic force, and a van der Waals force. According to the present invention, as one example, the micro-LED (ML) is absorbed to the bottom surface 7701b with the vacuum suction force.

In a case where the bottom surface 7701b absorbs the micro-LED (ML) with the vacuum suction force, a member generating an absorption force may be provided on a lower end portion of the oblique portion 7701a. Thus, the bottom surface 7701b may absorb the micro-LED (ML) with the vacuum suction force.

In a case where the bottom surface 7701b serves only to seat the micro-LED (ML), the micro-LED (ML) may be seated on the bottom surface 7701b through the oblique portion 7701a. In this case, the bottom surface 7701b may be formed by closing the lower end portion of the oblique portion 7701a without a separate member. Alternatively, a separate member that does not generate an absorption force may be used as the bottom surface 7701b.

As illustrated in FIG. 13, a member that can generate an absorption force may be provided on the lower end portion of the oblique portion 7701a. Thus, the oblique portion 7701a may be formed by closing the lower end portion of the bottom surface 7701b. A member constituting the bottom surface 7701b can generate the absorption force. Therefore, the bottom surface 7701b may absorb the micro-LED (ML) using the absorption force.

The positional error correction carrier 7700 includes the bottom surface 7701b and the oblique portion 7701a. Thus, the loading groove 7701 accommodating the micro-LED (ML) is provided, and the non-loading surface 7704 is provided in the vicinity of the loading groove 7701. The non-loading surface 7704 is configured as a horizontal surface, and may positionally correspond to the micro-LED (ML) not accommodated in the loading groove 7701.

A plurality of loading grooves 7701 in the positional error correction carrier 7700 are formed in such a manner as to be spaced apart, and the non-loading surface 7704 may be formed in the vicinity of the loading groove 7701. The loading grooves 7701 may be formed in such a manner to be spaced apart, considering the fact that red, green, and blue micro-LEDs (ML) that realize a pixel are transferred to the second substrate 301.

The positional error correction carrier 7700 may receive the micro-LED (ML) from the first substrate 101 and may correct the alignment position thereof. The loading groove 7701 may be formed in such a manner that a distance therebetween is three or more times the pitch distance in the x-direction between the micro-LEDs (ML) on the first substrate 101. Thus, the micro-LED (ML) of which the positional error is corrected may be transferred before each of the red, green, and blue micro-LEDs (ML) is transferred to the second substrate.

As one example, the positional error correction carrier 7700 corrects the positional error of the red micro-LED (ML). In this case, the positional error correction carrier 7700 receives the red micro-LED (ML) from the first substrate 101 or the transfer head. Among the red micro-LEDs (ML) on the first substrate 101 on which the red micro-LEDs (ML) are arranged, only the red micro-LED (ML) that corresponds to the loading groove 7701 may be accommodated in the loading groove 7701.

The red micro-LED (ML) accommodated in the loading groove 7701 in the positional error correction carrier 7700 may be absorbed by the transfer head that is a means of transporting the micro-LED (ML). As one example, the red micro-LEDs (ML) may be absorbed to the transfer head in a state where a separation distance therebetween is the same as a separation distance between the loading grooves 7701. The absorbed red micro-LEDs (ML) may be transferred to the second substrate, the red micro-LEDs (ML) may be transferred to the second substrate in a state where the separation distance therebetween is in advance set to be the same as the separation distance between the loading grooves 7701 to realize the pixel arrangement. The green and blue micro-LEDs (ML) and may be transferred in a state of being separated from each other by the separation distance between the red micro-LEDs (ML). As described above, the green micro-LEDs (ML) may be transferred to the second substrate in a state where the separation distance therebetween is the same as the separation distance between the loading grooves 7701. The blue micro-LEDs (ML) may also be transferred to the second substrate in a state where the separation distance therebetween is the same as the separation distance between the loading grooves 7701.

With the blue, green, and blue micro-LEDs (ML) that are transferred in this manner to the second substrate, a pixel arrangement is made on the second substrate. The blue, green, and blue micro-LEDs (ML) may be sequentially transferred to the second substrate in such a manner that a unit pixel in which each of the blue, green, and blue micro-LEDs is included is configured.

The positional error correction carrier 7700 may correct the positional error of the micro-LED (ML) received from the transfer head. As one example, the red micro-LED (ML) may be transferred to the positional error correction carrier 7700. The red micro-LED (ML) transferred from the transfer head may be accommodated in the loading groove 7701 with the absorption force of the bottom surface 7701b in the loading groove 7701. In this case, only the micro-LED (ML) corresponding to the loading groove 7701 may be transferred to the positional error correction carrier 7700.

The non-loading surface 7704 may be provided in the vicinity of the loading groove 7701. The loading grooves 7701 are spaced apart, and thus the non-loading surface 7704 is provided in the vicinity thereof. Accordingly, although the loading groove 7701 is formed in such a manner that a width of an entrance end thereof is small, interference between the loading grooves 7701 does not occur. In other words, although the width of the opening portion of the loading groove 7701 is increased, regions of the loading groove 7701 may be prevented from interfering with each other. Thus, the loading groove 7701 may be formed in such a manner that the width of the opening portion thereof is so great that the micro-LED (ML) is easily received.

As illustrated in FIG. 13, the positional error correction carrier 7700 may be configured to include a guide member 7703 and a closing support portion 7702. The guide member 7703 includes the oblique portion 7701a and the non-loading surface 7704. The closing support portion 7702 is combined with a bottom of the guide member 7703 in such a manner as to close the lower end portion of the oblique portion 7701a and to form the loading groove 7701.

The closing support portion 7702 is combined with the bottom of the guide member 7703 and the lower end of the oblique portion 7701a is closed. Thus, the bottom surface 7701b is formed on the lower end portion of the oblique portion 7701a, and the loading groove 7701 including the bottom surface 7701b and the oblique portion 7701a is formed.

Due to the oblique portion 7701a, the loading groove 7701 is formed in such a manner as to have a rectangular cross section and to have a great upper end width and a small lower end width.

The guide member 7703 may be formed of an elastic material. Thus, the guide member 7703 serves as a buffer when the micro-LED (ML) transferred from the transfer head or the first substrate 101 is brought into contact with the positional error correction carrier 7700.

Specifically, when the transfer head or the first substrate 101 descends toward the guide member 7703, the lower surface of the micro-LED (ML) and an upper surface of the non-loading surface 7704 of the guide member 7703 may be brought into contact with each other.

In a case where a means of transferring the micro-LED (ML) is the first substrate 101, a laser lift-off (LLO) process may be performed in order to transfer the micro-LED (ML) on the first substrate 101 to the positional error correction carrier 7700. The LLO process may be selectively performed on only the micro-LED (ML) at a position that corresponds to the loading groove 7701. When the LLO process is performed, a phenomenon where the micro-LED (ML) bounces may occur. In order to prevent the micro-LED (ML) from being accommodated in the loading groove 7701 due to this bouncing phenomenon, the first substrate 101 may further descend toward the positional error correction carrier 7700. At this time, the micro-LED (ML) at a position corresponding to the non-loading surface 7704 of the guide member 7703 is brought into close contact with to the non-loading surface 7704. Because the guide member 7703 is formed of an elastic material, the guide member 7703 serves as a buffer in order to prevent damage to the micro-LED (ML) that is brought into close contact with which the non-loading surface 7704. Thus, although the phenomenon where the micro-LED (ML) bounces occurs, the positional error of the micro-LED (ML) with respect to the loading groove 7701 may be efficiently corrected, and the micro-LED (ML) not accommodated in the loading groove 7701 may be prevented from being damaged.

the closing support portion 7702 combined with the bottom of the guide member 7703 may absorb the micro-LED (ML) using the absorption force. In this case, the absorption force that is used by the closing support portion 7702 may be at least one of a vacuum suction force, a van der Waals force, an electrostatic force and a magnetic force. The closing support portion 7702 is configured to form the loading groove 7701, and thus the bottom surface 7701b of the loading groove 7701 may absorb the micro-LED (ML) using the absorption force that is used by the closing support portion 7702. The closing support portion 7702 will be described below as using the vacuum suction force.

The closing support portion 7702 may be configured as the porous member 1000 that has arbitrary or vertical pores. The closing support portion 7702 may vacuum-absorb the micro-LED (ML) transferred by applying vacuum to the pore in the porous member 1000. The porous member 1000 may be configured to have the same configuration as the porous member 1000 described above.

In addition, as illustrated in FIG. 13, the closing support portion 7702 may be configured as the anodic oxide film 1600. In this case, the anodic oxide film 1600 has the same configuration as the anodic oxide film 1600 in the first embodiment.

A separate hole forming the vacuum suction force may be formed in the closing support portion 7702 by etching at least one portion thereof. Thus, the closing support portion 7702 may absorb the micro-LED (ML) with relatively great vacuum pressure.

The separate hole may be formed in the closing support portion 7702 in such a manner as to be positioned at a position for closing the bottom surface 7701b of the loading groove 7701. The separate hole may be formed in the closing support portion 7702 in a manner that passes therethrough from top to bottom. The separate hole may be formed in such a manner that a width thereof is smaller than a width of the bottom surface 7701b of the loading groove 7701 and is greater than a width of the lower surface of the micro-LED (ML). The forming of the separate hole in the closing support portion 7702 increases vacuum pressure. Thus, the micro-LED (ML) corresponding to the loading groove 7701 may be easily detached and may be absorbed to the loading groove 7701.

The micro-LED (ML) is accommodated in the loading groove 7701 in the positional error correction carrier 7700 and thus the positional error thereof is corrected. It is possible that the positional error thereof is preferably corrected before the micro-LED (ML) is transferred to the second substrate. Thus, the error of alignment between the second substrate and the bonding pad may be minimized.

The positional error correction carrier 7700 may correct the positional error of the micro-LED (ML) on the second substrate through a step of transferring the micro-LED (ML) in the positional error correction carrier 7700 to the second substrate. Thus, the positional error of the micro-LED (ML) may be corrected before the micro-LED (ML) on the second substrate (for example, the circuit substrate 301) is transferred to a micro-LED display wiring substrate that constitutes the micro-LED display.

6. Step of Inspecting and Repairing a Defective Micro-LED (ML)

Defect inspection may be performed on the micro-LED (ML) before transferring to the second substrate. A process of replacing a defective micro-LED found in the defect inspection with a quality micro-LED may be performed.

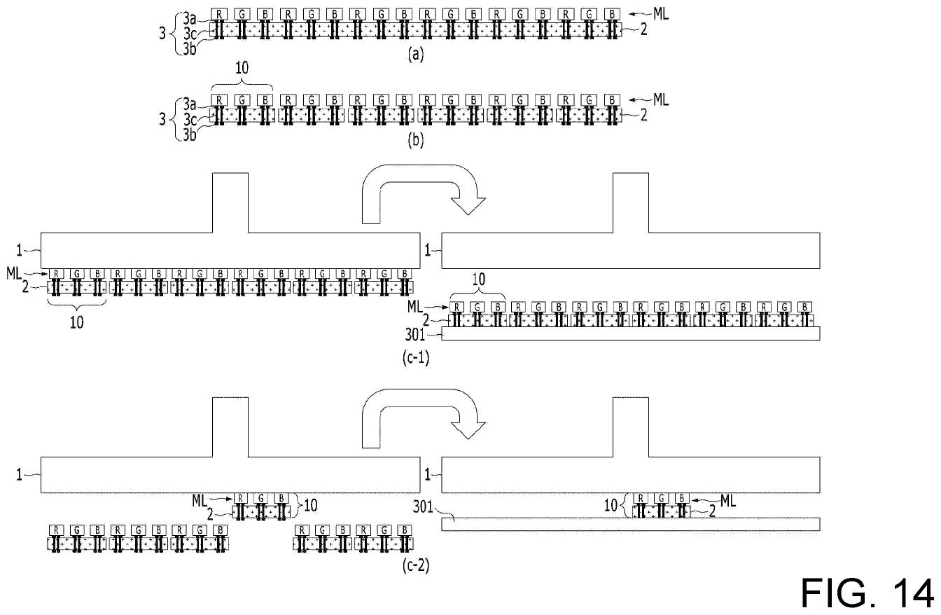

FIG. 14 is a view schematically illustrating the process of replacing the defective micro-LED with the quality micro-LED. In this case, the transfer head 1 absorbing the micro-LED (ML) may be the transfer head in the first embodiment to the ninth embodiment. As an example, a description is provided with reference to FIG. 14, using the same reference characters associated with the transfer head 1 in the first embodiment. The absorption force here with which the micro-LED (ML) is absorbed is at least one of a vacuum suction force, an electrostatic force, a magnetic force, or a van der Waals force. Alternatively, at least two of these forces may be used depending on a structure of the transfer head. In addition, the absorption forces of the transfer head may include a bonding force and the like that disappears by light, but are not limited to this bonding force.

The process of replacing the defective micro-LED with the quality micro-LED may be performed with the transfer head 1 transferring the micro-LED (ML) on the first substrate 101 to a relay wiring substrate 2 and the second substrate 301, a discrete module including the relay wiring substrate 2 and the micro-LED (ML), and a repair head replacing a defective discrete module with a quality discrete module.

In a method for manufacturing the micro-LED display according to the present invention, the process of replacing the defective micro-LED with the quality micro-LED may be performed. This process includes a step of transferring the micro-LED (ML) on the first substrate 101 to the relay wiring substrate 2 including a relay wiring unit 3, a step of cutting the relay wiring substrate 2 to which the micro-LED (ML) is transferred into a plurality of discrete modules 10, and a step of transferring a quality discrete module to the second substrate 301.

The second substrate 301 illustrated in FIG. 14 is configured to receive the micro-LED (ML) on the first substrate 101 from the transfer head 1, and a solder bump to which a contact pad 3b of the discrete module 10 may be provided on an upper surface of the second substrate 301. The second substrate 301 may be the circuit substrate 301 on which the micro-LED (ML) is finally mounted, or may be a target substrate or a display substrate. The second substrate 301 that is the circuit substrate 301 may include a circuit wiring unit (not illustrated) inside.

The relay wiring substrate 2 may include the relay wiring unit 3 that includes a wiring line 3c, the bonding pad 3a, and the contact pad 3b. The relay wiring unit 3 has the wiring line 3c inside. The bonding pad 3a is provided on an upper surface of the relay wiring unit 3. The contact pad 3b is provided on a lower surface of the relay wiring unit 3. The micro-LED (ML) that is transferred to the relay wiring substrate 2 may be provided as a flip type. The micro-LED (ML) transferred to the relay wiring substrate 2 may be bonded on the bonding pad 3a provided on an upper surface of the relay wiring substrate 2. The micro-LEDs (ML) that are transferred to the relay wiring substrate 2 and is bonded thereto is in a state where the micro-LEDs (ML) on the relay wiring substrate 2 are not yet cut into discrete modules 10 in such a manner as to include a minimum pixel unit and may be one structure.

The discrete module 10 may be configured to include the relay wiring substrate 2 and the micro-LED (ML). The discrete module may be formed by cutting the micro-LEDs (ML) on the relay wiring substrate 2 in such a manner as to include a minimum pixel unit. Therefore, the discrete module 10 may be configured to include a unitized relay wiring substrate 2 and a micro-LED (ML) in a minimum pixel unit. The discrete module 10 will be described in detail below with reference to FIG. 14(b).

The repair head may be configured in such a manner as to replace the defective discrete module, among the discrete modules 10, with the quality discrete module, and may absorb the defective discrete module and the quality discrete module for replacement. The absorption forces with which the repair head absorbs the defective discrete module and the quality discrete module may include a vacuum suction force, an electrostatic force, a magnetic force, a van der Waals force, and a bonding force that disappears by heat or light. However, the absorption forces are not limited to these forces.

With the configuration as described above, before transferred to the second substrate 301, the micro-LEDs (ML) on the first substrate 101 is transferred to the relay wiring substrate 2 and are formed into the discrete modules 10, and the defect inspection is performed to check whether or not the discrete module 10 is defective. Only the quality micro-LED (ML) may be transferred to the second substrate 301.

FIG. 14(a) is a view illustrating a step of transferring the micro-LED (ML) on the first substrate 101 to the relay wiring substrate 2 including the relay wiring unit 3. As illustrated in FIG. 14(a), the micro-LED (ML) may be transferred by the transfer head 1 in such a manner that first and second contact electrodes are brought into contact with the bonding pad 3a provided on the upper surface of the relay wiring substrate 2. The micro-LED (ML) may be bonded by the bonding pad 3a to the relay wiring substrate 2 and may be electrically connected to the relay wiring substrate 2. One structure that results from bonding the micro-LEDs (ML) to the relay wiring substrate 2 may be formed through a step of transferring the micro-LED (ML) on the first substrate 101 to the relay wiring substrate 2.

Subsequently to the step of transferring the micro-LED (ML) to the relay wiring substrate 2, a step (hereinafter referred to as a “molding-portion formation step) of molding an upper portion of the relay wiring substrate may be performed.

In a case where the molding-portion formation step is performed, a molding portion may be formed in such a manner as to cover the micro-LED (ML) on the relay wiring substrate 2. The molding portion may improve the flatness of the upper portion of the relay wiring substrate to which the micro-LED (ML) is transferred. Subsequently, the molding portion remains on the display and may function as a light diffusion layer. In addition, because the molding portion fixes the adjacent micro-LEDs (ML) to each other, the discrete module 10, when transferred, is in a fixed position thereof. Because the molding covers the upper surface of the micro-LED (ML), the transfer head 1 and the micro-LED (ML) are prevented from being brought into contact with each other. Thus, when transferring the discrete module 10, the micro-LED (ML) may be prevented from being damaged. The molding portion may scatter light emitted from the micro-LED (ML) and thus may increase photon extraction efficiency. In a case where the molding portion is formed on top of the relay wiring substrate 2 by performing a step of forming the molding portion, the structure may be configured to include the relay wiring substrate 2, the micro-LED (ML), and the molding portion. In addition, in a case where the structure is cut into the discrete modules 10, the discrete module 10 may be configured to include the relay wiring substrate 2, the micro-LED (ML) in the minimum pixel unit, and the molding portion.

Then, as illustrated in FIG. 14(b), a step of cutting the relay wiring substrate 2 into a plurality of discrete modules 10 may be performed. In the cutting step, the relay wiring substrate 2 to which the micro-LEDs (ML) are transferred may be cut into a plurality of discrete modules 10. The relay wiring substrate 2 may be cut using a normal wiring substrate cutting method.

The relay wiring substrate 2 that is to cut into the plurality of discrete modules 10 may be cut in such a manner as to include a minimum pixel unit of the micro-LED (ML) transferred to the relay wiring substrate 2. The micro-LEDs (ML) transferred to the relay wiring substrate 2 are arranged according to an arrangement of the absorption regions of the absorption member of the transfer head 1 transferring the micro-LED (ML) on the first substrate 101 to the relay wiring substrate 2.

Then, an inspection step of applying electricity to the relay wiring unit 3 of the relay wiring substrate 2 and inspecting the micro-LED (ML) may be performed. Through the inspection step, it may be checked whether or not the micro-LED (ML) is defective. The discrete module including the quality micro-LED (ML) may be specified among the plurality of discrete modules 10 formed in the step of cutting the relay wiring substrate.

In a case where the inspection step is performed subsequently to the step of cutting the relay wiring substrate 2 into the plurality of discrete modules 10, the micro-LEDs (ML) in the plurality of discrete modules 10 may be inspected in the inspection step. Specifically, by applying electricity to the plurality of discrete modules 10, it may be checked which discrete module 10 includes the defective micro-LED, among the micro-LEDs (ML) included in the discrete modules 10. Thus, the quality discrete module may be specified among the plurality of discrete modules 10.

The inspection step may be performed subsequently to the step of transferring the micro-LED (ML) on the first substrate 101 to the relay wiring substrate 2, or the defect inspection may be performed on the structure formed after performing the transfer step.

In a case where the inspection step is performed subsequently to the step of cutting the relay wiring substrate, the micro-LEDs (ML) in the plurality of discrete modules 10 are inspected in a state where the plurality of discrete modules 10 is formed, and the quality discrete module is specified. The micro-LEDs (ML) in the plurality of discrete modules 10 are inspected to check which discrete module includes the defective micro-LED among the plurality of discrete modules 10, and thus the quality discrete module may be specified.

Alternatively, in a case where the inspection step is performed subsequently to the step of transferring the micro-LED (ML) to the relay wiring substrate 2, the position of the defective micro-LED (ML) may be identified on the relay wiring substrate 2 before forming the plurality of discrete modules 10. Thus, before performing the step of cutting the relay wiring substrate 2, in the step of cutting the relay wiring substrate, it may be in advance specified which one of the plurality of discrete modules 10 is the quality discrete module, and then the step of cutting the relay wiring substrate may be performed.

By performing the inspection step in this manner, the quality discrete module that does not the defective micro-LED may be specified.

Then, the step of transferring the quality discrete module, among the discrete modules 10, to the second substrate 301 may be performed. In the step of transferring the quality discrete module to the second substrate 301, the quality discrete module may be transferred to the second substrate 301 using a method of simultaneously transferring a plurality of quality discrete modules or a method of individually transferring the plurality of quality discrete modules.

FIG. 14(c-1) is a view illustrating a state where the plurality of quality discrete modules is simultaneously transferred to the second substrate 301. As illustrated in FIG. 14(c-1), the transfer head 1 may simultaneously absorb the plurality of quality discrete modules and may transfer the plurality of quality discrete modules to the second substrate 301. Before the transfer head 1 simultaneously absorbs the plurality of quality discrete modules, a step of configuring the plurality of discrete modules to the plurality of quality discrete modules, respectively, may be performed.

In a case where, in the step of transferring the quality discrete module to the second substrate 301, the plurality of quality discrete modules needs to be simultaneously transferred to the second substrate 301, a step of replacing the defective discrete module with the quality discrete module may be performed by the repair head.

First, in the inspection step, the defective micro-LED (ML) is identified, a defective discrete module is specified. Then, the relay wiring substrate 2 is cut into the plurality of discrete modules 10, and the resulting defective discrete module 10 is absorbed by the repair head.

In the inspection step, the repair head receives a position of the specified defective discrete module from a control unit. Thus, the repair head may absorb only the defective discrete module among the plurality of discrete modules 10. In this case, the plurality of discrete modules that are not absorbed by the repair head may be the quality discrete modules.

The repair head may remove the defective discrete module from among the plurality of discrete modules 10 by absorbing and may transfer a spare quality discrete module in such a manner as to be positioned at a position at which the defective discrete module is positioned. The spare quality discrete module with which the defective discrete module is replaced may be absorbed or detached by the repair head itself that removes the defective discrete module by absorbing, or may be absorbed or detached by a separate spare repair head for absorbing the quality discrete module.

The repair head may transfer a spare quality discrete module in such a manner as to be positioned at a position from which the defective discrete module is removed.

As described above, before transferring the micro-LED (ML) on the first substrate 101 to the second substrate 301, the step of replacing the defective discrete module itself including the defective micro-LED with the quality discrete module may be performed, and thus the plurality of quality discrete modules may be simultaneously transferred to the second substrate 301. In this manner, the step of, on a discrete module basis, removing the defective discrete module itself including the defective micro-LED and transferring the quality discrete module in such a manner as to be positioned at the position from which the defective discrete module is removed ensures improved rapidity compared with a step of removing one fine-sized micro-LED for replacement.

As illustrated in FIG. 14(c-2), the transfer head 1 may individually transfer only the quality discrete module to the second substrate 301. The transfer head 1 may absorb one by one the quality discrete module to be transferred to the second substrate 301. The transfer head 1 may perform a step of receiving a position of a quality discrete module to be absorbed from the control unit and absorbing the quality discrete module. The transfer head 1 may transfer one absorbed quality discrete module to the second substrate 301. The quality discrete module that by the transfer head 1 is absorbed one by one and individually transferred to the second substrate 301 may be the quality discrete module that passes the defect inspection as a result of checking whether or not a discrete module is defective.

The repair step performed on the basis of a discrete module 10 brings about the effect of being able to improve UPH for producing the finished product. The micro-LED display manufactured through the steps above described may be configured to include the second substrate 301 and the discrete module 10. The second substrate 301 includes the circuit wiring unit. The discrete module includes the micro-LED (ML). The micro-LED (ML) is electrically connected to the circuit wiring unit at an upper surface of the second substrate 301 and is electrically connected to the relay wiring unit 3 at the upper portion of the relay wiring substrate 2 on which the relay wiring unit 3 is provided.

In this case, the discrete modules 10 are discontinuously arranged on the second substrate 301. As illustrated in FIG. 14, the discrete modules 10 may be arranged in the 1×3 pixel arrangement. This pixel arrangement may be a pixel arrangement that is made by arranging the red, green, and blue micro-LEDs in a one-dimensional array on the relay wiring substrate 2 and then cutting them in a minimum pixel unit.

The micro-LED display configured to include the discrete modules 10 may be realized to have a shape in which the pixel arrangement of the transformed micro-LEDs (ML) is the same as the pixel arrangement of the micro-LEDs (ML) in the discrete modules 10. In addition, the pitch distance in the pixel arrangement is set to be the same as an arrangement distance in the pixel arrangement in the discrete modules 10.

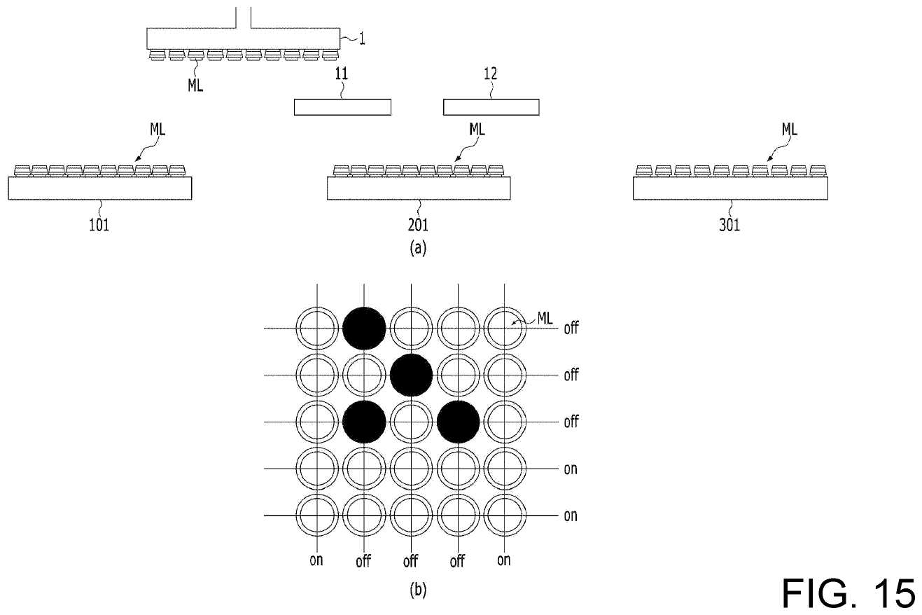

FIG. 15(a) is a view schematically illustrating a step of, through the use of an inspection apparatus 11, inspecting whether or the micro-LED (ML) is defective and replacing the defective micro-LED with the quality micro-LED.

The inspection apparatus 11 serves to inspect whether or not the micro-LED (ML) is defective.

The inspection apparatus 11 may move to over the first substrate 101, a temporary substrate 201, a second substrate 301, and the like. The inspection apparatus 11 may inspect whether or not the micro-LED (ML) on the first substrate 101, the micro-LED (ML) on the temporary substrate 201, and the micro-LED (ML) on the second substrate 301 are defective.

In addition, the inspection apparatus 11 may move to under the transfer head 1. Accordingly, the inspection apparatus 11 may inspect whether or not the micro-LED (ML) absorbed to the transfer head 1 is defective. In this case, the transfer head 1 may be configured as the transfer head in the first embodiment to the ninth embodiment. In addition, the transfer head 1 may use a vacuum suction force, an electrostatic force, a magnetic force, or a van der Waals force as an absorption force.

A repair apparatus 12 serves to attach (to absorb or mount) the quality micro-LED (ML) in such a manner as to be positioned at a position at which the defective micro-LED (ML) is positioned, on at least one of the temporary substrate 201, the transfer head 1, and the second substrate 301. The repair apparatus 12 may move to over the temporary substrate 201, under the transfer head 1, and over the second substrate 301. The repair apparatus 12 may descend toward an upper surface of the temporary substrate 201 and toward an upper surface of the second substrate 301 and may ascend toward a lower surface of the transfer head 1.

An absorption unit generating the absorption force may be provided in the repair apparatus 12. In this case, a vacuum suction force, an electrostatic force, a magnetic force, or a van der Waals force may be used as the absorption force of the absorption unit. As a specific example of the repair apparatus 12, the transfer head that uses one of the forces above described may be used.

With the absorption unit, the repair apparatus 12 may absorb the quality micro-LED (ML), receive coordinates of the defective micro-LED (ML) from the control unit, and may load the quality micro-LED (ML) in such a manner as to be positioned at a position that corresponds to the coordinates of a repair target.

As illustrated in FIG. 15(a), the inspection apparatus 11 may determine the defective micro-LED and the repair apparatus 12 may perform the step of repairing the defective micro-LED with the quality micro-LED.

First, an inspection step of inspecting whether or not the micro-LED (ML) on the first substrate 101 is defective. In this case, in the inspection step, it may be inspected whether or not the micro-LED (ML) on the first substrate 101 is defective or may be inspected whether or not the micro-LED (ML) on the temporary substrate 201 to which the micro-LED (ML) on the first substrate 101 is temporarily attached is defective. As one example, a step of inspecting whether or not the micro-LED (ML) on the temporary substrate 201 is defective will be described below.

In the inspection step, the inspection apparatus 11 may move to over the temporary substrate 201 and may inspect whether or not the micro-LED (ML) on the temporary substrate 201 is defective. As one example, the inspection apparatus 11 may check whether or not the micro-LED (ML) is electrified, using a probe tip or the like, and thus may determine whether or not the micro-LED (ML) is defective.

In a case where the inspection apparatus 11 detects the defective micro-LED (ML) present among the micro-LEDs (ML) temporarily attached to the temporarily substrate 201, the control unit connected to the inspection apparatus 11 may determine the coordinates of the defective micro-LED (ML).

In a case where, in the inspection step, the defective micro-LED (ML) is identified, a step of removing the defective micro-LED (ML) from the temporal substrate 201 may be performed. In a case where inspection of the micro-LED (ML) on the first substrate 101 is performed in the inspection step, in the removal step, the defective micro-LED (ML) identified in the inspection step is removed from the temporary substrate 201.

The control unit may transmit the coordinates of the defective micro-LED (ML) detected in the inspection step to the transfer head 1. The transfer head 1 may absorb only the defective micro-LED (ML) from the temporary substrate 201 using the coordinates. Thus, the defective micro-LED (ML) may be removed from the temporary substrate 201. As one example, a means of removing the defective micro-LED (ML) on the temporary substrate 201 in the removal step may be the transfer head described above and may be a separate apparatus only absorbing only the defective micro-LED (ML).

Then, the repair step may be performed. In the repair step, the repair apparatus 12 may perform a step of temporarily attaching the quality micro-LED (ML) in such a manner as to be positioned at a position from which the defective micro-LED (ML) on the temporary substrate 201 is removed. In this case, the repair apparatus 12 may be the transfer head that uses a vacuum suction force, an electrostatic force, a magnetic force, or a van der Waals force or may be an apparatus capable of absorbing or transferring the micro-LED.

The repair apparatus 12 may absorb the quality micro-LED (ML), may receive the coordinates of the defective micro-LED (ML) from the control unit and may load the quality micro-LED (ML) in such a manner as to be positioned at the position from which the defective micro-LED (ML) is removed.

Then, the transfer step may be performed. In the transfer step, a step in which the transfer head 1 transfers all the micro-LEDs (ML) temporarily attached on the temporary substrate 201 to the second substrate 301 may be performed.

In a case where, in the inspection step, the removal step, and the repair step, inspection, removal, and repair, respectively are performed with respect to the first substrate 101, the transfer head 1 may transfer the micro-LED (ML) on the first substrate 101 to the second substrate 301.

The transfer head 1 may absorb all the micro-LEDs (ML) on the temporary substrate 201 or the first substrate. In this case, all the micro-LEDs (ML) absorbed to the transfer head 1 are the quality micro-LEDs (ML) because the repair step is performed thereon.

In this manner, through the inspection step or the repair step, only the quality micro-LED (ML) may be arranged on the temporary substrate 201 or the first substrate 101. Since the transfer head 1 absorbs the micro-LED (ML) on the first substrate 101 or the temporary substrate 201 on which only the quality micro-LED (ML) is arranged and transfers the absorbed micro-LED (ML) to the second substrate 301, a defective pixel resulting from transferring the defective micro-LED (ML) to the second substrate 301 may be prevented from occurring in the display. In addition, a separate step of inspecting whether or not the defective micro-LED on the second substrate 301 is defective micro may be omitted. Thus, the efficiency of processing can be improved.

In a state where the transfer head 1 absorbs the micro-LED (ML) attached on the first substrate 101, the inspection step may be performed. To perform the inspection step, the inspection apparatus 11 may move to under the transfer head 1 or the transfer head 1 may move to over the inspection apparatus 11.

The transfer head 1 may perform a step of absorbing the micro-LED (ML) on the first substrate 101. Then, an inspection step of inspecting whether or not the micro-LED (ML) absorbed to the transfer head 1 is defective, a removal step of removing the defective micro-LED (ML) detected in the inspection step from the transfer head 1, a repair step in which the transfer head 1 absorbs the quality micro-LED (ML) in such a manner as to be positioned at the position on the transfer head 1 from which the defective micro-LED (ML) is removed, and a micro-LED (ML) transfer step in which the transfer head 1 transferring the absorbed micro-LED (ML) to the second substrate 301 may be sequentially performed.

In a case where the inspection apparatus 11 performs the inspection step of inspecting whether or not the defective micro-LED (ML) is present among the micro-LEDs (ML) absorbed to the transfer head 1, the control unit connected to the inspection apparatus 11 may determine the coordinates of the defective micro-LED.

Then, the removal step of removing the defective micro-LED detected in the inspection step from the transfer head 1 may be performed. The control unit may transmit the coordinates of the defective micro-LED to the transfer head 1, and the transfer head 1 may release the absorption force of the absorption region 2000 corresponding to the coordinates. Thus, the defective micro-LED may be detached. Thus, only the defective micro-LED (ML) may be removed from the transfer head 1.

In a state where the transfer head 1 absorbs the micro-LED (ML), in a case where the step of removing the defective micro-LED (ML) is performed, the absorption force of the absorption region 2000 to which the defective micro-LED (ML) is absorbed may be released, and thus the defective micro-LED (ML) may be detached. Furthermore, the defective micro-LED (ML) may be detached from the transfer head 1 using a separate removal apparatus that has an absorption force relatively greater than the absorption force of the transfer head 1. In this case, the removal apparatus may be positioned below the transfer head 1 and may release the absorption force of the absorption region 2000 of the transfer head 1.

Then, the repair step may be performed. In the repair step, the transfer head 1 may absorb the quality micro-LED (ML) in such a manner as to be positioned at the position the transfer head 1 from which the defective micro-LED (ML) is removed. This step may be performed by the repair apparatus. In this case, the transfer head 1 may move to over the repair apparatus 12 to which the quality micro-LED (ML) is adsorbed, or the repair apparatus absorbing the quality micro-LED (ML) may move to under the transfer head 1. As one example, in a case where the repair apparatus 12 moves to under the transfer head 1, in a state of being positioned under the transfer head 1, the repair apparatus 12 may release the absorption force on the quality micro-LED (ML) at a position that corresponds to the position from which the defective micro-LED is removed, on the basis of the coordinates of the defective micro-LED (ML) received from the control unit

Then, the absorption force is exerted on the absorption region 2000 of the transfer head 1 that is positioned at a position that corresponds to the position from the defective micro-LED is removed, and thus may absorb the quality micro-LED, the absorption force on which is released in the repair apparatus 12.

Alternatively, the absorption force of the repair apparatus 12 is set to be relatively smaller than the absorption force of the transfer head 1, so that repair may be easily performed only when the quality micro-LED on the repair apparatus 12 is positioned at a position that corresponds to a replacement position.

Then, the transfer step may be performed. In the transfer step, the transfer head 1 transfers the absorbed micro-LED (ML) to the second substrate 301. In this case, the transfer head 1 may transfer all the absorbed quality micro-LEDs (ML) to the second substrate 301.

As described above, in the state where the transfer head 1 absorbs the micro-LED (ML), in the case where the inspection step is performed, it is possible that the transfer head 1 desorbs the defective micro-LED for removal. Therefore, it is possible that the removal step is rapidly performed. Thus, the efficiency of the micro-LED transfer and repair processing can be increased.

In the state where the transfer head 1 absorbs the micro-LED (ML), subsequently to the inspection step of inspecting the defective micro-LED (ML) is performed, the micro-LED (ML) may be transferred to the second substrate 301 immediately after the step of removing the defective micro-LED (ML), and then, the repair step may be performed.

Specifically, a step in which the transfer head 1 absorbs the micro-LED (ML) on the first substrate 101, an inspection step of inspecting whether or not the micro-LED (ML) absorbed to the transfer head 1 is defective, a removal step of removing the defective micro-LED detected in the inspection step from the transfer head 1, a micro-LED transfer step in which the transfer head 1 transfers the absorbed micro-LED (ML) to the second substrate 301, and a repair step of attaching the quality micro-LED (ML) in such a manner as to be positioned at the position from which the defective micro-LED (ML) is removed in the second substrate 301 may be sequentially performed. In other words, the transfer head 1 performs the inspection and removal of the defective micro-LED, and the step of loading the quality micro-LED in such a manner as to be positioned at the position from which the defective micro-LED is removed may be performed with respect to the second substrate 301.

After the inspection step of inspecting whether or not the micro-LED (ML) absorbed to the transfer head 1 is defective is performed, the removal step of removing the defective micro-LED detected in the inspection step from the transfer head 1 may be performed.

Then, the transfer step may be performed. In the transfer step, the transfer head 1 may transfer the absorbed micro-LED (ML) to the second substrate 301. In this case, since the defective micro-LED is removed from the transfer head 1, an occupied region is not present at the position from which the defective micro-LED.

Then, the repair step may be performed. In the repair step, the repair apparatus 12 attaches the quality micro-LED (ML) in such a manner as to be positioned at the position from which the defective micro-LED (ML) on the second substrate 301 is removed. The repair apparatus 12 may receive the coordinates of the defective micro-LED (ML) from the control unit. In this case, the coordinates of the defective micro-LED (ML) may be coordinates of the defective micro-LED detected by the inspection apparatus 11 that is present among the micro-LEDs (ML) absorbed to the transfer head 1. These coordinates may correspond to coordinates of the second substrate 301. Using the received coordinates, the repair apparatus 12 may attach the quality micro-LED (ML) in such a manner as to be positioned at the position from which the defective micro-LED (ML) is removed. Thus, the quality micro-LED (ML) may be attached in such a manner as to be positioned at the position on the second substrate 301 that corresponds to the unoccupied region of the transfer head 1. As a result, only the quality micro-LED (ML) is present on the second substrate 301.

Subsequently to the inspection step of inspecting whether or not the micro-LED (ML) absorbed to the transfer head 1 is detective, the micro-LED (ML) absorbed to the transfer head 1 may be immediately transferred to the second substrate 301, and the removal step of removing the defective micro-LED (ML) from the second substrate 301 and the repair step of replacing the defective micro-LED (ML) with the quality micro-LED (ML) may be performed.

Specifically, an absorption step in which the transfer head 1 absorbs the micro-LED (ML) on the first substrate 101, an inspection step of inspecting whether or not the micro-LED (ML) absorbed to the transfer head 1 is defective, a step of transferring the micro-LED (ML) absorbed to the transfer head 1 to the second substrate 301, a removal step of removing the defective micro-LED detected in the inspection step from the second substrate 301, and a repair step of attaching the quality micro-LED (ML) in such a manner as to be positioned at the position from which the defective micro-LED is removed in the second substrate 301 may be sequentially performed. Thus, only the quality micro-LCD (ML) may be present on the second substrate 301.

In this manner, the inspection step of detecting the defective micro-LED and the repair step of removing the defective micro-LED and replacing the defective micro-LED with the quality micro-LED may be performed in various ways, and thus the defective micro-LED may be prevented from occurring on the second substrate 301.

FIG. 15(b) is a view illustrating a result of performing inspection using a method of determining the coordinates of the position of the defective micro-LED through row-based inspection and column-based inspection.

The step of inspecting the micro-LED (ML) may be performed. In the inspection step, the micro-LEDs (ML) in the first to m-th rows that are arranged in a matrix form are sequentially inspected, and the micro-LEDs (ML) in the first to m-th columns are sequentially inspected. Thus, the coordinates of the position of the defective micro-LCD (ML) may be identified through the row-based inspection and the column-based inspection. In this case, m and n are integers that are greater than 2.

The method of identifying the position of the defective micro-LED (ML) through the row-based inspection and the column-based inspection may be used without any restriction in a case where the micro-LEDs (ML) are arranged in m rows and n columns. For example, when the micro-LEDs (ML) are arranged in m rows and in n columns, inspection may be performed on the micro-LEDs (ML) on the first substrate, the micro-LEDs (ML) mounted on the second substrate, or the micro-LEDs (ML).

The inspection of the micro-LEDs (ML) may be performed by an inspection apparatus configured as a line inspection apparatus that inspects, row by row and column by column, micro-LEDs (ML) are arranged in m rows and in n columns.

The inspection apparatus may have a configuration that varies according to respective positions of the first and second contact electrodes on the micro-LED (ML).

As one example, in a case where the micro-LEDs (ML), as illustrated in FIG. 1, is of a vertical type in which the first contact electrode 106 is formed underneath the micro-LED and the second contact electrode 107 is formed on top thereof, the inspection apparatus inspecting whether or not the micro-LED is defective may be configured to include a lower substrate is positioned under the micro-LED (ML) and an upper substrate is positioned over the micro-LED (ML).

A first electrode in contact with a lower surface of the first contact electrode 106 on the adjacent micro-LED (ML) may be provided on an upper surface of the lower substrate. The first electrode is brought into contact with the first contact electrode 106 on the adjacent micro-LED (ML). When electric power is applied to the inspection apparatus, the first electrode may serve to pass an electric current through the first contact electrodes on the adjacent micro-LEDs (ML).

The second electrode in contact with an upper surface of the second contact electrode 107 on the adjacent micro-LED (ML) may be provided on a lower surface of the upper substrate. The second electrode is brought into contact with the second contact electrode 107 on the adjacent micro-LED (ML). When electric power is applied to the inspection apparatus, the second electrode may serve to pass an electric current through the second contact electrodes on the adjacent micro-LEDs (ML).

The first electrode and the second electrode may be arranged over and under the micro-LED (ML) in a manner that intersects, with the micro-LED (ML) in between.

The inspection apparatus with the above-described, when electric power is applied thereto, may inspect whether or not the micro-LED (ML) is defective.

As one example, the inspection apparatus may inspect whether or not the micro-LED (ML) underneath which the first contact electrode is provided and on top of which the second contact electrode is provided is defective. In this case, the micro-LED (ML) that is an inspection target may be transferred by the transfer head to the lower substrate of the inspection apparatus in such a manner that the first electrode on the lower substrate of the inspection apparatus 11 and the first contact electrode 106 of the micro-LED (ML) are brought into contact with each other.

Specifically, the micro-LED (ML) that is an inspection target may be arranged by the transfer head on the lower substrate of the inspection apparatus. The inspection apparatus may inspect whether or not the micro-LED (ML) in a state of being absorbed to the transfer head is defective. In this case, the transfer head that is to absorb the micro-LED (ML) is configured to include an electrode layer and thus may absorb the micro-LED (ML). The transfer head may be turned upside down and thus may function as a lower substrate. As one example, the micro-LED (ML) is described below as being transferred by the transfer head to the lower surface of the inspection apparatus in order to inspect whether or not the micro-LED (ML) is defective.

The micro-LED (ML) may be arranged in m rows and in n columns on the lower substrate of the inspection apparatus in such a manner that the first contact electrode 106 on the micro-LED (ML) is brought into contact with the first electrode adjacent to the lower substrate of the inspection apparatus.

Then, the inspection apparatus may descend and may come into contact with the second contact electrode 107 on the micro-LED (ML) to which the second electrode is adjacent. In this manner, the first and second contact electrodes 106 and 107 on the micro-LED (ML) are brought into contact with the first and second electrodes of the inspection apparatus, respectively, and the micro-LED (ML) is interposed between the upper substrate and the lower substrate of the inspection apparatus. In this state, one terminal of the inspection apparatus may apply electric power.

In a case where all the micro-LEDs (ML) interposed between the upper and lower substrates of the inspection apparatus are quality micro-LEDs (ML), the second electrode, the second contact electrode 107, the first electrode, and the first electrode 106 may be repeatedly electrified in the above-described order. In addition, the other terminal of the inspection apparatus is also electrified, and thus all the micro-LEDs (ML) interposed between the upper and lower substrates of the inspection apparatus are checked as the quality micro-LEDs (ML).

In a case where at least one of the micro-LEDs (ML) interposed between the upper and lower substrates of the inspection apparatus is the defective micro-LED, an electric current does not pass therethrough. Therefore, an electric current does not pass through the other terminal of the inspection apparatus. Thus, it may be determined that the defective micro-LED is present in one column or in one row, among the micro-LEDs (ML) arranged on the lower substrate.

The micro-LED (ML) may be of a flip type or of a lateral type in which the first and second contact electrodes are all formed on top of, underneath, or on top of and underneath the micro-LED (ML). As one example, the first and second contact electrodes 106 and 107 may be formed over the micro-LED (ML). In this case, the inspection apparatus may be configured to include the upper substrate that is brought into contact with the first and second contact electrodes 106 and 107 formed on top of the micro-LED (ML), Specifically, an upper electrode may be provided on the lower surface of the upper substrate, and the upper electrode of the upper substrate may be brought into contact with the first and second contact electrodes 106 and 107.

Lower surfaces of opposite end portions of the upper electrode may be brought into contact with at least one portion of the first contact electrode 106 and at least one portion of the second contact electrode 107, respectively, on the micro-LED (ML). In other words, the upper electrode may be brought into contact with at least one portion of the first contact electrode 106 and at least one portion of the second contact electrode 107, respectively, on the micro-LED (ML) that are adjacent to opposite ends of the upper electrode. Thus, the first and second electrodes 106 and 107 on the micro-LED (ML) are brought into contact of the upper electrode.

In this case, a distance between the upper electrodes may be greater than, or the same as a distance between inner lateral surfaces of the first and second contact electrodes formed on top of the micro-LED (ML). it is preferable that the distance between the upper electrodes is smaller than, or the same as a distance between outer lateral surfaces of the first and second contact electrodes 106 and 107.

A plurality of upper electrode may be formed in such a manner as to be spaced apart in the low/column direction. Lower surfaces of opposite end portions of the unit upper electrode may be brought into contact with at least one portion of the first contact electrode 106 and at least one portion of the second contact electrode 107, respectively, on the micro-LED (ML). When electric power is applied to the inspection apparatus, the upper electrode may pass an electric current pass the first and second electrodes 106 and 107 on the adjacent micro-LED (ML).

The inspection apparatus configured to include the upper substrate including the upper electrode in order to inspect whether or not the micro-LED (ML) including the first and the second contact electrodes 106 and 107 on top of the micro-LED (ML) is defective may inspect whether or not the micro-LED (ML) is defective, by performing the following processing.

The micro-LEDs (ML) may be arranged in m rows and in n columns on a substrate. The substrate may be the first or second substrate. Alternatively, the substrate may be the transfer head including an electrode layer. In a case where the substrate is the transfer head, in a state where the transfer head absorbs the micro-LED (ML), the inspection apparatus may inspect whether or not the micro-LED (ML) is defective.

The inspection apparatus may descend toward the micro-LED (ML) arranged on the substrate and may bring the upper electrode into contact with the first and second contact electrodes 106 and 107 on the adjacent micro-LED (ML). At least one portion of the first contact electrode 106 and at least one portion the second contact electrode 107 may be brought into contact with opposite ends, respectively, of the upper electrode.

In a state where the micro-LED (ML) is interposed between the substrate and the upper substrate of the inspection apparatus, electric power may be applied to one terminal of the inspection apparatus. In a case where all the micro-LEDs (ML) are the quality micro-LEDs (ML), the upper electrode, the first contact electrode 106, the second contact, and the second contact electrode 107 are repeatedly electrified in this order. In addition, the other terminal of the inspection apparatus is also electrified, and thus all the micro-LEDs (ML) are checked as the quality micro-LEDs (ML).

In a case where at least one of the micro-LEDs (ML) interposed between the upper and lower substrates of the inspection apparatus is the defective micro-LED, an electric current does not pass therethrough. Thus, an electric current does not pass through the other terminal of the inspection apparatus. Accordingly, the inspection apparatus determines that the defective micro-LED (ML) is present in at least one row or in at least one row.

A method of determining the coordinates of the position of the defective micro-LED through the row-based inspection and the column-based inspection using the above-described configuration will be described in detail below with reference to FIG. 15(b).

As illustrated in FIG. 15(b), as one example, the micro-LED (ML) including the first and second electrodes 106 and 107 constituting its lower end portion, respectively, are formed may be arranged in the first to fifth rows and in the first to fifth columns. The micro-LEDs (ML) in this arrangement may be attached or mounted on the substrate for arrangement. Alternatively, the micro-LEDs (ML) in this arrangement may be absorbed to the transfer head.

The inspection apparatus may sequentially inspect the micro-LEDs (ML) in the first to fifth rows and sequentially inspect the micro-LEDs (ML) in the first to fifth columns. The inspection apparatus, as the line inspection apparatus with the above-described configuration, may inspect whether or not the micro-LED (ML) is defective on a per-row basis or on a per-column basis.

In a case where the result of the inspection by the inspection apparatus is that only the quality micro-LEDs (ML) are present in each row and in each column, the inspection apparatus may transmit an “on” inspection signal to the control unit. In other words, in a case where an inspection signal transmitted, as a result of the inspection on a per-row or -column basis, to the control unit by the inspection apparatus is the “on” inspection signal, the control unit may recognize that only the quality micro-LEDs (ML) are present in each of row or each column.

In contrast, in a case where an inspection signal transmitted to the control unit by the inspection apparatus is an “off” inspection signal, the control unit may recognize that at least one defective micro-LED is present in each row or in each column.

As illustrated in FIG. 15(b), with the “off” inspection signal, the control unit may recognize that the defective micro-LED is present at coordinates (1, 2), (2, 3), (3, 2), and (3, 4) (in this case, the coordinates are expressed as (m, n) (m denotes a row, and n denotes a column). Specifically, although electric power is applied to one terminal of the inspection apparatus, in the first to third rows, an electric current does not pass through the other terminal of the inspection apparatus Therefore, the inspection apparatus may recognize that the defective micro-LED is present in at least one of the first to third rows and may transmit the “off” inspection signal to the control unit.

In the fourth and fifth rows, when electric power is applied to one terminal of the inspection apparatus, an electric current passes through the other terminal of the inspection apparatus. Thus, the inspection apparatus may recognize that only the quality micro-LEDs (ML) are present in the fourth and fifth rows. The inspection apparatus that recognizes the defective micro-LED is present may transmit the “on” inspection signal with respect to the fourth and fifth rows to the control unit.

Although in the second to fourth columns, electric power is applied to one terminal of the inspection apparatus, in the first to third rows, an electric current does not pass through the other terminal of the inspection apparatus. Thus, the inspection apparatus may recognize that at least one defective micro-LED is present in the second to fourth columns and may transmit the “off” inspection signal to the control unit.

In the first and fifth columns, when electric power is applied to one terminal of the inspection apparatus, an electric current passes through the other terminal of the inspection apparatus. Thus, the inspection apparatus may recognize that only the quality micro-LEDs (ML) are present in the first and fifth columns and may transmit the inspection signal.

In this manner, when the inspection signals with respect to the first to fifth rows and the first to fifth columns are transmitted by the inspection apparatus to the control unit, the control unit may recognize the coordinates of the position of the defective micro-LED (ML) on the basis of the received inspection signals. The control unit may transmit the coordinates of the position of the defective micro-LED (ML) to a defective micro-LED removal apparatus and the repair apparatus, and may cause the process of replacing the defective micro-LED with the quality micro-LED to be performed.

In a case where the defective micro-LED is detected using a method of determining the defective micro-LED through the row-based inspection and the column-based inspection, it is possible that the inspection is performed less frequently and is simplified. In addition, an individual inspection apparatus may be additionally provided, and the individual inspection apparatus may precisely determine only the coordinates of the position of the defective micro-LED (ML) that is determined by the line inspection apparatus. Thus, the quality micro-LED (ML) and the defective micro-LED (ML) may be divided and determined in a more precise manner. However, it is preferable that high precision re-inspection for determination of the position of the defective micro-LED (ML) is performed on the micro-LED (ML) to be used for an extra-large display. Because a large number of micro-LEDs (ML) are used for the extra-large display, when a yield of 99.9% is projected, there is a likelihood that a large number of the quality micro-LED (ML) will be determined and discarded as the defective micro-LED (ML).

7. Step of Bonding the Micro-LED (ML) to the Second Substrate

The micro-LED (ML) on the first substrate (for example, the growth substrate 101, a temporary substrate, or a carrier substrate) may be absorbed to the transfer head 1, and then, after going through the detaching process, may be transferred to the second substrate (for example, the circuit substrate 301, a target substrate, or a display substrate) The micro-LED (ML) may be transferred to the second substrate and may be bonded.

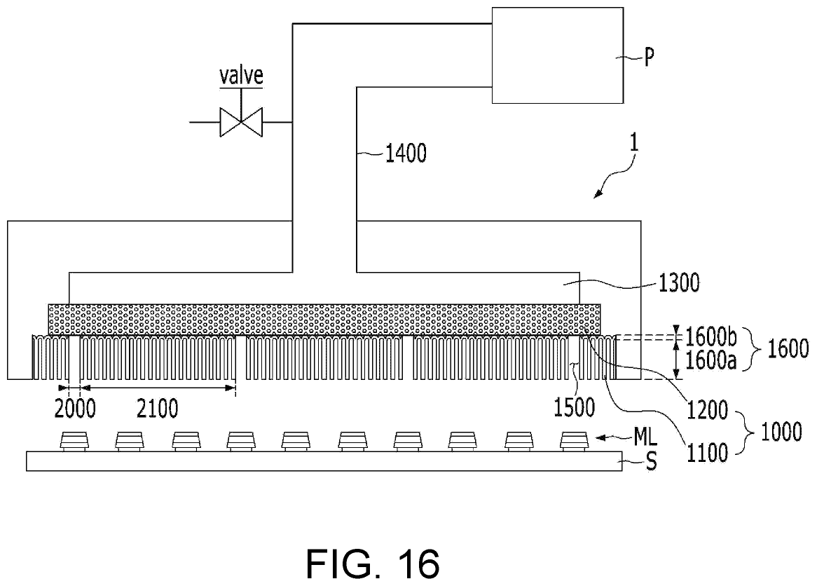

FIGS. 16 and 17 are views each illustrating an implementation example where the micro-LED (ML) is detached from the transfer head and is transferred to the second substrate.

As a method of detaching the micro-LED (ML) from the transfer head, a method of releasing vacuum by valve opening and a method of using an electrostatic chuck may be employed. The absorption forces of the transfer head, configured to transport the micro-LED (ML), may include a vacuum suction force, an electrostatic force, a magnetic force, a van der Waals force, and a bonding force that disappears by heat or light. However, the absorption forces are not limited to these forces.

However, the vacuum suction force will be described below as being used as the absorption force with which the micro-LED (ML) is absorbed in a preferred embodiment of the transfer head. Accordingly, the transfer head 1 in the first embodiment is illustrated and described for illustrative purposes. A description of the same constituent element is omitted.

FIG. 16 is a view illustrating an implementation example where the absorption force with which the micro-LED (ML) is absorbed is released by valve opening and where the micro-LED (ML) is thus detached from the transfer head 1.

As illustrated in FIG. 16, the micro-LED (ML) may be arranged on the substrate S. In a case where the transfer head 1 does not yet absorb the micro-LED (ML), the substrate S may be the first substrate (for example, the growth substrate 101, a temporary substrate, or a carrier substrate). In a case where the transfer head 1 already absorbs the micro-LED (ML), the substrate S may be the second substrate (for example, the circuit substrate 301, a target substrate, or a display substrate). FIG. 16 illustrates a state where the transfer head 1 already transfers the micro-LED (ML). The substrate S is assumed to be the second substrate.

As illustrated in FIG. 16, the transfer head 1 may include an openable valve. The openable valve may be a type of valve that is connectable to the suction pipe 1400 of the transfer head 1. The openable value, if capable of being provided on one side of the suction pipe 1400, enabling the suction pipe 1400 to communicate with a transfer space, and blocking flow from the suction pipe 1400 to the transfer space, is not limited in structure. The suction pipe 1400 is not limited to one structure of the suction pipe 1400 as illustrated in FIG. 16 and may be configured to employ a multi-suction structure in such a manner as to generate a uniform absorption force to be exerted on the micro-LED (ML).

The value may be mounted in a structure that is such a manner to be openable. When the transfer head 1 absorbs the micro-LED (ML), a vacuum pump P is caused to operate in a state where the valve is closed. Thus, the micro-LED (ML) may be absorbed with the vacuum suction force. When the micro-LED (ML) is detached from the transfer head 1, the valve is open, and thus the vacuum suction force is released. Thus, the micro-LED (ML) absorbed to the transfer head 1 may be detached therefrom.

When opening the valve, vacuum pressure applied to the transfer head 1 is the same as pressure of the transfer space in the micro-LED (ML). Specifically, the vacuum pressure exerted on the upper surface of the micro-LED (ML) is the same as the vacuum pressure of the transfer space. In this manner, in a case where the valve is open, the vacuum pressure inside the transfer head 1 that is generated by the vacuum pump P is the same as the pressure of the transfer space. Thus, the transfer head 1 desorbs the micro-LED (ML) for transferring to the second substrate.

A process for bonding to the second substrate may be performed on the micro-LED (ML) transferred to the second substrate. The bond layer for bonding the micro-LED (ML) is provided on the second substrate. The micro-LED (ML) may be bonded to the second substrate by applying heat or pressure to the bond layer on the second substrate.

The bond layer may be formed of an electrically conductive adhesive material containing conductive particles. For example, the bond layer may be formed of anisotropic conductive film or an anisotropic conductive adhesive. The bond layer may be formed of a material, such as thermoplastic or thermosetting polymer. The bond layer may be formed of a material selected from among materials used for bonding the micro-LED (ML) using a eutectic alloy bonding method that requires heating to a specific temperature for bonding, a transitional liquid bonding method, or a solid-phase diffusion bonding method.

In a case where the second substrate is the circuit substrate 301 illustrated in FIG. 2, the first electrode that is electrically connected to the first contact electrode 106 on the micro-LED (ML) is formed on the second substrate. The bond layer is provided on top of the first electrode. The bond layer serves not only to electrically connect the first contact electrode 106 on the micro-LED (ML) and the first electrode to each other, but also to fix the micro-LED (ML) to the second substrate.

There are two methods in which the transfer head 1 transfers the micro-LED (ML) to the second substrate are largely divided into the following two types. In the first method, in a state where the lower surface of the transfer head 1 is spaced away from the upper surface of the micro-LED (ML), the micro-LED (ML) absorbed to the transfer head 1 is desorbed for transferring the second substrate. In the second method, in a state where the lower surface of the absorption member 1100 is brought into contact with the upper surface of the micro-LED (ML), the micro-LED (ML) absorbed to the transfer head 1 is desorbed for transferring the second substrate.

In a case where air is discharged through the absorption surface of the absorption member 1100 by operating the vacuum pump P in the reverse direction in order for the transfer head 1 to desorb the micro-LED (ML) (or by mounting two vacuum pumps and switching between the two vacuum pumps), the micro-LED (ML) flows. At this time, there is a likelihood that a positional error will occur. In addition, when air is discharged through the absorption surface of the absorption member 1100, a foreign material or a particle stuck to the absorption surface is detached and then is stuck to the bond layer on the second substrate. Thus, the efficiency of bonding between the micro-LED (ML) and the bond layer may be decreased.

In this manner, when air is discharged through the absorption surface of the absorption member 1100 by operating the vacuum pump P in the reverse direction (or by mounting two vacuum pumps and switching between the two vacuum pumps), it is easy to desorb the micro-LED (ML). However, the precision of a transfer position of the micro-LED (ML) and the transfer efficiency are decreased.

Therefore, when the transfer head 1 transfers the micro-LED (ML) to the second substrate, the valve is open in a state where the vacuum pump P is not in operation. Thus, the vacuum pressure exerted on the upper surface of the micro-LED (ML) is the same as the vacuum pressure of the transfer space. Then, preferably, the micro-LED (ML) is transferred to the second substrate.

In a case where the bond layer is heated to a specific temperature of 200 C.° or higher for bonding, the micro-LED (ML) is brought into contact with the bonding layer and is bonded thereto in a state where the bond layer is heated to the specific temperature. In this case, when the bonding force between the micro-LED (ML) and the bond layer is greater than the absorption force between the transfer head 1 and the micro-LED (ML), the micro-LED (ML) is transferred to the second substrate. Therefore, the transfer head 1 cannot ascend from the second substrate until before a sufficient bonding force is exerted between the micro-LED (ML) and the bond layer. In this manner, the micro-LED (ML) needs to be bonded to the bond layer in a state where the bond layer is heated to the specific temperature. However, temperature of the air discharged through the absorption surface of the transfer head 1 is temperature (room temperature) that is lower than a bonding temperature. Thus, due to the discharge at a low temperature, it takes a longer time for the absorption layer to reach the specific temperature. As a result, a per-hour transfer speed of the transfer head 1 is decreased.

As described above, when air is discharged through the absorption surface of the absorption member 1100 by operating the vacuum pump P, the micro-LED (ML) is absorbed more easily. However, due to the air discharge through the absorption surface, the precision of the transfer position of the micro-LED (ML) and the efficiency of bonding are decreased.

Therefore, when the transfer head 1 transfers the micro-LED (ML) to the second substrate, the valve is open in the state where the vacuum pump P is not in operation. Thus, the vacuum pressure exerted on the upper surface of the micro-LED (ML) is the same as the vacuum pressure of the transfer space. Then, preferably, the micro-LED (ML) is transferred to the second substrate.

FIG. 17 is a view illustrating an implementation example where the micro-LED (ML) is desorbed from the transfer head using the electrostatic chuck. In this case, the absorption forces which the transfer head absorbs the micro-LED (ML) may include a vacuum suction force, an electrostatic force, a magnetic force, a van der Waals force, and a bonding force that disappears by heat or light and are limited to one of these forces. However, the vacuum suction force will be described below as being used as the absorption force with which the micro-LED (ML) is absorbed in a preferred embodiment of the transfer head. Accordingly, the transfer head 1 in the first embodiment is schematically illustrated and a description is provided, using the same reference characters associated with the transfer head 1 in the first embodiment.

As illustrated in FIG. 17, the transfer head 1 absorbing the micro-LED (ML) on the first substrate (for example, the growth substrate 101, a temporary substrate) transfers the absorbed micro-LED (ML) to the second substrate (for example, the circuit substrate 301, a target substrate, or a display substrate).

the bonding pad 3a is provided on the upper surface of the second substrate 301. The bonding pad 3a serves as the adhesion layer in such a manner that the micro-LED (ML) is bonded to the second substrate 301 for being fixed thereto. The transfer head 1 transfers the micro-LED (ML) to the bonding pad 3a and serves to fix the transferred micro-LED (ML) to the second substrate 301. The bonding pad 3a may be formed to an island-like shape at a position corresponding to the micro-LED (ML). Alternatively, the bonding pad 3a may be formed on the entire upper surface of the second substrate 301.

The bonding pad 3a may be formed of a metal layer. In a case where the bonding pad 3a is formed of a metal layer, the bonding pad 3a may be electrically connected to the contact electrode underneath the micro-LED (ML). In this case, the bonding pad 3a serves to perform eutectic bonding of the micro-LED (ML) on the second substrate 301. In a case where the second substrate 301 is the circuit substrate, the bonding pad 3a may be formed as an electrode. In this case, the bonding pad 3a may be realized like the bonding pad 3a in FIG. 17.

Alternatively, the bonding pad 3a may be formed as a non-metal layer. In a case where the bonding pad 3a is formed as a non-metal layer, the second substrate 301 may be a temporary substrate.

The electrostatic chuck 4000 is provided underneath the second substrate 301. The electrostatic chuck 4000 may fix the second substrate 301 on an upper surface thereof using an electrostatic force. In other words, the electrostatic chuck 4000 may attach the second substrate 301 with the electrostatic force. Moreover, the electrostatic chuck 4000 applies the electrostatic force to the micro-LED (ML) absorbed to the transfer head 1 and thus may force the micro-LED (ML) to descend toward the second substrate 301. An electrode E is provided inside the electrostatic chuck 4000. A voltage is applied to an electrode E to induce the electrostatic force.

The electrostatic chuck 4000 may be divided into a low-resistance chuck and a high-resistance chuck by resistance value of a dielectric material. However, the electrostatic chuck 4000 serves not only to fix the second substrate 301 to the electrostatic chuck 4000, but also to exert the electrostatic force on the micro-LED (ML). Thus, the low-resistance chuck that uses the Johnsen-Rahbek effect of inducing a great electrostatic force is preferable. In the case of the high-resistance electrostatic chuck, electric charges corresponding to a simply implied voltage accumulate, and a coulomb force acts between positive and negative electric charges. In contrast, in the case of the low-resistance electrostatic chuck, in addition to the accumulation of the electric charges by the applied voltage, an electric charge moving up to an interface between an insulating layer underneath the second substrate 301 and an upper surface of the electrostatic chuck 4000 accumulate. Because an electrostatic force between the electric charges induced at the interface is very short, a greater electrostatic force flows in the low-resistance electrostatic chuck that uses the Johnsen-Rahbek effect than in the high-resistance electrostatic chuck. Therefore, it is preferable that the low-resistance electrostatic chuck is used.

Therefore, when a voltage is applied to the electrostatic chuck 4000, the electrostatic chuck 4000 may fix the second substrate 301 on the upper surface thereof using the electrostatic force. In this case, the electrostatic force generated in the electrostatic chuck 4000 may also be applied to the micro-LED (ML) absorbed to the transfer head 1. When the electrostatic force exerted by the electrostatic chuck 4000 on the micro-LED (ML) is greater than the absorption force exerted by the transfer head 1 on the micro-LED (ML), due to a difference therebetween, the micro-LED (ML) may be transferred toward the second substrate 301.

After the micro-LED (ML) is transferred to the second substrate 301, the electrostatic force resulting from operating the electrostatic chuck 4000 also attracts the micro-LED (ML) toward the downward direction. In other words, after the micro-LED (ML) is transferred toward the second substrate 301, a downward force is continuously exerted by the electrostatic chuck 4000 on the micro-LED (ML). Thus, the micro-LED (ML) may be fixed more firmly to the bonding pad 3a on the second substrate 301. The downward force continuously exerted by the electrostatic chuck 4000 on the micro-LED (ML) can prevent the micro-LED (ML) from being tilted during bonding to the bonding pad 3a. Thus, an error of alignment of the micro-LED (ML) can be prevented from occurring.

The circuit substrate may be provided on the second substrate 301 to which the micro-LCD (MR) is transferred. In this case, the micro-LED (ML) may be transferred by the transfer head 1 to the circuit substrate, and a process of bonding the micro-LED (ML) to the first electrode of the circuit substrate may be performed. In this case, the electrostatic force generated by the electrostatic chuck 4000 provided underneath the circuit substrate continuously exerts the downward force, toward the circuit substrate, on the micro-LED (ML). Thus, the micro-LED (ML) may be more firmly fixed to the first electrode of the circuit substrate.

When the micro-LED (ML) is transferred to the circuit substrate and the bonding of the micro-LED (ML) to the first electrode is completed, the electrostatic chuck 4000 stops operating and thus releases the electrostatic force. Accordingly, the circuit substrate is in a state of being separable from the electrostatic chuck 4000. Then, the circuit substrate on which the micro-LED (ML) is mounted is transported for a subsequent process. Thereafter, the circuit substrate is manufactured into a structure as illustrated in FIG. 2.

In this manner, in a case where the micro-LED (ML) absorbed to the transfer head 1 is desorbed using the electrostatic chuck 4000, the micro-LED (ML) may be desorbed without a separate fixation apparatus for fixing the micro-LED (ML) to the second substrate 301. Furthermore, the micro-LED (ML) may be firmly fixed to the second substrate 301 using the same physical electrostatic force as used for transferring to the second substrate 301.

In addition, with the method of transferring the micro-LED (ML) using the electrostatic chuck 4000, in a state where the micro-LED (ML) is spaced away from the second substrate 301, it is possible to transfer the micro-LED (ML). Thus, high-precision control of the bottom dead center of the transfer head 1 is unnecessary.

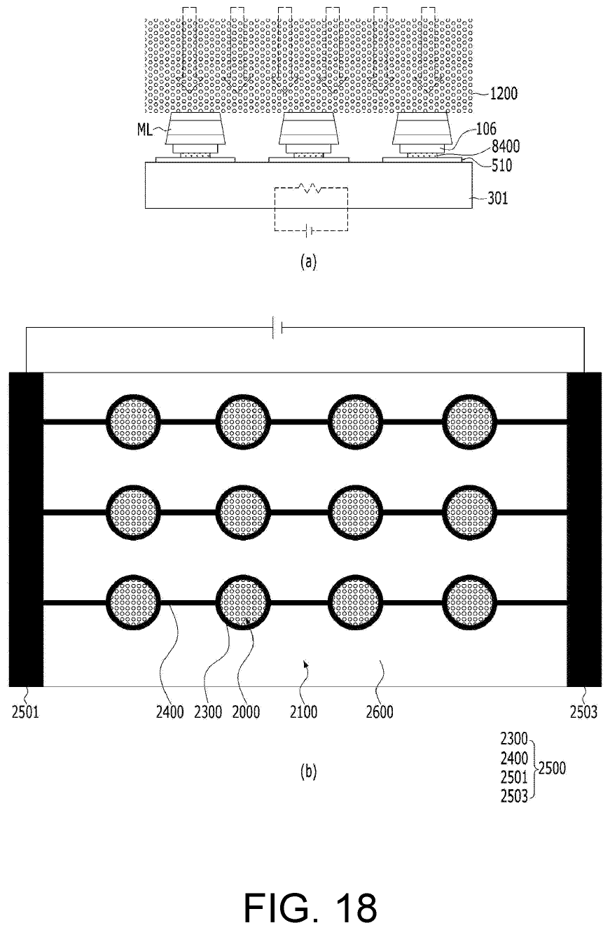

In a micro-LED bonding step, a cold solder joint occurs on the micro-LED (ML) transferred to the second substrate (for example, the circuit substrate 301, a target substrate, or a display substrate) due to a temperature difference between the micro-LED (ML) and the second substrate while bonded to the second substrate. FIGS. 18(a) and 18(b) are views each illustrating an implementation example of a method of solving the problem of the cold solder joint occurring in the micro-LED bonding step and preforming the micro-LED bonding step.

First, a method of heating the upper surface of the micro-LED (ML) using a heating means in the micro-LED bonding step and solving the problem of the cold solder joint between the micro-LED (ML) and the second substrate 301 will be described with reference to FIG. 18(a). FIG. 18(a) is a partially enlarged view illustrating a state where the micro-LED (ML) is bonded to the second substrate 301.

The heating means may serve to heat the upper surface of the micro-LED (ML). The heating means may be provided as a means of blowing hot air through the absorption region, a means of heating the suction pipe 1400 of the transfer head, a portion that is provided on the outside of the fixation support unit 7000 of the transfer head, a portion (for example, a heat jacket) covering the outside of the fixation support unit 7000 of the transfer head, or the like. However, the heating means is limited to these and may be suitably provided according to a configuration of the transfer head.

As one example, the transfer head may be configured to include the porous member 1200 for using the vacuum suction force and generating the vacuum suction force as the absorption force The porous member 1200 is formed in such a manner as to have the same structure as the second porous member 1200 in the first embodiment and thus serves as the absorption member to substantially absorb the micro-LED (ML). At this time, the first porous member 1100 in the first embodiment may be provided underneath the porous member 1200 and thus may absorb the micro-LED (ML). In this case, it is preferable that the heating means is provided as a means of blowing air through the absorption region. The transfer head may have the same configuration as in the first embodiment to the ninth embodiment.

As one example, an arrow, illustrated in FIG. 18(a), indicates a direction in which hot air is blown to the absorption region by a means of supplying hot air to the absorption region.

The heating means is provided in such a manner as to communicate with the suction pipe 1400 through which vacuum of the vacuum pump P is transferred to the porous member 1200, and thus may supply hot air to a pore in the porous member 1200. Thus, hot air may be applied to the micro-LED (ML) through the absorption region to which the micro-LED (ML) is absorbed. As a result, the upper surface of the micro-LED (ML) may be heated.

The transfer head absorbing the micro-LED (ML) on the first substrate (for example, the growth substrate 101, a temporary substrate, or a carrier substrate) may transport the absorbed micro-LED (ML) to the second substrate 301 for transferring. The transfer head using the vacuum suction force may desorb the micro-LED (ML) for transferring to the second substrate 301 by releasing the vacuum.

Then, the micro-LED bonding step of bonding the micro-LED (ML) on the second substrate 301. Specifically, in the micro-LED bonding step, the micro-LED (ML) is bonded to the bond layer 8400 provided on the second substrate 301. The bond layer 8400 may be formed to an island-like shape at a position corresponding to the micro-LED (ML).

In the micro-LED bonding step, the heating means operates when the micro-LED (ML) is bonded. When the heating means operates, hot air may be supplied to the pore in the porous member 1200. Thus, hot air may be applied to the upper surface of the micro-LED (ML) through the absorption region of the transfer head, and the upper surface of the micro-LED (ML) may be heated.

Specifically, in a case where the second substrate 301 illustrated in FIG. 18(a) is the circuit substrate 301, a first electrode 510 electrically connected to the first contact electrode 106 on the micro-LED (ML) is formed on the second substrate 301. The bond layer 8400 is provided on top of the first electrode 510, and serves to connect the first contact the electrode E of the micro-LED (ML) and the first electrode 510 and to fix the micro-LED (ML) to the second substrate 301.

When the micro-LED (ML) is bonded to the second substrate 301 using a metal bonding method (for example, a eutectic bonding method, only the second substrate 301 is heated. Thus, the cold solder joint may occur. In a case where the micro-LED (ML) is bonded by heating only the second substrate 301, temperature of a bonding metal (an alloy) relatively gradually decreases toward an upper surface thereof. Thus, the cold solder joint occurs. Thus, the micro-LED (ML) is not firmly bonded to the first electrode E.

However, in the bonding step, the means of supplying hot air to the absorption region may supply hot air to the pore in the porous member 1200, and thus may apply the hot air to the upper surface of the micro-LED (ML) through the absorption region. In this case, the porous member 1200 may be in a state of being spaced away from the upper surface of the micro-LED (ML) or being brought into contact therewith. FIG. 18(a) illustrates that, as one example, hot air is applied in a state where the porous member 1200 is brought into contact with the micro-LED (ML).

Hot air is supplied to the pore in the porous member 1200, and the porous member 1200 may be heated by the hot air. The heat of the porous member 1200 may be dissipated to the micro-LED (ML) in contact with the porous member 1200. A portion of the surface of the porous member 1200 with which the micro-LED (ML) is brought into contact may be the absorption region to which the micro-LED (ML) is absorbed. Therefore, the heat of the absorption region of the porous member 1200 may be dissipated to the micro-LED (ML) in contact with the absorption region. Thus, while the upper surface of the micro-LED (ML) is heated, temperature of the bond layer 8400 may be uniformly distributed according to a depth of the bond layer 8400. As a result, in the bonding step, the cold solder junction does not occur between the second substrate 301 and the micro-LED (ML). The micro-LED (ML) may be bonded more firmly to the first electrode 510 of the second substrate 301 by the bond layer 8400 in which temperature is uniformly distributed.

Alternatively, in a state where the micro-LED (ML) is desorbed from the absorption region and where the transfer head and the micro-LED (ML) are spaced apart, the porous member 1200 may apply hot air to the upper surface of the micro-LED (ML) through the absorption region. In this case, a state where hot air is injected toward the upper surface of the micro-LED (ML) through the absorption region may be attained. Accordingly, while the micro-LED (ML) is heated, the temperature of the bond layer 8400 may be uniformly distributed.

In this manner, in a case where the means of applying hot air to the absorption region is provided, the upper surface of the micro-LED (ML) may be heated in a state where the transfer head and the micro-LED (ML) are brought into contact with each other or in a state where the transfer head is spaced away from the micro-LED (ML). Thus, since the temperature of the bond layer 8400 is uniformly distributed, the micro-LED (ML) may be bonded more firmly to the first electrode 510.

The heating means may be provided as a hot air blower. In this case, the heating means is formed to a shape that communicates with the suction pipe 1400. The heating means may be provided in such a manner as to supply hot air to the pore in the porous member 1200. Alternatively, the heating means may be provided in such a manner as to supply hot air to the outside of the suction pipe 1400. Thus, the heating means may heat the suction pipe 1400 itself by supplying hot air to the outside of the suction pipe 1400. The hot air blower, as a means of heating the suction pipe 1400 from outside the suction pipe 1400, is one example. The heating means is not limited to the hot air blower.

In a case where the heating means is provided on the outside of the suction pipe 1400, air introduced into the transfer head may be heated while passing through the suction pipe 1400 heated by the heating means. The heated air may be transferred to the pore in the porous member 1200, and thus the upper surface of the micro-LED (ML) may be heated. As a result, the temperature of the bond layer 8400 is uniformly distributed, and thus the cold solder joint does not occur. Accordingly, the micro-LED (ML) may be bonded more firmly on the first electrode 510 of the second substrate 301.

The heating means may be provided on the outside of the fixation support unit 7000. The fixation support unit 7000 may include the porous member 1200 functioning as the absorption member and thus may serve to protect the configuration of the transfer head in such a manner as not to be exposed to the outside. Therefore, in a case where the heating means provided on the outside of the fixation support unit 7000 heats the fixation support unit 7000, the porous member 1200 provided inside the fixation support unit 7000 for being protected thereby may be heated. In a case where the heating means is provided on the outside of the fixation support unit 7000, the heating means, if capable of heating the fixation support unit 7000, is not limited in position.

The porous member 1200 to which heat is dissipated by the fixation support unit 7000 may heat the upper surface of the micro-LED (ML). The heating means is provided on the outside of the fixation support unit 7000, and thus the porous member 1200 is heated by the fixation support unit 7000 heated by the heating means. The porous member 1200 may in turn dissipate the heat to the micro-LED (ML) in a state of being in contact with the micro-LED (ML). Thus, the upper surface of the micro-LED (ML) may be heated.

The heated porous member 1200 may heat the upper surface of the micro-LED (ML), and thus the temperature of the bond layer 8400 is uniformly distributed. As a result, the temperature of the bonding metal (an alloy) gradually decreases toward the upper surface thereof. Accordingly, a phenomenon does not occur where the micro-LED (ML) is not bonded to the first electrode 510 of the second substrate 301 and falls.

It is preferable that the heating means heating the fixation support unit 7000 starts to heat the fixation support unit 7000 before absorbing the micro-LED (ML) on the first substrate and keeping heating the micro-LED (ML) until the micro-LED (ML) is transferred to the second substrate 301. In other words, the heating means may heat the fixation support unit 7000 in advance before the micro-LED (ML) is absorbed from the first substrate. In this case, the transfer head may absorb the micro-LED (ML) on the first substrate, in a state of being heated, and may transport the absorbed micro-LED (ML) to the second substrate 301.

In a case where the heating means heats the fixation support unit 7000 before the transfer head absorbs the micro-LED (ML), the first substrate on which the absorbing of the micro-LED (ML) is performed and the second substrate 301 on which the transferring and bonding of the micro-LED (ML) are performed may be in the same temperature environment.

Specifically, if the transfer head absorbs and transfers the micro-LED (ML) at different temperatures, respectively, the pitch distance between the micro-LEDs (ML) may change. Thus, a transfer error may occur, and the steps of transferring and bonding the micro-LED (ML) are not properly performed. Accordingly, a process yield may be decreased.

However, in a case where the fixation support unit 7000 is heated in advance before the transfer head absorbs the micro-LED (ML) on the first substrate, the temperature environment where the micro-LED (ML) is absorbed from the first substrate 101 and the temperature environment where the micro-LED (ML) is transferred to the second substrate 301 may be the same. Thus, the transfer head may be prevented from being thermally expanded due to a difference in temperature in the second substrate 301. The transfer error due to thermal deformation of the transfer head does not occur. In addition, the heating means continues heating until the micro-LED (ML) is transferred to the second substrate 301, and thus the upper surface of the micro-LED (ML) may be heated until the bonding step is performed after transferring. As a result, temperature may be uniformly distributed to upper and lower portions of the bond layer 8400, and thus the micro-LED (ML) may be bonded more firmly to the first electrode 510 of the second substrate 301.

The heating means may be formed to a shape that covers the fixation support unit 7000 from outside the fixation support unit 7000. In this case, the heating means, if capable of covering an outer surface of the fixation support unit 7000, is not limited in configuration. As one example, the heating means in the shape of a heat jacket may be provided on the outside of the fixation support unit 7000.

With the heating means, the absorption member serving to absorb the micro-LED (ML) may be heated, and the heated absorption member in contact with the micro-LED (ML) may heat the upper surface of the micro-LED (ML). As a result, the temperature may be uniformly distributed to the upper and lower portions of the bond layer 8400, and thus the efficiency of bonding of the micro-LED (ML) is increased.

FIG. 18(b) is a view illustrating a portion of the lower surface of the transfer head. As illustrated in FIG. 18(b), the transfer head is configured to include a heater unit 2500. In the micro-LED bonding step, the heater unit 2500 may heat the upper surface of the micro-LED (ML).

The cold solder joint that occurs between the micro-LED (ML) and the second substrate 301 in the micro-LED bonding step does not further occur because of the heater unit 2500 mounted on the lower surface of the transfer head that is substantially brought into contact with the micro-LED (ML). The transfer head may be configured as a transfer head that uses a vacuum suction force, an electrostatic force, a van der Waals force, or an adhesive force. However, as an example, the transfer head that includes the porous member 1000 as the absorption member absorbing the micro-LED (ML) and uses the vacuum suction force is provided for description.

The heater unit 2500 may be configured to include the first and second pads 2501 and 2503, a heating unit 2300, and a connection unit 2400. The eating unit 2300 is formed at a position corresponding to a position for absorbing the micro-LED (ML). The connection unit 2400 connected between each of the first and second pads 2501 and 2503 and the heating unit 2300 and between the heating units 2300. When voltage is applied to the first and second pads 2501 and 2503, the heating unit 2300 converts electrical energy to thermal energy. Accordingly, the upper surface of the micro-LED (ML) may be heated.

As many heating units 2300 as the number of the micro-LEDs (ML) that are to be transferred may be formed. In FIG. 18(b), only a portion of the heater unit 2500 is illustrated for the convenience of description.

The heating unit 2300 may have the shape of a closed loop. As illustrated in FIG. 18(b), the closed loop may be a circular ring or a polygonal ring. The heating unit 2300 is not limited to these shapes. The heating unit 2300 according to the present invention may take any shape that is suitable for receiving its electricity and converting electrical energy into thermal energy.

The connection unit 2400 is configured to be provided between the heating unit 2300 and the heating unit 2300. The connection unit 2400 electrically connects the heating units 2300 to each other and serves to carry electricity for supply to the heating unit 2300. In addition, the connection unit 2400 serves to connect the outermost heating unit 2300 and each of the first and second pads 2501 and 2503.

The pore formed in the surface of the porous member absorbs the micro-LED (ML) with a suction force. In this case, the pore formed in the surface of the porous member is exposed into the inside of the heating unit 2300. Using the pore inside the heating unit 2300, the micro-LED (ML) may be absorbed, and the heating unit 2300 may heat the upper surface of the micro-LED (ML).

The pore here inside the heating unit 2300 may be a pore that naturally occurs when manufacturing the porous member and a through-hole that is additionally formed by etching or a laser process after manufacturing the porous member.

The cover portion of the transfer head may be configured as the shield portion 2600. The shield portion 2600 is formed a portion of a lower surface of the porous member other than the inside of the heating unit 2300 and thus may block the pore in the porous member. Thus, as illustrated in FIG. 18(b), the pore in the lower surface of the porous member is not exposed except for the inside of the heating unit 2300. With this structure, the absorption force for the micro-LED (ML) is exerted on the absorption region 2000 formed inside the heating unit 2300 and is not exerted on the outside of the heating unit 2300. The absorption region 2000 may vacuum-absorb the micro-LED (ML) using vacuum exerted on the pore.

The transcription head on which the heater unit 2500 is provided may absorb the micro-LEDs ML using the adsorption region 2000 and then may transfer the micro-LEDs (ML) to the first electrode on the second substrate.

Then, electricity is applied to the heater unit 2500 on the transfer head and heats the heating unit 2300. In addition, electric power is applied to the second substrate and heats the first electrode of the second substrate.

As a means of bonding the micro-LED (ML) to the second electrode, a metal bonding method may be used. In the metal bonding method, a bonding metal (an alloy) is heated, and the micro-LED (ML) is bonded to the first electrode with the melted bonding metal. In the metal bonding method, thermal compression bonding, eutectic bonding, or the like may be performed.

In this bonding process, in a case where only the second substrate is heated, temperature of the bonding metal (an alloy) is relatively gradually decreased toward the upper surface thereof. Thus, a cold solder joint may occur. However, in a case where the heater unit 2500 is provided, as described above, only the upper surface of the micro-LED (ML) may be heated. Thus, since temperature is uniformly distributed to upper and lower portions of the bond layer 8400, the cold solder joint does not occur. As a result, the micro-LED (ML) may be bonded more firmly to the first electrode of the second substrate.

In a case where the porous member 1000 of the transfer head transferring the micro-LED (ML) has a double structure as in the first embodiment and where the first porous member is provided as the anodic oxide film, the heater unit 2500 may be provided on the lower surface of the anodic oxide film. In this case, the heater unit 2500 may be provided in such a manner as not to block the pore formed in the lower surface of the first porous member, and the micro-LED (ML) may be absorbed to the absorption region 2000 formed inside the heating unit 2300. In this case, the barrier layer 1600b may be removed from the absorption region, and thus a hole may be formed in the absorption region in a manner that passes through from top to bottom.

In a case where the first porous member is provided as the anodic oxide film, the heater unit 2500 may be configured to include a vertical conductive part that vertically passes through the first porous member and a horizontal conductive part that is connected to the vertical conductive part and is exposed toward the surface side. The heater 2500 with this configuration may be included in the transfer head.

The heater unit 2500 may be configured in such a manner as to be included in the absorption region 2000 instead of being formed on the lower surface of the first porous member.

The heater unit 2500 configured to include the vertical conductive part and the horizontal conductive part may be provided inside the absorption region 2000 and may be provided inside the non-absorption region 2100. However, in a case where the vertical conductive part and the horizontal part are configured in such a manner as to be provided inside the absorption region 2000, electricity may be applied to the heater unit 2500 in a state where the micro-LED (ML) is absorbed. In this case, the absorption region 2000 may be configured to include an absorption unit and the heater unit 2500. A pore is formed in the absorption unit in a manner that passes through from top to bottom. The micro-LED (ML) is absorbed to the absorption portion of the absorption region 2000. The heater unit 2500 is formed of a conductive material.

The horizontal conductive part is formed on a surface that is opposite to the absorption surface to which the micro-LED (ML) is absorbed by the transfer head. The vertical conductive part is positioned inside the absorption region 2000 to which the micro-LED (ML) is absorbed. The vertical conductive part is formed by filling the pore or the through-hole in the anodic oxide film with a conductive material. A first end thereof is connected to one portion of the horizontal part, and a second end thereof is formed, in an exposed manner, on the absorption surface to which the micro-LED (ML) is absorbed.

Accordingly, the absorption region 2000 absorbs the micro-LED (ML) and at the same time, the horizontal conductive part is brought into contact with the absorption surface of the absorption region 2000. Thus, it is possible that the upper surface of the micro-LED (ML) is heated.

Alternatively, the horizontal conductive part is configured in such a manner as to cover only one portion of the pore in the absorption region 2000 that passes through from top to bottom. The micro-LED (ML) is absorbed to the pore not covered by the horizontal conductive part.

In addition, a common heater unit that connects together the horizontal conductive parts that are arranged side by side is provided on one side of the anodic oxide film. One common heater unit is configured in such a manner as to be connected to a plurality of horizontal conductive parts. With this configuration of the common heater unit, the horizontal conduction parts that are arranged side by side are simultaneously connected to each other.

The transfer head including the heater unit configured to include the vertical conductive part and the horizontal conductive part may absorb and transfer the micro-LED (ML) and at the same time may heat the upper surface of the micro-LED (ML).

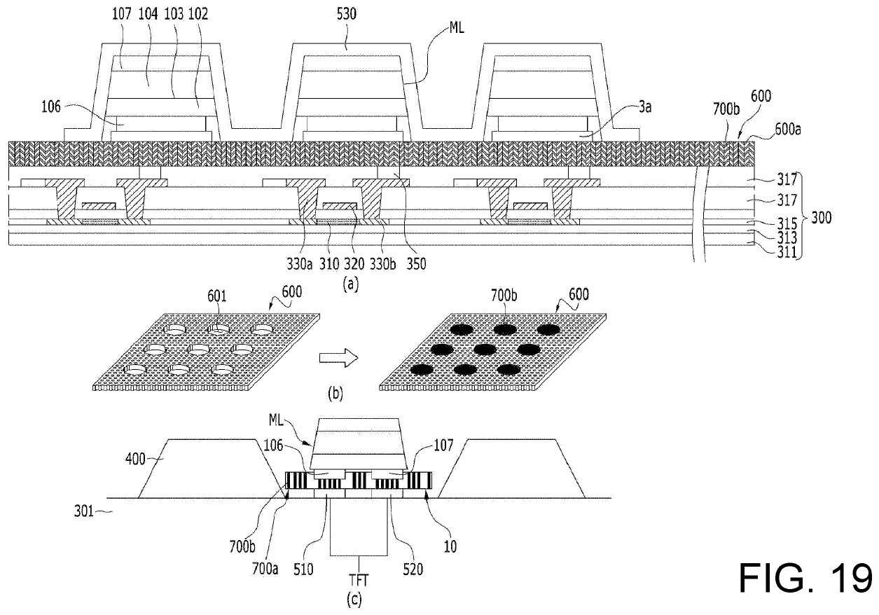

FIG. 19 is a view illustrating implementation examples of the micro-LED bonding step that uses an anisotropic conductive layer. Due to a short separation distance between the micro-LEDs (ML), electricity may not flow between the micro-LEDs (ML). This problem can be prevented by performing the micro-LED bonding step that uses an anisotropic conductive layer.

FIG. 19(a) is a partially enlarged view illustrating the micro-LED (ML) mounted on the circuit substrate 301. FIG. 19(b) is a view illustrating the anodic oxide film in which a through-hole 601 and a state where the through-hole 601 is filled with a conductive material 700b.

The micro-LED bonding step of bonding the micro-LED (ML) to the second substrate 301 is configured to include: a sub-step of preparing between the micro-LED (ML) and the second substrate 301 an anisotropically conductive anodic oxide film 600 formed by filling with the conductive material 700b a pore 600a in the anodic oxide film 1600 formed by anodically oxidizing a metal or a separate through-hole 601; and a sub-step of mounting the micro-LED (ML) on the anisotropically conductive anodic oxide film 600. The micro-LED bonding step configured to include these sub-steps may be performed to bond the micro-LED (ML).

As illustrated in FIG. 19(a), the anisotropically conductive anodic oxide film 600 is provided on the circuit substrate 301. The anisotropically conductive anodic oxide film 600 is provided between the micro-LED (ML) and the circuit substrate 301, and thus electrically connects the circuit substrate 301 and the micro-LED (ML) to each other. In this case, the anisotropically conductive anodic oxide film 600 is formed with reference to the configuration of the above-described anodic oxide film 1600. Thus, a description of a configuration that is the same as that of the above-described anodic oxide film is omitted.

The pores 600a that constitute the anodic oxide film 1600 are present independently of each other. The conductive materials 700b fill the pores 600a, respectively. Then, the conductive materials 700b with which the pores 600a, respectively, are filled are present independently without being connected to each other. In this manner, when the pore 600a in the anodic oxide film 1600 is filled with the conductive material 700b, the anisotropically conductive anodic oxide film 600 that is vertically conductive and is horizontally non-conductive is formed. The anodic oxide film 1600 that is filled with the conductive material 700b is referred to as the “anisotropically conductive anodic oxide film 600”. The conductive material 700b is not particularly limited. in type. The anisotropically conductive anodic oxide film 600 may function as an anisotropically conductive layer.

As illustrated in FIG. 19(a), the conductive material 700b may fill all the pores 600a in the anisotropically conductive anodic oxide film 600. The anisotropically conductive anodic oxide film 600 is divided into a region on which the micro-LED (ML) is mounted and a region on which the micro-LED (ML) is not mounted. As illustrated in FIG. 19(a), the conductive material 700b may fill all the pores 600a in the regions including the region on which the micro-LED (ML) is not mounted.

When the pores 600a in the region on which the micro-LED (ML) is mounted are filled with the conductive material 700b, the region on which the micro-LED (ML) is mounted may be vertically conductive due to the conductive material 700b. Moreover, heat occurring in the micro-LED (ML) may be effectively dissipated through the conductive material 700b.

With the configuration of the anisotropically conductive anodic oxide film 600 formed of the same material as the anodic oxide film, the heat occurring in the micro-LED (ML) is effectively dissipated in the vertical direction and is effectively blocked from being dissipated in the horizontal direction. As a result, the effect which the heat occurring in the micro-LED (ML) has on the adjacent micro-LED (ML) is minimized, and thus the luminous efficiency of the micro-LED (ML) can be prevented from decreasing.

In addition, since the pore 600a in the region on which the micro-LED (ML) is not mounted is also filled with the conductive material 700b, there is an advantage in that the technology for precise alignment is not necessary when forming the bonding pad 3a described below. In addition, in a case where the micro-LED (ML) is of a flip type, there is an advantage in that the precise alignment of the micro-LED (ML) is not necessary.

As illustrated in FIG. 19(a), the bonding pad 3a is provided on top of the anisotropically conductive anodic oxide film 600. Specifically, the bonding pad 3a is formed on top of the anisotropically conductive anodic oxide film 600 in a manner that corresponds to a position at which the micro-LED (ML) is mounted. The bonding pad 3a is electrically connected to the first contact electrode 107 on the micro-LED (ML). The bonding pad 3a may have various shapes. For example, the bonding pad 3a may be formed to an island-like shape by patterning. The bonding pad 3a may function as the bond layer 8400. The micro-LED (ML) is mounted on top of the bonding pad 3a.

The first contact electrode 106 on the micro-LED (ML) is electrically connected to the bonding pad 3a. The bonding pad 3a is electrically connected to a drain electrode 330b through the conductive material 700b of the anisotropically conductive anodic oxide film 600 and a contact hole in the circuit substrate 301.

The first electrode may be formed on the circuit substrate 301. The first electrode is electrically connected to the drain electrode 330b through a contact hole 350 formed in the planarization layer 317 and is electrically connected to the bonding pad 3a through the anisotropically conductive anodic oxide film 600. The first electrode may have various shapes. For example, the first electrode may be formed to an island-like shape by patterning.

A lower bonding pad (not illustrated) may be additionally formed underneath anisotropically conductive anodic oxide film 600. The lower bonding pad, if capable of being conductive, is not limited in material. The lower bonding pad may have various shapes. For example, the lower bonding pad may be formed to an island-like shape by patterning. The bonding pad may serve to electrically connect the anisotropically conductive anodic oxide film 600 and the drain electrode 330b in a more effective manner.

As illustrated in FIG. 19(a), the micro-LED display including the anisotropically conductive anodic oxide film 600 may be manufactured using a fabrication method including: a first step of filling all pores 600a in the anodic oxide film 1600 formed by anodically oxidizing a metal with the conductive material 700b and preparing the anisotropically conductive anodic oxide film 600; and a second step of forming the bonding pad 3a on top of the anisotropically conductive anodic oxide film 600; and a third step of mounting the micro-LED (ML) on top of the bonding pad 3a.

First, a process of manufacturing the anisotropically conductive anodic oxide film 600 is described. The anodic oxide film 1600 is manufactured by anodically oxidizing a metal that is a base material. Then, the metal base material is removed, and a barrier layer of the anodic oxide film 1600 is removed. Thus, the pore 600a is formed in the anodic oxide film 1600 in a manner that passes therethrough from top to bottom. Then, the pore 600a passing through the anodic oxide film 1600 from top to bottom is filled with the conductive material 700b. In this case, the Atomic Layer Deposition (ALD) may be used to fill the pore 600a with the conductive material 700b. However, in addition to the ALD, any method of filling the pore 600a with the conductive material 700b may be used. When the pore 600a is filled with the conductive material 700b according to a direction in which the pore 600a is formed, the anodic oxide film 1600 becomes the anisotropically conductive anodic oxide film 600.

Thereafter, the micro-LED (ML) is transferred to the upper surface of the bonding pad 3a for being mounted thereon. Then, the second electrode 530 is formed on the upper surface of the micro-LED (ML). In this case, the second electrode 530 may be individually formed on each of the micro-LEDs (ML). As illustrated in FIG. 19(a), one second electrode 530 may be formed on upper surfaces of the micro-LEDs (ML). Then, the second electrode 530 is positioned on top of the circuit substrate 301. The fabrication of the micro-LED display is finished.

However, before the micro-LED (ML) is mounted on top of the bonding pad 3a, the anisotropically conductive anodic oxide film 600 on which the bonding pad 3a is formed may be provided to the circuit substrate 301. Then, the micro-LED (ML) may be mounted. In other words, after the anisotropically conductive anodic oxide film 600 on which the bonding pad 3a is formed is provided on top of the circuit substrate 301, the micro-LED (ML) may be mounted, and then the second electrode 530 may be formed. In this manner, the micro-LED display may be manufactured.

As described above, in a case where the micro-LED display is manufactured using the anisotropically conductive anodic oxide film 600, there is no need for a separate apparatus or process for thermal compression. The circuit substrate 301 and the micro-LED (ML) may be electrically connected to each other in a more effective manner through the conductive material 700b of a uniform length inside the pore 600a in the anodic oxide film 1600. The conductive materials 700b are spaced apart by a predetermined distance. In addition, in a case where the micro-LED display illustrated in FIG. 19(a) is manufactured, the patterned bonding pad 3a may be manufactured more easily because all the pores 600a in the anodic oxide film 1600 are filled with the conductive material 700b.

Instead of filling all the pores 600a in the anodic oxide film 1600 with the conductive material 700b as illustrated in FIG. 19(a), as illustrated in FIG. 19(b), the through-hole 601 having an opening that has a greater area than a single opening of the pore 600a in the anodic oxide film 1600 may be formed, and the through-hole 601 may be filled with the conductive material 700b. In this manner, the micro-LED display may be manufactured. In other words, the through-hole 601 has a greater size than the pore 600a formed by anodically oxidizing a metal. The micro-LED display with this configuration is advantageous in heat dissipation and in preventing occurrence of an electric short circuit due to an overflow of the conductive material 700b with which the pore 600a in the region on which the micro-LED (ML) is not mounted is filled.

When manufacturing the micro-LED display, instead of filling all the pores 600a in the anodic oxide film 1600 with the conductive material 700b as illustrated in FIG. 19(a), only the pore 600a in the region that corresponds to the region on which the bonding pad 3a is formed may be filled with the conductive material 700b. The region here that corresponds to the region on which the bonding pad 3a is formed has the same area as the bonding pad 3a or, although having a different area, is not brought into contact with the adjacent bonding pad 3a. With the above-described configuration, an amount of the conductive material 700b used is small when compared with the micro-LED display in which all the pores 600a in the anodic oxide film 1600 are filled with the conductive material 700b. In addition, the above-described configuration provides the advantage of preventing an electric short circuit due to the overflow of the conductive material 700b with which the pore 600a in the region on which the micro-LED (ML) is not mounted.

As described above, in a case where a micro-LED display is manufactured using the method for manufacturing the micro-LED display according to the present invention, the micro-LED display may be configured to include the second substrate on which the circuit wiring unit is provided and the anisotropically conductive anodic oxide film 600 that is provided between the micro-LED (ML) and the second substrate and electrically connects the second substrate and the micro-LED (ML) to each other.

In this case, the anisotropically conductive anodic oxide film 600 may electrically connect the second substrate and the micro-LED (ML) to each other by filling the pore 600a formed by anodically oxidizing a metal or the separate through-hole 601 with the conductive material 700b.

A plurality of anisotropically conductive anodic oxide films 600, each of which is formed by filling the pore 600a or the separate through-hole 601 in the anodic oxide film 1600 with the conductive material 700b, may be stacked on top of each other with the bond layer in between in such a manner as to have a predetermined thickness. When the configuration in which the plurality of anisotropically conductive anodic oxide films 600 are stacked on top of each other is employed, each of plurality of anisotropically conductive anodic oxide films 600 may include the conductive material 700b with which the through-hole is filled and a horizontal conductive material (not illustrated) formed on a surface of the anisotropically conductive anodic oxide film 600. Accordingly, when the micro-LED (ML) including a flip-type terminal is mounted, a short separation distance between the terminals is increased at lower portions thereof through the plurality of anisotropically conductive anodic oxide films 600. The micro-LED (ML) including the flip-type terminal may be electrically connected to the second substrate 301 in an easier manner.

FIG. 19(c) is an enlarged view illustrating the micro-LED display including an anisotropic conductive film 700. The micro-LED display may be configured to include the anisotropic conductive film 700 as an isotropic conductive layer.

In this case, the micro-LED bonding step of bonding the micro-LED (ML) to the second substrate 301 may be configured to include: a sub-step of preparing between the micro-LED (ML) and the second substrate 301 the anisotropic conductive film 700 formed by filling with the conductive material 700b a plurality of holes 700a vertically formed in an insulating porous film which is formed of an elastic material and in which the plurality of holes 700a is vertically formed; and a sub-step of mounting the micro-LED (ML) on the anisotropic conductive film 700. The micro-LED (ML) may be bonded to the second substrate 301 by performing the above-described micro-LED bonding step.

As illustrated in FIG. 19(c), the anisotropic conductive film 700 is formed by filling with the conductive material 700b a plurality of holes vertically formed in the insulating porous film which is formed of an elastic material and in which the plurality of hole. In other words, when the vertical hole in the insulating porous film is filled with the conductive material 700b, the anisotropic conductive film 700 may be formed.

The plurality of vertical holes formed in the insulating porous film are irregular. Therefore, the holes 700a in the anisotropic conductive film 700 formed by filling the holes with the conductive material 700b are irregular. The plurality of vertical holes 700a with which the conductive material 700b is filled are irregularly formed in such a manner as to be spaced apart by different distances. The holes 700a in a vertical form are present independently of each other. Thus, the conductive materials 700b with which the holes 700a are filled, respectively, are present independently of each other. Therefore, the conductive material 700b with which the holes 700a are filled are irregularly formed and are present in a vertical columnar shape. The conductive materials 700b in the vertical columnar shape that are spaced apart extend horizontally, and thus the conductive materials 700b have an effect on the adjacent micro-LED (ML) and terminals, such as the first contact electrode 106 and the second contact electrode 107 on the micro-LED (ML). The problem in which electricity does not flow can be prevented.

When the plurality of vertical holes in the insulating porous film is filled with the conductive material 700b, the anisotropic conductive film 700 that is vertically non-conductive may be formed. Alternatively, the anisotropic conductive film 700 may be formed by filling at least one or more vertical holes in the insulating porous film with the conductive material 700b. The conductive material 700b may be a thermally conductive material 700b and an electrically conductive material 700b. The conductive material 700b is not particularly limited in type.

All the holes 700a in the anisotropic conductive film 700 may be filled with the conductive material 700b. The anisotropic conductive film 700 may be partitioned into a region on which the micro-LED (ML) is mounted and a region on which the micro-LED (ML) is not mounted. The region here on which the micro-LED (ML) is mounted is partitioned into a direct contact portion on which the micro-LED (ML) is mounted and which is thus brought into direct contact with a terminal of the micro-LED (ML) and a micro-LED non-contact portion that corresponds to a portion on which the micro-LED (ML) is not formed.

FIG. 19(c) is an enlarged view illustrating the micro-LED display in which a pixel region is defined by the bank layer 400. In this case, the micro-LED display illustrated in FIG. 19(c) may be in a state where the anisotropic conductive film 700 is elastically deformed by application of pressure or heat.

In a micro-LED display 1 in which the pixel region is defined by the bank layer 400, the anisotropic conductive film 700 is provided, in a state of being cut, in the accommodation concave portion of the bank layer 400 on which the micro-LED (ML) is mounted. In the anisotropic conductive film 700, all the vertical holes 700b in the region on which the micro-LED (ML) is mounted and in the region which the micro-LED (ML) is not mounted are filled with the conductive material 700b.

Since the hole 700a in the direct contact portion of the micro-LED mounting region that is brought into direct contact with the terminal of the micro-LED (ML) is filled with the conductive material 700b, the direct contact portion is vertically conductive through the conductive material 700b. Thus, the terminal of the micro-LED (ML), and the first electrode 510 and the second electrode 520 of the circuit substrate 301 are electrically connected to each other.

As illustrated in FIG. 19(c), when pressure or heat is applied to the micro-LED (ML), the direct contact portion of the micro-LED mounting region is deformed by pressure or heat.

The direct contact portion may be deformed by pressure or heat, and thus the terminal of the micro-LED (ML), and the first electrode 510 and the second electrode may be electrically connected.

The anisotropic conductive film 700 formed of an elastic material may prevent the terminal from being damaged when the terminal and the anisotropic conductive film 700 are brought into contact with each other.

The hole 700a in the micro-LED non-contact portion of the micro-LED mounting region is also filled with the conductive material 700b. The conductive material 700b in the vertical columnar shape of the micro-LED non-contact portion may vertically dissipate heat occurring in the micro-LED (ML) in an effective manner. In a case where the conductive material 700b is a thermally conductive material, the heat dissipation through the conductive material 700b may be effectively performed.

The micro-LED display including the anisotropic conductive film 700 that is vertical conductive may effectively block the heat occurring in the micro-LED (ML) from being horizontally dissipated. In an anisotropic conductive film (ACF) in the related art, heat may be dissipated in any of the horizontal and horizontal directions by a core in which an insulating film is damaged. Thus, the luminous efficiency may be decreased due to the effect that the heat occurring in one micro-LED (ML) has on the adjacent micro-LED (ML).

However, in the micro-LED display including the anisotropic conductive film 700 that is vertically conductive, the effect that the heat occurring in the micro-LED (ML) has on the different micro-LED (ML) is minimized. Thus, the luminous efficiency of the micro-LED (ML) can be improved.

In the micro-LED display, in the direct contact portion as described above, the terminal, and the first electrode 510 and the second electrode 520 may be electrically connected to each other through the conductivity in the vertical direction without the effect on the adjacent micro-LED (ML) and the terminal of the micro-LED (ML). FIG. 19(c) illustrates a flip-type micro-LED (ML), as an implementation example of the micro-LED (ML), in which a terminal including the first and second contact electrodes 106 and 107 on the micro-LED (ML) is formed in such a manner as to protrude downward from a first semiconductor layer 102.

In this case, because the size of the micro-LED (ML) is small, a separation distance between the micro-LEDs (ML) may be short, and a separation distance between the terminals of the micro-LED (ML) may be short. The separation distance here between the terminals means a separation distance between a terminal of one micron-LED (ML) and a terminal of an adjacent micro-LED (ML) or a separation distance between the first contact electrode 106 and the second electrode 107 that are formed on one surface of the micro-LED (ML).

In a case where the anisotropic conductive film ACF is provided and where the micro-LED (ML) is electrically connected to the circuit substrate 301, the core in which the insulating film is damaged by pressure or heat extends in the horizontal direction, and thus has an effect on the adjacent micro-LED (ML) or the terminal of the micro-LED (ML). The problem in which electricity does not flow may occur. This problem is serious in the field of the micro-LED (ML) in which a distance between terminals is very short.

In a case where the anisotropic conductive film 700 that is vertically conductive is provided, the first contact electrode 106 may be connected to only the first electrode 510, and the second contact electrode 107 may be connected to only the second electrode 520. The conductivity in the horizontal direction does not occur. Thus, the electric effect on the micro-LED (ML) or the terminal of the micro-LED (ML) does not occur.

The anisotropic conductive film 700 may be formed in such a manner that all the holes 700a therein are filled with the conductive material 700b or in such a manner that only one or several of the holes 700a therein are filled with the conductive material 700b. In other words, only one or several of the holes in the anisotropic conductive film 700 may be filled with the conductive material 700b, but only the direct contact portion of the micro-LED mounting region may be filled with the conductive material 700b. This filling of the holes may be performed through a masking process. However, in addition to the masking process, any method in which only one or several holes 700a in the insulating porous film can be filled with the conductive material 700b may be used.

In a case where the holes in only the direct contact portion of the micro-LED mounting region of the anisotropic conductive film 700 are filed with the conductive material 700b, the thermal insulation effect can be achieved through the holes 700a not filled with the conductive material 700b.

For example, a direct contact portion of the micro-LED display that is illustrated in FIG. 19(c) is filled with the conductive material 700b, and a micro-LED non-mounting region other than the direct contact portion and the micro-LED non-contact portion of the micro-LED mounting region are not filled with the conductive material 700b. When pressure or heat is applied to the micro-LED (ML), the micro-LED (ML) and the circuit substrate 301 are electrically connected to each other through the direct contact portion of the micro-LED mounting region that is filled with the conductive material 700b. In this case, through air inside the hole 700a, a non-contact portion of the micro-LED mounting region that is not filled with the conductive material 700b serves to provide thermal insulation to the direct contact portion that is filled with the conductive material 700b. Thus, the stripping of the micro-LED (ML) from the circuit substrate 301 may be minimized.

In the case of the anisotropic conductive film 700, the hole 700a are irregularly formed, and thus heat may be dissipated through the region in which the hole 700a is not formed. However, the dissipation of the heat to the entire anisotropic conductive film 700 may be prevented through the holes 700a that are irregularly present and that are not filled with the conductive material 700b. Therefore, the anisotropic conductive film 700, one or several holes 700a in which are filled with the conductive material 700b, may serve to provide the thermal insulation.

A configuration in which the anisotropic conductive film 700 is continuously provided may be employed instead of the configuration in which the anisotropic conductive film 700 is individually provided inside the bank layer 400.

The anisotropic conductive film 700 may be provided continuously between the micro-LED (ML) and the circuit substrate 301. Thus, the micro-LEDs (MLP) may be mounted on one anisotropic conductive film 700 provided on top of the circuit substrate 301 in such a manner as to be spaced apart.

All holes 700a in the micro-LED mounting region and the micro-LED non-mounting region of the anisotropic conductive film may be filled with a conductive material. In this case, all the holes 700a in the micro-LED mounting region including the direct contact portion that is brought into direct contact with the terminal of the micro-LED (ML) and the micro-LED non-contact portion that corresponds to the portion on which the terminal of the micro-LED (ML) is not formed may be filled with the conductive material 700b.

Alternatively, only the hole 700a in the direct contact portion may be filled with the conductive material 700b. In this case, the anisotropic conductive film 700 may serve to provide the thermal insulation, and thus prevent the micro-LED (ML) from being stripped from the circuit substrate 301.

The micro-LED display including the anisotropic conductive film 700 may be manufactured using a fabrication method including: a first step of forming an anisotropic conducting film by filling with the conductive material 700b a plurality of holes 700a vertically formed in an insulating porous film which is formed of an elastic material and in which the plurality of holes 700a is vertically formed; a second step of mounting the anisotropic conductive film 700 on the circuit substrate 301 to which the micro-LED (ML) is bonded; and a third step of mounting the micro-LED (ML) on top of the anisotropic conductive film 700.

First, the anisotropic conductive film 700 may be manufactured as follows.

The insulating porous film which is formed of an elastic material and in which the plurality of holes 700a are vertically formed is prepared. Then, the plurality of holes 700a vertically formed is filled with the conductive material 700b. Accordingly, the plurality of holes 700a is filled with the conductive material 700b, and as a result, the anisotropic conductive film 700 that is vertically conductive is formed.

The plurality of holes 700a in the anisotropic conductive film 700 may be all filled with the conductive material 700b, or only one or several of the holes 700a may be filled with the conductive material 700b. In a case where all the holes 700a in the anisotropic conductive film 700 are filed with the conductive material 700b, the anisotropic conductive film 700 may serve to provide the heat dissipation, and thus the light emitting efficiency of the micro-LED (ML) can be increased.

In a case where one or several of the holes 700a in the anisotropic conductive film 700 are filled with the conductive material 700b, the anisotropic conductive film 700 may serve to provide the heat dissipation, and the micro-LED (ML) can be prevented from being stripped from the circuit substrate 301. In this case, one or several holes 700a of the holes 700a in the anisotropic conductive film 700 may mean the direct contact portion of the micro-LED mounting region.

The second step of mounting the anisotropic conductive film 700 formed in the first step on the circuit substrate 301 to which the micro-LED (ML) is bonded is performed. The anisotropic conductive film 700 may be mounted in continuous form on one circuit substrate 301 and may be mounted in a state of being cut in such a manner as to correspond to each of the micro-LEDs (ML).

In a case where the anisotropic conductive film 700 is provided in a state of being cut, a cutting step of cutting the anisotropic conductive film 700 may be performed subsequently to the first step. The anisotropic conductive film 700 to be mounted on the circuit substrate 301 may be mounted using a method suitable for moving the anisotropic conductive film 700.

Subsequently to the second step, the third step of mounting the micro-LED (ML) on top of the anisotropic conductive film 700 is performed. Then, the micro-LED (ML) and the circuit substrate 301 may be electrically connected to each other by applying pressure or heat to the micro-LED (ML). In this case, a portion of the anisotropic conductive film 700 that is provided between the micro-LED (ML) and the circuit substrate 301 may be elastically deformed.

In this manner, in the micro-LED display including the anisotropic conductive film 700 vertically conductive, the problem due to horizontal connection of the conductive material 700b, in which electricity does not flow, can be prevented. In addition, in a case where the plurality of holes 700a in the anisotropic conductive film 700 provided in the micro-LED display is all filled with the conductive material 700b, the heat dissipation effect can be achieved, and thus the luminous efficiency can be improved. In a case where one or several of the holes 700a are filled with the conductive material 700b, the thermal insulation effect can be achieved, and thus the micro-LED (ML) can be prevented from being stripped.

As described above, in a case where a micro-LED display is manufactured using the method for manufacturing the micro-LED display according to the present invention, the micro-LED display may be configured to include the second substrate 301 on which the circuit wiring unit is provided and the anisotropically conductive anodic oxide film 700 that is provided between the micro-LED (ML) and the second substrate 301.

In this case, the anisotropic conductive film 700 may be formed by filling with the conductive material 700b a plurality of holes 700a vertically formed in the insulating porous film which is formed of an elastic material and in which the plurality of holes 700a is vertically formed. The vertical conductive material 700b may electrically connect the micro-LED (ML) and the second substrate 301 to each other.

8. Display Panel Fabrication Step

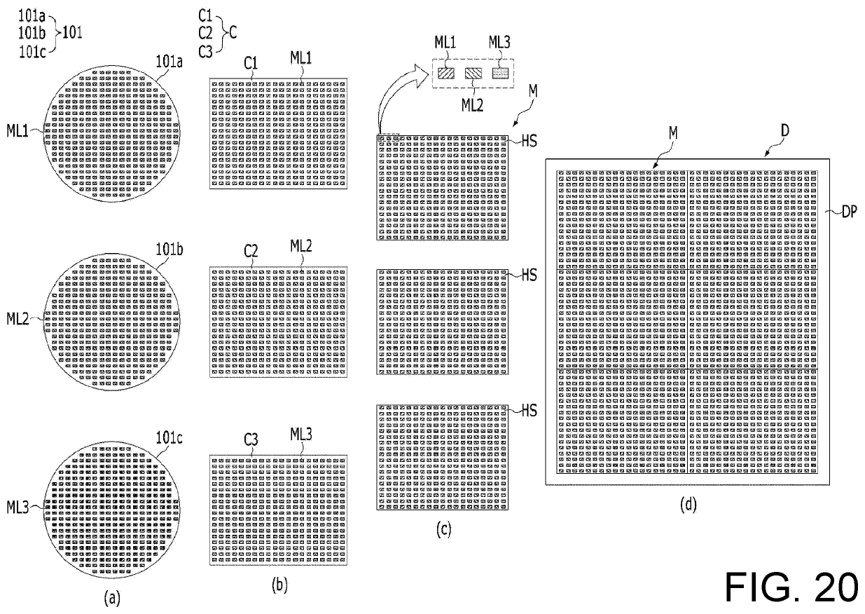

FIGS. 20(a) to 20(d) are views schematically illustrating a process of manufacturing the micro-LED display D according to the present invention. With reference to FIG. 20, the transfer head may be configured in such a manner that the pitch distance in one direction between the absorption regions is M/3 times (where M is an integer) the pitch distance in one direction between the micro-LEDs (ML) arranged in the first substrate.

The first substrate from which the transfer head absorbs the micro-LED (ML) may be the growth substrate or the carrier substrate C. The second substrate may be the carrier substrate or the circuit substrate HS. The first substrate and the second substrate may be determined according to which substrate the transfer head absorbs the micro-LED (ML) from and according to which substrate the transfer head transfers the absorbed micro-LED (ML) to.

Specifically, the first substrate refers to a substrate from which the transfer head absorbs the micro-LED (ML). In addition, the second substrate refers to a substrate to which the transfer head transfers the micro-LED (ML) absorbed from the first substrate. Therefore, in a case where the transfer head absorbs the micro-LED (ML) on the growth substrate 101, the growth substrate 101 may be the first substrate. In addition, in a case where the transfer head absorbs the micro-LED (ML) on the growth substrate 101 and then transfers the absorbed micro-LED (ML) to the carrier substrate C, the second substrate may be the carrier substrate C.

Alternatively, in a case where the transfer head absorbs the micro-LED (ML) on the carrier substrate C and transfers the absorbed micro-LED (ML) to the circuit substrate HS, the first substrate may refer to a temporary HS and the second substrate may refer to the circuit substrate HS. In this manner, the first substrate and the second substrate may be determined according to which substrate the transfer head absorbs the micro-LED (ML) from and according to which substrate the transfer had transfers the micro-LED (ML) to.

The method for manufacturing a micro-LED display may be configured to include a unit module fabrication step of manufacturing a unit module, the unit module fabrication step being performed subsequently to the micro-LED bonding step and a display panel fabrication step of transferring the unit module M to a display substrate DP.

First, FIG. 20(a) illustrates a step of preparing the first substrate to which the micro-LED (ML) is provided. As illustrated in FIG. 20(a), through an epitaxy process, the red, green, and blue micro-LEDs (ML1, ML2, and ML3) are manufactured and prepared on first to third growth substrates 101a, 101b, and 101c, respectively. Therefore, a plurality of the first substrate may be provided.

FIG. 20(b) is a view illustrating a state where the micro-LED (ML) on the micro-LED (ML) on the growth substrate 101 is transferred to the carrier substrate C. FIG. 20(c) is a view illustrating a state where the micro-LED (ML) on the micro-LED (ML) on the growth substrate 101 is transferred to the circuit substrate HS. The respective micro-LEDs (ML1, ML2, and ML3) on the growth substrates 101a, 101b, and 101c, as illustrated in FIG. 20(b), may be transferred by the transfer head to the first to third carrier substrates (C1, C2, and C3), respectively, that correspond to a predetermined pitch distance, or as illustrated in FIG. 20(c), may be transferred to the circuit substrate HS. The micro-LED (ML) on the carrier substrate C may be transferred to the circuit substrate HS.

In the unit-module fabrication step, the micro-LEDs (ML) that are transferred to the circuit substrate are arranged in the pixel arrangement, and thus, the unit module M having a specific pixel arrangement is manufactured.

As one example, the pitch distance in one direction between the absorption regions of the transfer head may be M/3 times (where M is an integer) the pitch distance in one direction between the micro-LEDs (ML) arranged on the first substrate, and the transfer head may selectively absorb and transfer the micro-LEDs (ML). Thus, each of the red, green, and blue micro-LEDs (ML1, ML2, and ML3) may be transferred to the circuit substrate HS with a predetermined pitch distance being maintained therebetween. In this case, the same types of micro-LEDs (ML) are transferred in such a manner as to be arranged in the same column.

The micro-LEDs (ML1, ML2, and ML3) that are transferred on the circuit substrate HS with a predetermined pitch distance being maintained therebetween are arranged in the 1×3 pixel arrangement. The 1×3 pixel arrangement is made on the circuit substrate HS, and thus the unit module M having the 1×3 pixel arrangement may be manufactured.

In this manner, in the unit-module fabrication step, various types of the micro-LEDs (ML1, ML2, ML3) are mounted on the circuit substrate HS in such a manner as to be arranged in the pixel arrangement. A plurality of unit modes M may be individually manufactured in the unit-module fabrication step. With the plurality of unit modules M, it is possible that edgeless (bezel-less) large-sized displays are realized.

Through the unit-module fabrication step, a relatively small number of micro-LEDs (ML) may be mounted in each of the plurality of individual unit modules M. Accordingly, it may be simply inspected whether or not the micro-LED (ML) is defective, and the repair step based on the inspection result may be simply performed. Accordingly, the unit module M including only the quality micro-LEDs (ML) may be mounted on the large-sized display. Thus, a yield for the process of manufacturing the large-sized display can be improved, and the effect of shortening the fabrication time can be achieved.

The unit module M manufactured in the unit-module fabrication step may be transferred to the display substrate DP in the display panel fabrication step. In other words, in the display panel fabrication step, the unit module M may be transferred to the display substrate DP.

In the display panel fabrication step, the unit module M may be transferred to the display substrate DP, and thus the display panel may be manufactured. With the plurality of modules M transferred to the display substrate DP, the pixel arrangement in the display substrate DP may be made to be the same as the pixel arrangement of the micro-LEDs (ML) in the unit module M. In addition, the pitch distance in the pixel arrangement in the display substrate DP may be made to be the same as the pitch distance in the pixel arrangement in the unit module M.

As one example, the module M having the 1×3 pixel arrangement is transferred to the display substrate DP, and the micro-LEDs (ML) are arranged in the 1×3 pixel arrangement. The transfer head is configured in such a manner that the pitch distance in one direction between the absorption regions is M/3 (where M is an integer that is equal to or greater than 4) times the pitch distance in one direction between the micro-LEDs (ML) arranged on the first substrate. The micro-LEDs (ML), the pitch distance between which is the same as the pitch distance in the pixel arrangement of the micro-LEDs that are made when the transfer head with the above-described configuration transfers the micro-LEDs (ML1, ML2, and ML3) to the circuit substrates, may be transferred to the display substrate DP.

With the method for manufacturing the micro-LED display according to the present invention, it is possible to manufacture the plurality of unit modules M in terms of configuration. Thus, it may be simply inspected whether or not the micro-LED (ML) is defective, and the repair step based on the inspection result may be simply performed. Accordingly, the unit module M including only the quality micro-LEDs (ML) may be mounted on the large-sized display. Thus, the yield for the process of manufacturing the large-sized display can be improved. In addition, the effect of shortening the fabrication time can be achieved. In addition, with the structure in which the plurality of unit models M manufactured by transferring the micro-LEDs (ML) to the circuit substrate HS are mounted and constitute the micro-LED display D, it is possible that the edgeless (bezel-less) large-sized display is realized.

The preferred embodiments of the present invention are described above. It would be apparent to a person of ordinary skill in the art to which the present invention pertains that various modifications and alterations are possibly made to the preferred embodiments of the present invention without departing from the spirit and scope of the present invention defined in the following claims.

### DESCRIPTION OF THE REFERENCE NUMERALS IN THE DRAWINGS

1, 1′, 1″, 1′″, 1″″: transfer head
1000: porous member 1100: first porous member, absorption member
1200: second porous member, support member 1300: vacuum chamber
1500, 1500′: absorption hole 1600: anodic oxide film
101: growth substrate 301: circuit substrate
ML: micro-LED

1. A method for manufacturing a micro-LED display, the method comprising:
a transfer step of absorbing, by a transfer head, a micro-LED on a first substrate and transferring, by the transfer head, the absorbed micro-LED to a second substrate.

2. The method of claim 1, wherein the transfer head comprises:
an absorption member divided into an absorption region absorbing the micro-LED that is a transfer target on the first substrate and a non-absorption region not absorbing the micro-LED that is a non-transfer target on the first substrate; and
a support member provided on top of the absorption member and formed of a porous material,
wherein the transfer head selectively absorbs the micro-LED on the first substrate and transfers the absorbed micro-LED to the second substrate.

3-5. (canceled)

6. The method of claim 1 further comprising:
a cleaning step of cleaning an absorption surface of the transfer head,
wherein the cleaning step is performed by at least one apparatus of a plasma generation apparatus, a purge gas injection apparatus, an ionic-wind injection apparatus, and a static electricity removal apparatus.

7-10. (canceled)

11. The method of claim 1, wherein the micro-LEDs are transferred in such a manner that a pitch distance in one direction between the same types of the micro-LEDs on the second substrate is M/3 (where M is an integer that is equal to or greater than 4) times a pitch distance in the one direction between the same types of the micro-LEDs on the first substrate.

12. The method of claim 1, further comprising:
a step of preparing a positional error correction carrier that includes a loading groove having a bottom surface and an oblique portion and accommodating the micro-LED, and a non-loading surface provided in the vicinity of the loading groove;
a positional error correction step of transferring the micro-LED on a first substrate to the positional error correction carrier and correcting a positional error of the micro-LED; and
a step of transferring the micro-LED in the positional error correction carrier to the second substrate.

13. The method of claim 1, further comprising:
an inspection step of inspecting the micro-LD on the first substrate or the second substrate,
wherein the micro-LEDs in the first to m-th rows are sequentially inspected, and the micro-LEDs in the first to m-th columns are sequentially inspected, and
coordinates of a position of the defective micro-LCD are identified through the row-based inspection and the column-based inspection.

14. The method of claim 1, further comprising:
an inspection step of inspecting whether or not the micro-LED on the first substrate is defective;
a removal step of removing the defective micro-LED detected in the inspection step from the first substrate;
a repair step of attaching the quality micro-LED in such a manner as to be positioned at a position on the first substrate from which the defective micro-LED is removed; and
a micro-LED transfer step of transferring the micro-LED on the first substrate to the second substrate using the transfer head.

15. The method of claim 1, further comprising:
a step of absorbing the micro-LED on the first substrate using the transfer head;
an inspection step of inspecting whether or not the micro-LED absorbed to the transfer head is defective;
a removal step of removing the defective micro-LED detected in the inspection step from the transfer head;
a repair step of absorbing, by the transfer head, the quality micro-LED in such a manner as to be positioned at a position on the transfer head from which the defective micro-LED is removed; and
a micro-LED transfer step of transferring the micro-LED absorbed to the transfer head to the second substrate.

16. The method of claim 1, further comprising:
a step of absorbing the micro-LED on the first substrate using the transfer head;
an inspection step of inspecting whether or not the micro-LED absorbed to the transfer head is defective;
a removal step of removing the defective micro-LED detected in the inspection step from the transfer head;
a micro-LED transfer step of transferring the micro-LED absorbed to the transfer head to the second substrate; and
a repair step of attaching the quality micro-LED in such a manner as to be positioned at a position on the second substrate from which the defective micro-LED is removed.

17. The method of claim 1, further comprising:
a step of absorbing the micro-LED on the first substrate using the transfer head;
an inspection step of inspecting whether or not the micro-LED absorbed to the transfer head is defective;
a micro-LED transfer step of transferring the micro-LED absorbed to the transfer head to the second substrate;
a removal step of removing the defective micro-LED detected in the inspection step from the second substrate; and
a repair step of attaching the quality micro-LED in such a manner as to be positioned at a position on the second substrate from which the defective micro-LED is removed.

18. The method of claim 1, further comprising:
a step of transferring the micro-LED on the first substrate to a relay wiring substrate including a relay wiring unit;
a step of cutting the relay wiring substrate to which the micro-LED is transferred into a plurality of discrete modules;
and a step of transferring, by the transfer head, a quality discrete module, among the discrete modules, and transferring, by the transfer head, the absorbed quality discrete module to the second substrate.

19. The method of claim 1, wherein an electrostatic chuck is provided underneath the second substrate, and the electrostatic chuck attaches the second substrate with an electrostatic force, applies the electrostatic force to the micro-LED absorbed to the transfer head, and thus forces the micro-LED to descend toward the second substrate.

20. The method of claim 1, wherein the transfer head comprises:
an openable valve,
wherein, when the transfer head absorbs the micro-LED, a vacuum pump is operated in a state where the openable value is closed, and thus the micro-LED is absorbed with a vacuum absorption force, and
wherein, when the transfer head desorbs the micro-LED, the openable value is open to release the vacuum absorption force, and thus the micro-LED absorbed to the transfer head is desorbed.

21. The method of claim 1, wherein the transfer head comprises:
a heater unit,
wherein in a micro-LED bonding step of bonding the micro-LED to the second substrate, an upper surface of the micro-LED is heated through the heater unit.

22. The method of claim 1, wherein in a micro-LED bonding step of bonding the micro-LED to the second substrate, an upper surface of the micro-LED is heated by applying hot air through an absorption region of the transfer head.

23. The method of claim 1, wherein a micro-LED bonding step of bonding the micro-LED to the second substrate comprises:
a sub-step of preparing between the micro-LED and the second substrate an anisotropically conductive anodic oxide film formed by filling with a conductive material a pore in an anodic oxide film formed by anodically oxidizing a metal or a separate through-hole; and
a sub-step of mounting the micro-LED on the anisotropically conductive anodic oxide film.

24. The method of claim 1, wherein a micro-LED bonding step of bonding the micro-LED to the second substrate comprises:
a sub-step of preparing between the micro-LED and the second substrate an anisotropic conductive film formed by filling with a conductive material a plurality of holes vertically formed in an insulating porous film which is formed of an elastic material and in which the plurality of holes is vertically formed; and
a sub-step of mounting the micro-LED on the anisotropic conductive film.

25. The method of claim 1, wherein a unit module fabrication step of manufacturing a unit module and a display panel fabrication step of transferring the unit module to a display substrate are included, the unit module fabrication step and a display panel fabrication step being performed subsequently to a micro-LED bonding step.

26-28. (canceled)
